(19) United States
(12) Patent Application Publication
(10) Pub. No.: US 2008/0245478 A1
(43) Pub. Date: Oct. 9, 2008

(54) Surface treatment apparatus

(75) Inventors: Eiki Hotta, Yokohama-shi (JP); Naohiro Shimizu, Miura-shi (JP); Yuichiro Imanishi, Nagoya-shi (JP)

Correspondence Address: OLIFF & BERRIDGE, PLC, P.O. BOX 320850, ALEXANDRIA, VA, 22320-4850, US

(73) Assignees: TOKYO INSTITUTE OF TECHNOLOGY, TOKYO (JP); NGK INSULATORS, LTD., NAGOYA-SHI (JP)

(21) Appl. No.: 12/081,913

(22) Filed: Apr. 23, 2008

Related U.S. Application Data
(63) Continuation-in-part of application No. 11/826,957, filed on Jul. 19, 2007.

(30) Foreign Application Priority Data
Feb. 9, 2007 (JP) 2007-031297
Mar. 16, 2007 (JP) 2007-068908

(51) Int. Cl. C23F 1/00; C23C 16/448

(52) U.S. Cl. 156/345.29; 156/345.43; 156/345.4; 118/723 E; 118/723 FE

(57) ABSTRACT

A surface treatment apparatus encompasses a gas introducing system configured to introduce a process gas from downstream end of a tubular treatment object; a vacuum evacuating system configured to evacuate the process gas from other end of the treatment object; an excited particle supplying system disposed at upstream side of the treatment object, configured to supply excited particles for inducing initial discharge in a main body of the treatment object; and a first main electrode and a second main electrode disposed oppositely to each other, defining a treating region of the treatment object as a main plasma generating region disposed therebetween, wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow in the inside of the treatment object, and thereby an inner surface of the treatment object is treated.

### CROSS REFERENCE TO RELATED APPLICATIONS AND INCORPORATION BY REFERENCE

This application is a continuation in part of U.S. patent application Ser. No. 11/826,957, filed on Jul. 19, 2007, abandoned, which claims benefit of priority under 35 USC 119 based on Japanese Patent Application No. P2007-31297 filed Feb. 9, 2007, and Japanese Patent Application No. P2007-68908 filed Mar. 16, 2007, the entire contents of which are incorporated by reference herein.

### BACKGROUND OF INVENTION

1. Field of Invention

The present invention pertains to a surface treatment apparatus using non-thermal equilibrium low temperature plasma. Invention particularly relates to a surface treatment apparatus that facilitates miscellaneous inner wall processing of treatment objects, which may include a long (several meters long) and narrow (several millimeters of inside diameter) dielectric tube.

2. Description of the Related Art

Liquid in a narrow tube contact with inner wall of the narrow tube at a specific contact angle, the value of the contact angle depends upon surface property of inner wall such as hydrophobic or hydrophilic behavior and geometry of inner wall such as glassy shape or hollow shape. An upward force in a pipe of a capillary action depends on the product of surface tension, cosine of a contact angle, and circumferential length of a hole. A downward force depends on the product of pressure, gravity, specific gravity of the liquid and height of the liquid. Therefore, the height of the liquid in a narrow tube can be calculated by equating the upward force and the downward force. For example, a column of water rises about 0.75 m in an atmospheric pressure in a pipe element having an inside diameter of 20 micrometers. However, in the inner wall of a narrow tube, it is difficult that liquid is transported at high speed. Therefore, as against inside of a long-narrow tube, it is extremely difficult to execute pasteurization, sterilization or washing by wet processing. Because of these problems, dry-process is suitable for inner wall processing of a long-narrow tube by non-thermal equilibrium low temperature plasma, which is full of radicals, is expected to process inner wall of a narrow tube.

Ichiki et al. have proposed an employment of plasma jet generated by inductively-coupled-high-frequency plasma for the dry-process of inner wall of a narrow tube is tried (See T. Ichiki et al., “Localized and ultrahigh-rate etching of silicon wafers using atmospheric-pressure microplasma jet”, J. Appl. Phys., 95 (2004) pp. 35-39). Plasma length of Ichiki et al is around several centimeters to the utmost.

Fujiyama proposed a configuration in which a metal electrode is interposed in a narrow tube so as to establish a pulsed discharge. However, it is extremely difficult to interpose the metal electrode in inside of a narrow tube having an inside diameter of less than several millimeters (See H. Fujiyama, “Inner coating of long-narrow tube by plasma sputtering”, Surface and Coating Technology, 131 (2000) pp. 278-283).

In particular, because medical instrument such as endoscope encompasses optical system and metallic parts having very minute geometry, the metallic part rises to a considerable high temperature, when the medical instrument are sterilized by plasma, even though low temperature plasma is employed. The rising to the high temperature generates a problem that warp or misalignment is produced in the optical system.

Because of these problems, under the present situations, in order to remove microbes adhered to an endoscope, a medical staff must dip the endoscope in antiseptic solution, and wash off microbes carefully from the endoscope with several stages in the antiseptic solution.

In view of these situations, Fukuda has proposed another sterilization method in a double tube structure, establishing washing in water and sterilization by plasma (See JP2006-21027 A). A long-narrow tube to be sterilized is dipped into water, which is filled in an inner tube made of glass, and the inner tube is installed in an outer tube. The plasma generated in a space between the inner tube and the outer tube is irradiated to long-narrow tube through the inner tube. However, in the double tube method proposed by Fukuda because a basis of sterilization is wet processing, there is a limit in the sterilization capability.

Therefore, no effective plasma generation method is proposed, which can be applied to in the inside of a long-narrow tube, having a length of several meters and an inside diameter of several millimeters, until now.

In particular, because dissociation energy of nitrogen molecules is so large compared with other gas molecules, as shown in table 1, as for the generation of nitrogen plasma, stable generation was very difficult until now.

TABLE 1

| gas molecules | F₂ | H₂O₂ | OH | N₂O | O₂ | CO₂ | NO | N₂ |
|---|---|---|---|---|---|---|---|---|
| dissociation | 1.66 | 2.21 | 4.62 | 4.93 | 5.21 | 5.52 | 6.50 | 9.91 |
| energy (eV) | | | | | | | | |

### SUMMARY OF INVENTION

In view of these situations, it is an object of the present invention to provide a surface treatment apparatus, which can treat surfaces of inner walls of various kinds of treatment objects, including a long-narrow tube having a length of several meters with an inside diameter of several millimeters. Hereinafter, the term “inner wall treatment” shall mean any surface treatment of a surface of inner wall of the subject treatment object. In addition, the term “surface treatment” shall mean any surface treatment of a surface of inner wall (inner surface) or the outer wall (outer surface) of the subject treatment object, which may include pasteurization, sterilization, and improvement of wettability. In a wide sense, the term “surface treatment” shall mean any removal of adhered materials, such as organic/inorganic materials, adhered to the surface of inner wall (inner surface) or the outer wall (outer surface) of the treatment object and any change of physical or chemical property of inner surface or the outer surface of the treatment object.

The term “change of physical or chemical property” shall include deposition or etching by plasma reaction. Therefore, a process to deposit a film made of material different from inner surface of the treatment object corresponds to the term “change of physical or chemical property”.

An aspect of the present invention inheres in a surface treatment apparatus encompassing a gas introducing system for introducing a process gas from an upstream end of a tubular treatment object; a vacuum evacuating system for evacuating the process gas from a downstream end of the treatment object;

an excited particle supplying system disposed at upstream side of the treatment object, for supplying excited particles for inducing initial discharge in a main body of the treatment object; and a first main electrode and a second main electrode disposed oppositely to each other, defining a treating region of the treatment object as a main plasma generating region disposed therebetween, wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow inside the treatment object, and thereby the inner surface of the treatment object is treated.

Another aspect of the present invention inheres in a surface treatment apparatus encompassing a vacuum evacuating system for evacuating a process gas introduced at a specific flow rate from a feed pipe provided at first end of a tubular treatment object having a blind wall at a second end, from an exhaust pipe provided at the first end, and maintaining the pressure of the process gas inside the treatment object at a process pressure; an excited particle supplying system disposed at upstream side of the treatment object, for supplying excited particles for inducing initial discharge in a main body of the treatment object; and a first main electrode and a second main electrode disposed oppositely to each other, defining a treating region of the treatment object as a main plasma generating region disposed therebetween, wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow inside the treatment object, and thereby the inner surface of the treatment object is treated.

Still another aspect of the present invention inheres in a surface treatment apparatus encompassing a vacuum manifold unit connected to a first end of a tubular treatment object having a blind wall at a second end, for confining hermetically process gas at specified pressure inside of the treatment object from the first end; an excited particle supplying system disposed at the first end side, for supplying excited particles for inducing initial discharge in a main body of the treatment object; and a first main electrode and a second main electrode disposed oppositely to each other, defining a treating region of the treatment object as a main plasma generating region disposed therebetween, wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow inside the treatment object, and thereby the inner surface of the treatment object is treated.

Further aspect of the present invention inheres in a surface treatment apparatus encompassing a vacuum evacuating system configured to evacuate process gas introduced from an upstream end of a tubular trunk pipe of a treatment object to generate a gas flow, the treatment object having the tubular trunk pipe and a branch pipe branched off from the trunk pipe, from a downstream end of the trunk pipe and an end portion of the branch pipe; an excited particle supplying system disposed at the upstream side of the treatment object, configured to supply excited particles for inducing initial discharge in a main body of the treatment object; and a first main electrode and a second main electrode disposed oppositely to each other, defining a treating region of the treatment object as a main plasma generating region disposed therebetween, wherein the excited particle supplying system is driven at least until generation of main plasma, and main pulse of duty ratio of 107 to 10⁻¹ is applied across the first main electrode and second main electrode, to generate a non-thermal equilibrium plasma flow inside the treatment object, and thereby an inner surface of the treatment object is treated.

Still further aspect of the present invention inheres in a surface treatment apparatus encompassing a vacuum evacuating system configured to evacuate process gas introduced from a downstream end of a tubular trunk pipe of a treatment object and an end portion of a branch pipe of the treatment object to generate a gas flow, the treatment object having the tubular trunk pipe and the branch pipe branched off from the trunk pipe, from an upstream end of the trunk pipe; an excited particle supplying system disposed at the upstream side of the treatment object, configured to supply excited particles for inducing initial discharge in a main body of the treatment object; and a first main electrode and a second main electrode disposed oppositely to each other, defining a treating region of the treatment object as a main plasma generating region disposed therebetween, wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow inside the treatment object, and thereby an inner surface of the treatment object is treated.

Still further aspect of the present invention inheres in a surface treatment apparatus encompassing an excited particle supplying system disposed at upstream-side of a tubular treatment object made of dielectric material, the treatment object having a length greater than the diameter, for supplying excited particles for inducing initial discharge in a main body of the treatment object; and a first main electrode and a second main electrode disposed oppositely to each other, defining a treating region of the treatment object as a main plasma generating region disposed therebetween, wherein a process gas is introduced from one end of the treatment object to form a gas flow inside of the treatment object, and the pressure of the gas flow is adjusted to a process pressure in a range of 20 kPa to 100 kPa, the excited particle supplying system is driven at least until generation of main plasma, and main pulse of duty ratio of 10⁻⁷ to 10⁻¹ is applied across the first main electrode and second main electrode to generate a non-thermal equilibrium plasma flow inside the treatment object, and thereby the inner surface of the treatment object is treated.

Still further aspect of the present invention inheres in a surface treatment apparatus encompassing a dielectric housing configured to accommodate an treatment object; a gas introducing system configured to introduce a process gas from an upstream end of the dielectric housing; a vacuum evacuating system configured to evacuate the process gas from a downstream end of the dielectric housing; an excited particle supplying system disposed at upstream side of the dielectric housing, configured to supply excited particles for inducing initial discharge in a main body of the dielectric housing; and a first main electrode and a second main electrode disposed oppositely to each other, defining a treating region of the treatment object as a main plasma generating region disposed therebetween, wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow inside the dielectric housing, and thereby a surface of the treatment object is treated.

Still further aspect of the present invention inheres in a surface treatment apparatus encompassing a dielectric housing configured to accommodate an treatment object; a vacuum evacuating system cored to evacuate a process gas introduced at a specific flow rate from a feed pipe provided at a first end of the dielectric housing having a blind wall at a second end, from an exhaust pipe provided at the first end, and maintaining the pressure of the process gas inside the dielectric housing at a process pressure; an excited particle supplying system disposed at first end of the dielectric housing, configured to supply excited particles for inducing initial discharge in a main body of the dielectric housing; and a first main electrode and a second main electrode disposed oppositely to each other, defining a treating region of the treatment object as a main plasma generating region disposed therebetween, wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow inside the dielectric housing, and thereby a surface of the treatment object is treated.

Other and further objects and features of the present invention will become obvious upon an understanding of the illustrative embodiments about to be described in connection with the accompanying drawings or will be indicated in the appended claims, and various advantages not referred to herein will occur to one skilled in the art upon employing of the present invention in practice.

### BRIEF DESCRIPTION OF THE DRAWINGS

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified. Generally and as it is conventional in the representation of semiconductor devices, it will be appreciated that the various drawings are not drawn to scale from one figure to another nor inside a given figure, and in particular that the layer thicknesses are arbitrarily drawn for facilitating the reading of the drawings.

FIG. 1 is a schematic diagram explaining the principle of a surface treatment apparatus in accordance with a first embodiment of the present invention;

FIG. 2 is a bird's-eye view specifically explaining part of the surface treatment apparatus in accordance with the first embodiment of the present invention;

FIG. 3A is a bird's-eye view explaining a meandering treatment object guide groove for accommodating a flexible long-narrow tube adapted for the surface treatment apparatus in accordance with the first embodiment of the present invention;

FIG. 3B is a schematic sectional view explaining an accommodated state of the treatment object in the treatment object guide grooves shown in FIG. 3A;

FIG. 4A shows a voltage waveform of high voltage pulse applied between a first main electrode and a second main electrode in the surface treatment apparatus in accordance with the first embodiment of the present invention;

FIG. 4B shows a corresponding current waveform to the voltage waveform of high voltage pulse shown in FIG. 4A;

FIG. 5 is a schematic diagram explaining an electric field distribution, when a treatment object made of dielectric material is disposed in parallel between first main electrode and second main electrode implementing a parallel flat electrode configuration;

FIG. 6 is a sectional diagram schematically explaining essential structure of a surface treatment apparatus in accordance with a second embodiment of the present invention;

FIG. 7 is a schematic plan view explaining a configuration of a plurality of gas supply holes of the surface treatment apparatus in accordance with the second embodiment of the present invention;

FIG. 8 is a cross-sectional view schematically explaining essential structure of a surface treatment apparatus in accordance with a first modification of the second embodiment of the present invention;

FIG. 9 is a cross-sectional view schematically explaining essential structure of a surface treatment apparatus in accordance with a second modification of the second embodiment of the present invention;

FIG. 10 is a cross-sectional view schematically explaining essential structure of a surface treatment apparatus in accordance with a third embodiment of the present invention;

FIG. 11 is a cross-sectional view schematically explaining essential structure of a surface treatment apparatus in accordance with a fourth embodiment of the present invention;

FIG. 12 is a cross-sectional view schematically explaining essential structure of a surface treatment apparatus in accordance with a fifth embodiment of the present invention;

FIG. 13 is a cross-sectional view schematically explaining essential structure of a surface treatment apparatus in accordance with a first modification of the fifth embodiment of the present invention;

FIG. 14 is a cross-sectional view schematically explaining essential structure of a surface treatment apparatus in accordance with a second modification of the fifth embodiment of the present invention;

FIG. 15 is a cross-sectional view schematically explaining essential structure of a surface treatment apparatus in accordance with a sixth embodiment of the present invention;

FIG. 16 is a cross-sectional view schematically explaining essential structure of a surface treatment apparatus in accordance with a seventh embodiment of the present invention;

FIG. 17 is a cross-sectional view schematically explaining essential structure of the surface treatment apparatus in accordance with the seventh embodiment as seen from a direction orthogonal to FIG. 16;

FIG. 18 is a cross-sectional view schematically explaining essential structure of a surface treatment apparatus in accordance with an eighth embodiment of the present invention;

FIG. 19 is a cross-sectional view schematically explaining essential structure of the surface treatment apparatus in accordance with the eighth embodiment as seen from a direction orthogonal to FIG. 18;

FIG. 20 is a cross-sectional view schematically explaining essential structure of a surface treatment apparatus in accordance with a ninth embodiment of the present invention;

FIG. 21 is a cross-sectional view schematically explaining essential structure of a surface treatment apparatus in accordance with a tenth embodiment of the present invention;

FIG. 22 is a cross-sectional view schematically explaining essential structure of a surface treatment apparatus in accordance with an eleventh embodiment of the present invention;

FIG. 23 is a cross-sectional view schematically explaining essential structure of a surface treatment apparatus in accordance with a first modification of the eleventh embodiment of the present invention;

FIG. 24 is a cross-sectional view schematically explaining essential structure of a surface treatment apparatus in accordance with a second modification of the eleventh embodiment of the present invention;

FIG. 25 is a cross-sectional view schematically explaining essential structure of a surface treatment apparatus in accordance with a third modification of eleventh embodiment of the present invention;

FIG. 26 is a cross-sectional view schematically explaining essential structure of a surface treatment apparatus in accordance with a fourth modification of the eleventh embodiment of the present invention;

FIG. 27 is a cross-sectional view schematically explaining essential structure of a surface treatment apparatus in accordance with a twelfth embodiment of the present invention;

FIG. 28A illustrates an example of dielectric triple points, which can be employed in the surface treatment apparatus in accordance with the twelfth embodiment of the present invention;

FIG. 28B illustrates another example of dielectric triple points, which can be employed in the surface treatment apparatus in accordance with the twelfth embodiment of the present invention;

FIG. 29 is a cross-sectional view schematically illustrating a treatment object under treatment by a surface treatment apparatus in accordance with a thirteenth embodiment of the present invention;

FIG. 30 illustrates Paschen's law, which serves as a basis of the surface treatment apparatus of the thirteenth embodiment of the present invention;

FIG. 31 is a cross-sectional view schematically illustrating a state when the treatment against the treatment object is completed in the surface treatment apparatus of the thirteenth embodiment of the present invention;

FIG. 32 is a cross-sectional view schematically illustrating another state when the treatment against the treatment object is completed in the surface treatment apparatus of the thirteenth embodiment of the present invention;

FIG. 33 is a cross-sectional view schematically illustrating a treatment object under treatment by a surface treatment apparatus in accordance with a modification of the thirteenth embodiment of the present invention;

FIG. 34 is a cross-sectional view schematically illustrating a state when the treatment against the treatment object is completed in the surface treatment apparatus of the modification of the thirteenth embodiment of the present invention;

FIG. 35 is a cross-sectional view schematically illustrating another state when the treatment against the treatment object is completed in the surface treatment apparatus of the modification of the thirteenth embodiment of the present invention;

FIG. 36A is a cross-sectional view cut along axial direction, schematically explaining structure of an excited particle supplying system of a surface treatment apparatus in accordance with another embodiment of the present invention;

FIG. 36B is a corresponding cross-sectional view cut along radial direction of the excited particle supplying system shown in FIG. 36A;

FIG. 37A is a cross-sectional view cut along axial direction, schematically explaining structure of another excited particle supplying system of a surface treatment apparatus in accordance with another embodiment of the present invention, and

FIG. 37B is a corresponding cross-sectional view cut along radial direction of the excited particle supplying system shown in FIG. 37A.

### DETAILED DESCRIPTION OF INVENTION

In the following description specific details are set forth, such as specific materials, processes and equipment in order to provide a thorough understanding of the present invention. It will be apparent, however, to one skilled in the art that the present invention may be practiced without these specific details. In other instances, well-known manufacturing materials, processes and equipment are not set forth in detail in order not to unnecessarily obscure the present invention. Prepositions, such as “on”, “over”, “under”, “beneath”, and “normal” are defined with respect to a planar surface of the object component, regardless of the orientation in which the object component is actually held. A layer is on another layer even if there are intervening layers.

### First Embodiment

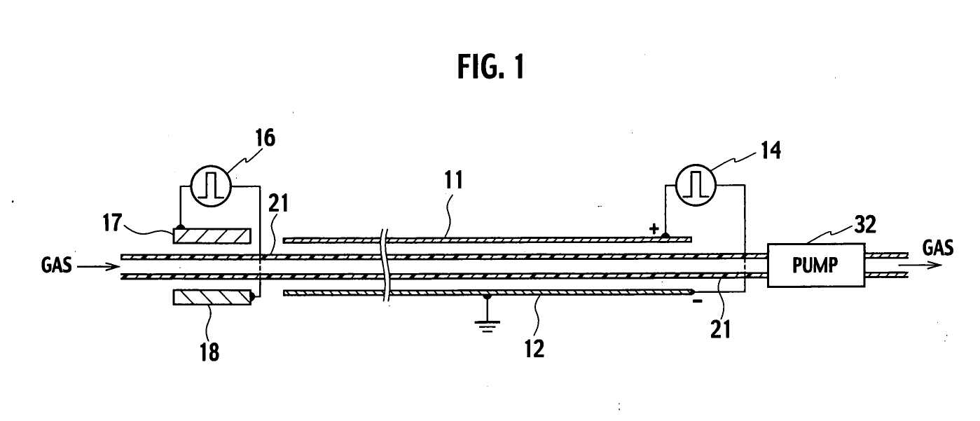

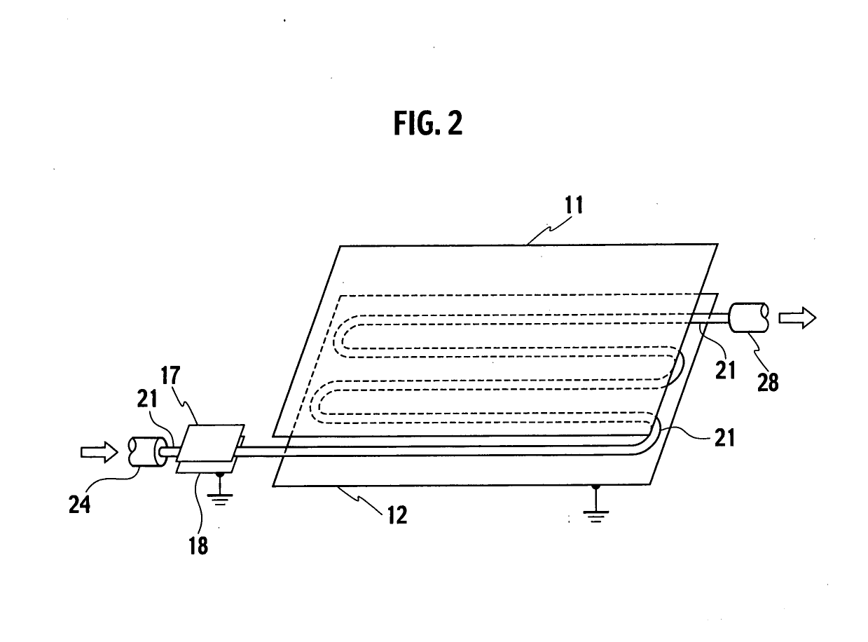

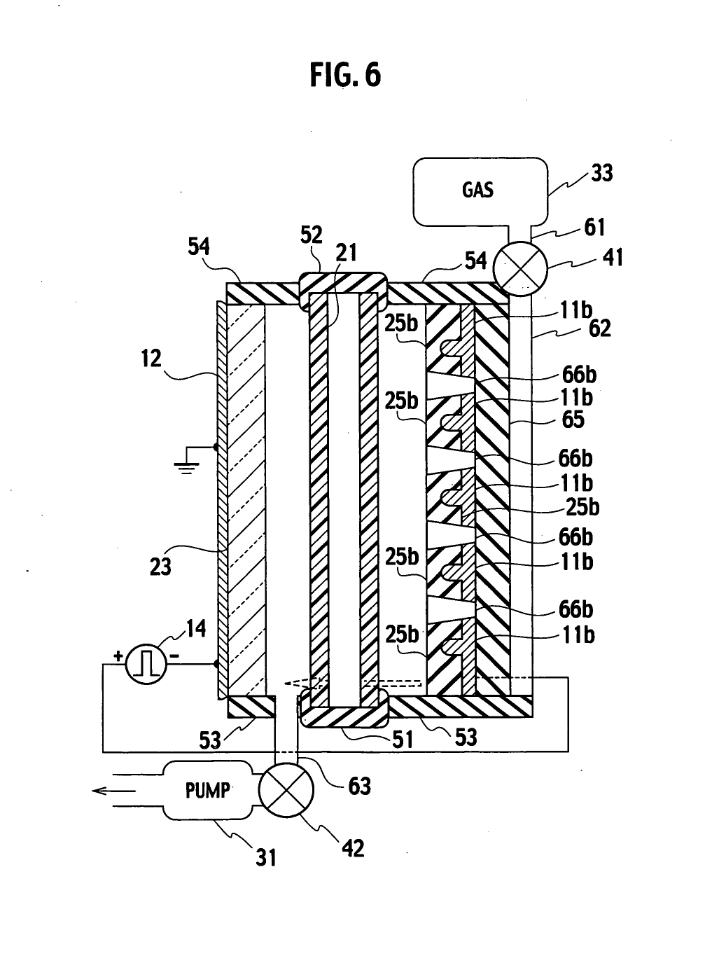

As shown in FIGS. 1 and 2, a surface treatment apparatus related to a first embodiment of the present invention encompasses a gas introducing system (illustration is omitted, but the gas introducing system is shown in FIG. 6) for introducing a process gas from an upstream end of a tubular treatment object 21; a vacuum evacuating system 32 for evacuating the process gas from a downstream end of the treatment object 21; an excited particle supplying system (16, 17 and 18) disposed at upstream side of the treatment object 21, for supplying excited particles for inducing initial discharge in a main body of the treatment object 21; and a first main electrode 11 and a second main electrode 12 disposed oppositely to each other, defining a treating region of the treatment object 21 as a main plasma generating region disposed therebetween, wherein the excited particle supplying system (16, 17 and 18) is driven at least until generation of main plasma, and main pulse of duty ratio of 10⁻⁷ to 10⁻¹ is applied across the first main electrode 11 and second main electrode 12, to generate a non-thermal equilibrium plasma flow inside the treatment object 21, and thereby the inner surface of the treatment object 21 is treated.

In FIGS. 1 and 2, the second main electrode (cathode electrode) 12 that is illustrated at lower side is grounded, while to the first main electrode (anode electrode) 11 that is illustrated at upper side is illustrated, a high voltage is applied. But the drawing is illustrative, and top and bottom relation of a drawing, or right and left relation of the drawing can be defined and expressed arbitrary. For example, the second main electrode 12 illustrated at lower side can be assigned as anode electrode, while the first main electrode 11 illustrated at upper side can be assigned as cathode electrode, theoretically. If the second main electrode 12 is kept to be grounded, the polarity of the output pulse of the power supply 14 is reversed so that the first main electrode 11 can serve as the cathode. On the other hand, the first main electrode 11 can be grounded without turning over the polarity of the output pulse of the power supply 14 such that a high voltage is applied to the second main electrode 12, the first main electrode 11 can serve as the cathode electrode.

The technical feature such that, in a surface treatment apparatus related to the first embodiment, a long-narrow tube having an inside diameter of less than or equal to 7-5 millimeters and a length of more than 4-7 meters is supposed to be employed as the treatment object 21 having tubular geometry, but even if the length is equal to or less than 4 meters long or inside diameter is more than 7 millimeters, the treatment object 21 can be processed, may be understood from the following discussion.

In particular, as for the technical advantage of the surface treatment apparatus related to the first embodiment, because, in Ichiki's methodology, the length of a microplasma is several centimeters at longest, a tube having a length of around 10 centimeters can achieve a significant effectiveness over Ichiki's methodology. In view of the technology taught by Ichiki's methodology, in a technical field of plasma, a tube having an inside diameter of equal to or less than 7-5 millimeters, a length of more than around 10 centimeters can be defined as “a long-narrow tube”. In addition, a cross-section of treatment object 21 is not limited to a circle, but polygons, including rectangle, can be employed. However, as for the long-narrow tubes adapted for industrial applications, there will be many cases that the long-narrow tubes have a circular cross-section. Although as representative long-narrow tube, medical instrument such as an endoscope (fiber scope) is well known, the technical concept of “a long-narrow tube” covers through various kinds of narrow tubes. For example, narrow tubes adapted for drinking water, which is used in vending machines can be included in the technical concept of “a long-narrow tube”.

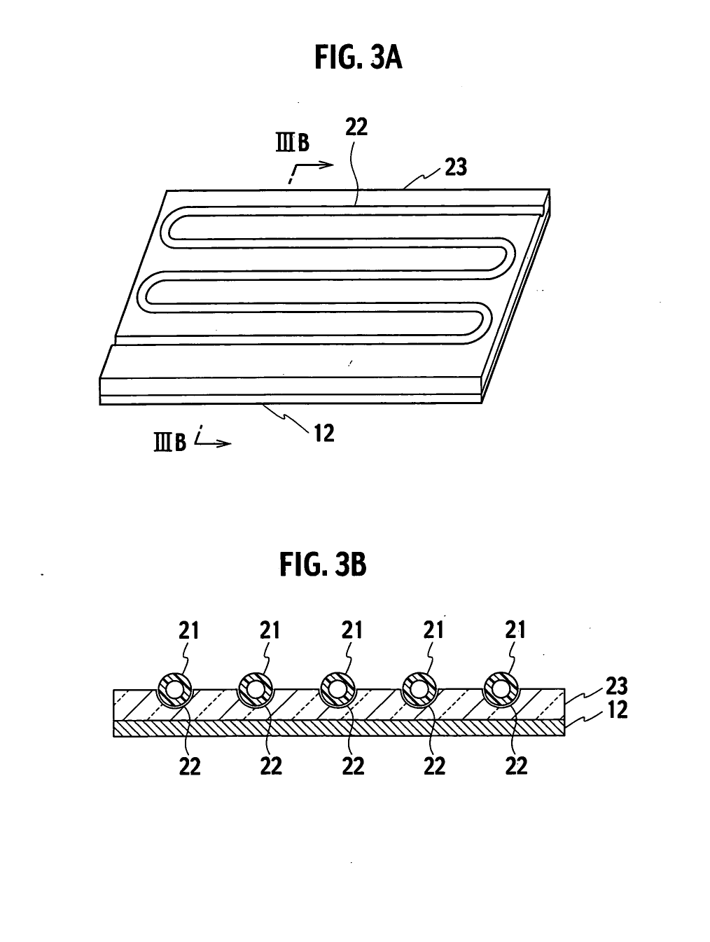

When the treatment object 21 is a flexible long-narrow tube having an inside diameter equal to or less than around several millimeters, and a length of more than around several meters, and further the length is known beforehand, as shown in FIGS. 3A and 3B, a second main electrode-covering insulator 23 made of high purity quartz is provided on the second main electrode 12, such that a meandering treatment object guide groove 22 is cut in and at the surface of second main electrode-covering insulator 23. Then, the flexible long-narrow tube can be fixed in the treatment object guide groove 22, by bending at one corner or plural number of corners, the number of corners depends on the length of the flexible long-narrow tube as shown in FIG. 3B. Because the configuration of the treatment object guide groove 22 can be designed so as to conform to the length of the treatment object 21, if each of the lengths of the treatment objects 21 are predetermined, like a case of medical instrument, a plurality of second main electrode-covering insulators 23, each having different length of treatment object guide groove 22 corresponding to the length of the treatment objects 21 may be prepared.

Anyhow, the configuration with the treatment object guide grooves 22 shown in FIGS. 3A and 3B is a mere example, and various kinds of structure can be adopted, in fact. For example, a hook structure implemented by a plurality of protrusions or a screw structure having a plurality of screws may be established on a top surface of the flat second main electrode-covering insulator 23 so as to fix the treatment object 21 with a plurality of fixing sites.

If the treatment object 21 is the flexible long-narrow tube, rather than the configuration shown in FIGS. 3A and 3B, first and second reels may be provided so that downstream end of the treatment object 21 can be rolled up by the first reel while the second reel provided at upstream end of the treatment object 21 rolls out the treatment object 21, thereby establishing internal surface treatment of the treatment object 21 may be conducted partially and sequentially. Therefore, it is illustrated as if the full length of the treatment object 21 and the length of the first main electrode 11 and the second main electrode 12 are approximately equal in FIG. 1, but depending on behaviors of material such as flexure property, expansive property and contractive property of the treatment object 21, the relationship between the full length of the treatment object 21 and each length of the first main electrode 11 and the second main electrode 12 can be elected arbitrary.

The excited particle supplying system (16, 17 and 18) encompasses a first auxiliary electrode 17, a second auxiliary electrode 18 facing to the first auxiliary electrode 17 so as to sandwich the upstream side of the treatment object 21, implementing a parallel plate configuration, and an auxiliary pulse power supply 16 configured to supply electric pulses between the first auxiliary electrode 17 and the second auxiliary electrode 18. The excited particle supplying system (16, 17 and 18) is provided so as to the starting voltage of the discharges and to generate initial plasma so as to facilitate generation of the plasma in the treatment object 21.

In addition to the effect such that generated plasma or excited particle are transported by diffusion and flow of process gas to arrive in the inside of the treatment object 21, an effect of irradiation by the light emitted from the generated plasma in the excited particle supplying system (16, 17 and 18) can be expected so that light can ionize neutral particles in the treatment object 21. Once plasma is generated in the treatment object 21, and if density of charged particles is large enough, an discharge is realized in the treatment object 21 only by the electric field established between the first main electrode Hand the second main electrode 12, and the generated plasma can be maintained in the treatment object 21. In this stage, the excited particle supplying system (16, 17 and 18) is not needed any more. Therefore, the excited particle supplying system (16, 17 and 18) is employed only at the initial stage of the plasma generation.

In addition, because it is enough that initial plasma can be injected in the gas flow in the early stage, the excited particle supplying system may be implemented by any other configuration such as an inductive plasma source which can generate initial plasma, and the excited particle supplying system is not limited to the parallel plate configuration shown in FIG. 1.

After excitation of initial plasma, the surface treatment apparatus shown in FIG. 1 execute treatment in the inside of the treatment object 21 by radicals included in the plasma generated by discharge. In the surface treatment apparatus related to the first embodiment, high purity nitrogen gas is supplied as process gas in the treatment object 21 from the upstream side, but “process gas” is not limited to nitrogen gas. For example, for pasteurization or sterilization of inside of the treatment object 21, even mixed gas of chlorine (Cl₂) gas or compound gas including chlorine, or more generally, various kinds of active gas such as halogen based compound gas, or mixed gas of these active gas with nitrogen gas can be employed. Even oxygen (O₂ gas or various compound gas including oxygen is available, depending on the object of the surface treatment. The purity or the dew point of the process gas may be determined appropriately in view of the object of surface treatment.

In the surface treatment apparatus related to the first embodiment, the process gas is supplied in the treatment object 21 as shown in FIG. 1 from the upstream side, and the process gas flows through the treatment object 21, and the treatment object 21 is kept at a processing pressure of less than or equal to an atmospheric pressure by the vacuum pump 32 arranged at downstream side. Although the illustration is omitted in FIG. 1, a pressure gauge and a variable conductance valve configured to adjust the exhaust conductance may be provided, as a person skilled in the art may easily understand. For example, a pressure gauge and a mass-flow controller configured to control the flow rate are provided to intake adapter 24 as shown in FIG. 2, and a variable conductance valve adjusting the exhaust conductance may be established in the exhaust adapter 28 shown in FIG. 2. In addition, a pressure gauge may be provided to the exhaust adapter 28.

Intake adapter 24 shown in FIG. 2 is a pipe including a vacuum tight connection joint, configured to connect the supply of process gas such as gas cylinder, illustration of which is omitted, and downstream end of the treatment object 21. The exhaust adapter 28 is another pipe including a vacuum tight connection joint configured to connect the vacuum pump 32 shown in FIG. 1 and downstream end of the treatment object 21. Depending on materials, geometry and size of the treatment object 21, intake adapter 24 and the exhaust adapter 28 can be designed and manufactured, by changing appropriately the well-known gas joints or vacuum components.

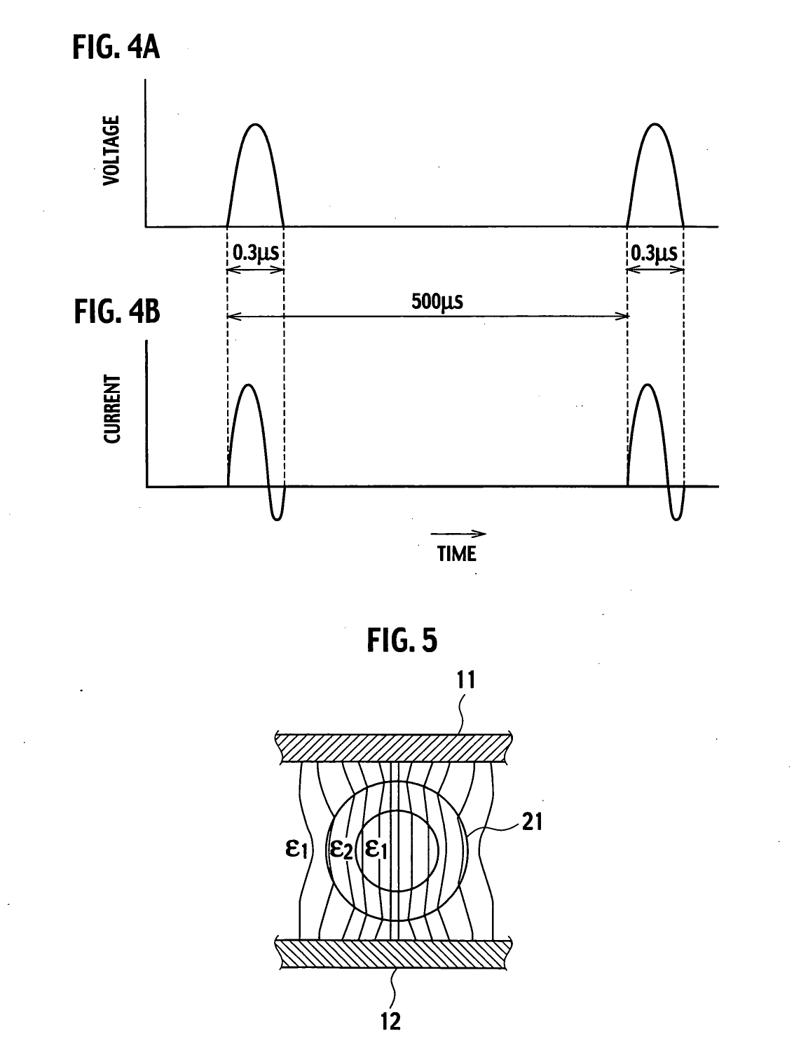

A high voltage pulse having a duty ratio of 10⁻⁷ to 10⁻¹ is applied across the first main electrode 11 and the second main electrode 12. FIG. 4A shows a pulse width of the voltage pulse measured at full width at half maximum (FWHM) is 300 nano seconds, however for the pulse width of the main pulse, around 50-300 nano seconds is preferable. When, in the surface treatment apparatus related to the first embodiment, if a distance between the first main electrode 11 and the second main electrodes 12, implementing a parallel plate configuration, is 15 millimeters, a high voltage pulse with a repetition frequency of 2 k Hz, and voltage value of around 24 kV is preferred. In addition, as for the pressure in the treatment object 21, about 30 kPa, and the nitrogen gas flow rate, around 1 SLM is preferred Because the repetition period is 500 microseconds as shown in FIG. 4, and, in the case of the repetition frequency 2 k Hz for the high voltage pulse, the duty ratio becomes 0.3/500=0.006. Therefore, non-thermal equilibrium low temperature plasma is generated efficiently and stably, without generating heat plasma as the high frequency discharge generates.

In the surface treatment apparatus related to the first embodiment of the present invention, duty ratio of 10⁻⁷ to 10⁻¹ is preferable for the voltage pulse. If the duty ratio is less than 10⁻⁷, the discharge becomes unstable, and if the duty ratio is more than 10⁻¹, unfavorable effect of heat plasma becomes prominent. The duty ratio of around 0.003-0.01 is more preferable. In addition, even a barrier discharge by a low frequency alternating electric field can be used to generate low temperature plasma in the treatment object 21, but a large input power cannot be expected by the barrier discharge.

Even for finely machined optical system or medical instrument such as an endoscope, which includes metallic components, because the duty ratio can be set to be around 10⁻⁷ to 10⁻¹ according to the surface treatment apparatus related to the first embodiment, metallic components will not rise to a considerable high temperature, and the optical system can overcome the problem that warp or misalignment is generated by thermal effect of the plasma.

When a treatment object 21 made of dielectric material is inserted between the first main electrode 11 and the second main electrode 12, implementing a parallel plate configuration, and if dielectric constant ε₂ of the dielectric material is larger than dielectric constant ε₁ of gas (relative dielectric constant=1), the approximate electric field distribution can be represented as shown in FIG. 5. As for the electric field strength around the centerline extending vertically along the center of the first main electrode 11 and the second main electrode 12 of FIG. 5, as illustrated by approximately parallel straight lines in FIG. 5, the electric field in the inside of the treatment object 21 made of dielectric material becomes the same of the electric field in the outside of the treatment object 21.

Because the dielectric breakdown field depends upon the size of space, or if the ambient pressure at inside and outside of the treatment object 21 is the same, the dielectric breakdown field becomes large in the inside of the treatment object 21. Therefore, it is necessary to reduce the dielectric breakdown field in the treatment object 21, by an appropriate method, to generate discharge in the inside of the treatment object 21. One method is to reduce gas pressure in the inside of the treatment object 21, for discharge in the right side region of Paschen's curve.

### Second Embodiment

As shown in FIG. 6, a surface treatment apparatus related to a second embodiment of the present invention encompasses a process chamber (23, 53, 54, 62) establishing a closed space enclosing the surrounding of the treatment object 21; a first main electrode 11b as an anode; a second main electrode 12 as a cathode; and an ambient gas adjusting means (62, 65, 66b, 25b) incorporating the first main electrode 11b therein, for supplying the process gas in the process chamber (23, 53, 54, 62), from the first main electrode 11b like a shower toward the second main electrode 12, and evacuating the shower of the process gas from a part of the process chamber (23, 53, 54, 62). The main pulse of duty ratio of 10⁻⁷ to 10⁻¹ is applied across the first main electrode 11b and second main electrode 12, and an outer surface of the treatment object 21 is treated in non-thermal equilibrium plasma.

In the surface treatment apparatus related to the second embodiment, the treatment object 21 has a tubular geometry made of dielectric material as shown in FIG. 6. A pulse power supply 14 applies electric pulses (main pulses) across the first main electrode 11b and the second main electrode 12, which implement a quasi-parallel plate configuration, so that the electric pulse can cause the fine-streamer discharge in the hermetically sealed space, which surrounds the outside of the treatment object 21.

Because a periodic array of T-shaped protrusions, rather than flat slab configuration, is employed for the first main electrode 11b, we will call the electrode configuration shown in FIG. 6 as “quasi-parallel plate configuration” in view of the situation such that each of discharge points originates at each tips of the T-shaped protrusions, and all of the tips of the T-shaped protrusion are arranged on a singe plane so as to implement a virtual flat slab. In this case the first main electrode 11b is equivalent to an array of bar-shaped linear) electrodes arranged in parallel so as to implement a ladder, and the ladder can implement an approximately “parallel plate configuration” with the second main electrode 12.

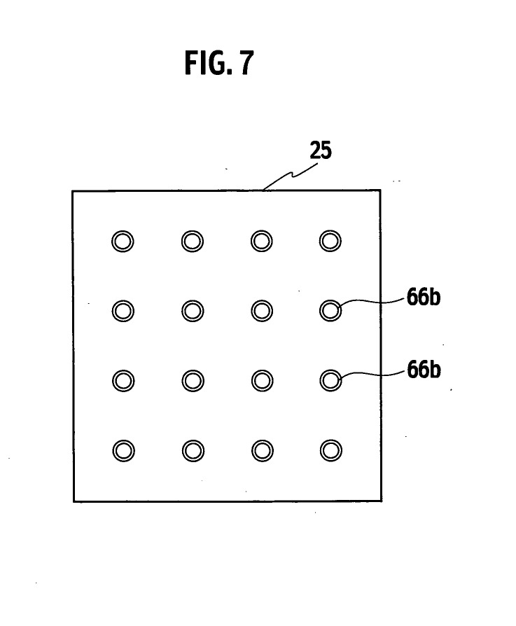

In addition, as the allocations of the exhaust pipe 63 to be connected to the process chamber (23, 53, 54, 62), any site of the process chamber, rather than the downstream side of the treatment object 21 shown in FIG. 6 can be employed. As shown in FIG. 6, the ambient gas adjustment mechanism (62, 65, 66b, 25b) embraces an injection-adjusting chamber 62, a gas supply layer 65 connected to injection-adjusting chamber 62, the first electrode protection layer (first main electrode protection layer) 25b. The gas supply layer 65 has a plurality of gas supply holes 66b arranged in a matrix form as shown in FIG. 7. The gas supply layer 65, which is made of porous ceramics, makes the flow of the treatment gas uniform. Six planes, which establish a flat rectangular parallelepiped, implement injection-adjusting chamber 62, the five planes out of six planes are made of metallic material and the remaining one plane (in a cross-sectional view shown in FIG. 6, the left side plane) is substituted by the gas supply layer 65.

The ambient gas adjustment mechanism (62, 65, 66b, 25b) is implemented by a plurality of taper-shaped gas supply holes 66b penetrating through the first electrode protection layer (first main electrode protection layer) 25b, as shown in FIG. 7, the gas supply holes 66b are arranged in a form of two-dimensional matrix with a predetermined pitch. On the other hand, on the second electrode (second main electrode) 12, a second electrode-covering insulator (second main electrode-covering insulator) 23 made of high purity quartz is disposed.

The process chamber (23, 53, 54, 62) embraces four planes assigned to a rectangular parallelepiped, embraces the second electrode-covering insulator (second main electrode-covering insulator) 23, a chamber bottom lid 53, a chamber top lid 54 and an injection-adjusting chamber 62, and two side plates at a rearward portion of the paper (not illustrated) and at the near side (not illustrated) of the paper of FIG. 6, implement remaining two planes assigned to the planes of the rectangular parallelepiped. To the chamber top lid 54 and the chamber bottom lid 53, a top treatment object holder 52 and a bottom treatment object holder 51 are attached, respectively, so as to implement a hermetically sealed space. To establish the hermetically sealed space, the top treatment object holder 52 configured to hold the upstream end of the treatment object 21 is connected to the chamber top lid 54, and the bottom treatment object holder 51 configured to hold the downstream end of the treatment object 21 is connected to the chamber bottom lid 53. Depending on materials, geometry and size of the treatment object 21, by applying required changes and modifications appropriately, the structure of the top treatment object holder 52 and the bottom treatment object holder 51 can be designed and manufactured with well-known architecture pertaining to gas joints or vacuum components, easily.

Furthermore, as shown in FIG. 6, the surface treatment apparatus related to the second embodiment embraces a gas source 33 such as a gas cylinder configured to store process gas, a feed pipe 61 connected to the gas source 33, and a feed valve 41 connected to the feed pipe 61. In addition, although the illustration is omitted, to at least one of the top treatment object holder 52 and the bottom treatment object holder 51, the valve for gas introduction may be provided.

In the process chamber (23, 53, 54, 62), through the feed pipe 61, feed valve 41 and the injection-adjusting chamber 62, process gas is supplied from gas source 33, and the flow of the process gas is shaped into the configuration of a uniform shower by the ambient gas adjustment mechanism (62, 65, 66b, 25b). The process gas supplied to inside of the process chamber (23, 53, 54, 62) from the ambient gas adjustment mechanism (62, 65, 66b, 25b) is exhausted by the exhaust pipe 63 from the process chamber (23, 53, 54, 62).

Therefore, as shown in FIG. 6, a vacuum pump 31 configured to evacuate the process chamber (23, 53, 54, 62) through the exhaust pipe 63 connected to the process chamber at downstream side of the tubular treatment object 21 is provided to the surface treatment apparatus related to the second embodiment. The vacuum pump 31, through the exhaust pipe 63 and the exhaust valve 42, is connected to the process chamber (23, 53, 54, 62). It is preferable, for the exhaust valve 42, to use the variable conductance valve through which the exhaust conductance can be adjusted.

In FIG. 6, the case that the second main electrode 12 is grounded so as to function as the cathode, while high voltage is applied to the first main electrode 11b so as to function as an anode is illustrated. Polarity of the pulse power supply 14 can be reversed, such that the first main electrode 11b is assigned as the cathode, and the second main electrode 12 is assigned as the anode. When the first main electrode 11b is assigned as the cathode, the first main electrode 11b is grounded as a slab-shaped electrode, and a high voltage is applied to the second main electrode 12, and the ambient gas adjustment mechanism (62, 65, 66b, 25b) is provided to the second main electrode 12.

Similar to the first embodiment, a narrow tube having an inside diameter of less than or equal to 7-5 milimeters and a length of more than 4-7 meters may be used as the tubular treatment object 21 in the surface treatment apparatus related to the second embodiment. However, if the length is equal to or less than 4 meters, and the inside diameter is more than 7 millimeters, the tube can be similarly processed. In addition, a cross-section of the treatment object 21 is not limited to a circular geometry, as already explained in the first embodiment.

Although the illustration is omitted, if the treatment object 21 is a flexible long-narrow tube, by providing first and second reels which roll up the treatment object 21, downstream end of the treatment object 21 may be rewound from the first reel so that upstream end of the treatment object 21 can be rolled up by the second reel, and a plurality of partial surface treatments at the outside of the treatment object 21 can be executed sequentially so as to achieve a full length treatment along the flexible long-narrow tube.

In the surface treatment apparatus related to the second embodiment, a high purity nitrogen gas could be supplied as the process gas through the ambient gas adjustment mechanism (62, 65, 66b, 25b) in a shape of a shower, however the “process gas” is not limited to nitrogen gas. For example, for pasteurize or sterilize the outer surface of the treatment object 21, nitrogen gas being mixed with various kinds of active gas, which may include halogen based compound gas, can be adopted.

High voltage pulses having duty ratio of 10⁻⁷ to 10⁻¹ are applied across the first main electrode 11b and the second main electrode 12. FIG. 4A shows an example of pulse width spanning in a range of 10-500 nano seconds, which is preferable for the main pulse. When, in the surface treatment apparatus related to the second embodiment, if a distance between the first main electrode 11b and the second main electrodes, implementing a quasi-parallel plate configuration, is 15 millimeters, the high voltage pulse having a repetition frequency of 2 kHz and a voltage value of around 24 kV is preferred.

Because the period of the high voltage pulse is 500 microseconds, as shown in FIG. 4A, and the corresponding repetition frequency is determined to be 2 k Hz for the high voltage pulse, the duty ratio becomes 0.3/500=0.006, therefore, non-thermal equilibrium low temperature plasma is generated efficiently and stably, without generating heat plasma ascribable to the high frequency discharge. A reasonable pulse width has a close relation to the distance between e anode and cathode. From the start, along with the voltage application time, the discharge progress from the glow discharge to the streamer discharge, from the streamer discharge to the fine-streamer discharge, and from the fine-streamer discharge to the arc discharge. A discharge, which can maximize the plasma-input power, without reaching to the arc discharge, which is accompanied by high electric current, thermal dissipation and loss of electrode, is considered to be the fine-streamer discharge. Therefore, there is an appropriate pulse width to generate the fine-streamer discharge. It is ideal that the distance between anode and cathode, the discharged condition should be adjusted so that there is no application of voltage pulses, before reaching to the arc discharge.

To generate the discharge in the hermetically sealed space surrounding the outside of the treatment object 21, the feed valve 41 and the exhaust valve 42 are adjusted so that internal gas pressure P2 of the process chamber (23, 53, 54, 62) is equal to the atmospheric pressure P3=101 kPa, or around 80-90 kPa, which is slightly lower than the atmospheric pressure P3. Under the condition such that, in the process chamber (23, 53, 54, 62), through the feed pipe 61 and the feed valve 41, the process gas is supplied from the gas source 33, if high voltage pulses with high repetition rate as shown in FIGS. 4A and 4B are applied across the first main electrode 11b and the second main electrode 12, while the process gas is supplied as a shower by the ambient gas adjustment mechanism (62, 65, 66b, 25b), the non-thermal equilibrium low temperature plasma is generated in the inside of the process chamber (23, 53, 54, 62) by the fine-streamer discharge, the surface treatment of the outside of the treatment object 21 is achieved.

### First Modification of the Second Embodiment

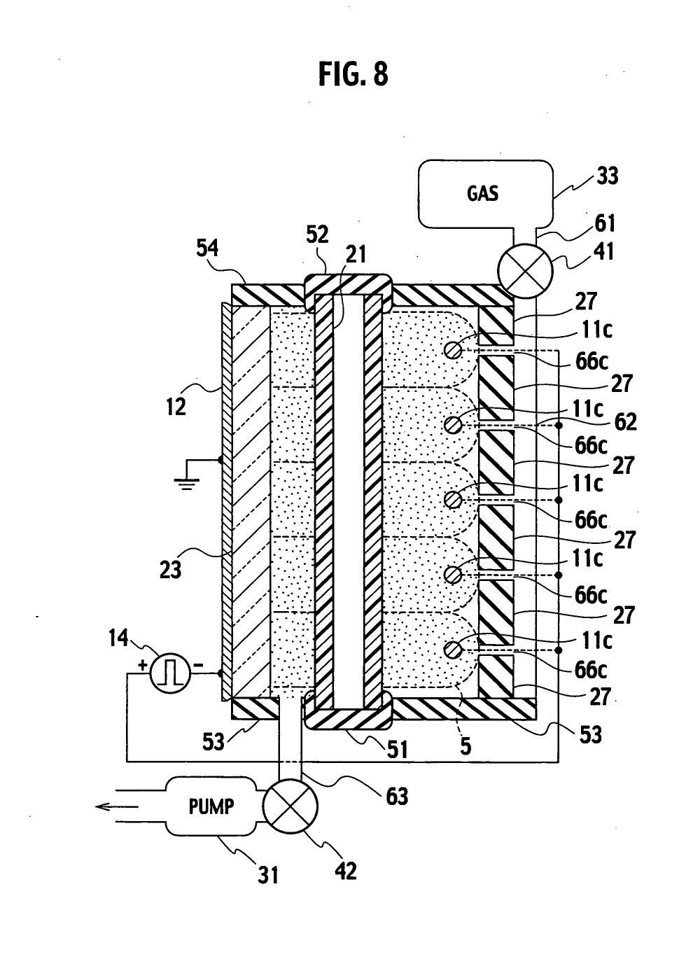

As shown in FIG. 8, a surface treatment apparatus related to a modification of the second embodiment of the present invention encompasses a process chamber (23, 53, 54, 62) establishing a closed space enclosing the surrounding of the treatment object 21; a first main electrode 11b as an anode; a second main electrode 12 as a cathode; and an ambient gas adjusting means (62, 27, 66c) incorporating the first main electrode 11b therein, for supplying the process gas in the process chamber (23, 53, 54, 62), from the first main electrode 11c like a shower toward the second main electrode 12, and evacuating the shower of the process gas from a part of the process chamber (23, 53, 54, 62). The main pulse is applied across the first main electrode 11c and second main electrode 12, and the outside of the treatment object 21 is treated in non-thermal equilibrium plasma.

An array of first main electrodes 11c implement a periodic ladder structure, which arranges a plurality of bar (linear) electrodes in parallel as shown in FIG. 8, can be regarded as “quasi-parallel plate configuration” with the second main electrode 12. Similar to the configuration shown in FIG. 6, the process chamber (23, 53, 54, 62) embraces four planes assigned to a rectangular parallelepiped, embraces the second electrode-covering insulator (second main electrode-covering insulator) 23 and the process chamber bottom lid 53, the chamber top lid 54 and the injection-adjusting chamber 62, two side plates at a rearward portion of the paper (not illustrated) and at the near side (not illustrated) of the paper of FIG. 8, implement remaining two planes assigned to the planes of the rectangular parallelepiped.

The second main electrode 12 serves as the cathode, and the surface treatment apparatus related to the first modification of the second embodiment supplies the process gas as a shower from the first main electrode 11c serving as the anode, the structure of the ambient gas adjustment mechanism (62, 27, 66c) to exhaust the process gas from the exhaust pipe 63 is different from the process chamber (23, 53, 54, 62) shown in FIG. 6.

The ambient gas adjustment mechanism (62, 27, 66c) embraces a process chamber side wall 27, to which a plurality of gas supply holes 66c are provided, and an injection-adjusting chamber 62, the process gas is injected from the injection-adjusting chamber 62 as shown in FIG. 8. Because a plurality of bar-shaped first main electrode 11c made of metallic material such as tungsten (W), or austenitic nickel (Ni) based alloy such as Inconel™, which may include iron (Fe), chromium (Cr), niobium (Nb) or molybdenum (Mo) in the Ni based alloy, are exposed to the discharge space, the contamination by metal must be considered. However, for the applications in which the contamination by metal will not cause serious problems, because the structure shown in FIG. 6 is simple, it can achieve a technical advantage such that the first main electrode 11c can be manufactured at lower cost.

The plurality of gas supply holes 66c are arranged in a two-dimensional matrix with a uniform pitch, the gas supply holes 66c penetrate through the process chamber side wall 27, as shown in FIG. 7. On the other hand, on the second electrode (second main electrode) 12, a second electrode-covering insulator (second main electrode-covering insulator) 23 made of high purity quartz is disposed.

Furthermore, the surface treatment apparatus related to the first modification of the second embodiment embraces a gas source 33 such as a gas cylinder configured to store process gas, a feed pipe 61 connected to the gas source 33, a feed valve 41 connected to the feed pipe 61 as shown in FIG. 8. It is preferable to adopt needle valves facilitating the adjustment of the flow rate for the feed valve 41.

In the process chamber (23, 53, 54, 62), through the feed pipe 61 and the feed valve 41, process gas is supplied from the gas source 33, and the flow of the process gas is shaped into the configuration of uniform shower by the ambient gas adjustment mechanism (62, 27, 66c). The process gas supplied by the ambient gas adjustment mechanism (62, 27, 66c) is exhausted by the exhaust pipe 63 from the process chamber (23, 53, 54, 62). Then, as shown in FIG. 8, a vacuum pump 31 configured to evacuate inside of the process chamber (23, 53, 54, 62) at downstream side of the tubular treatment object 21 is provided to the surface treatment apparatus related to the first modification of the second embodiment.

The vacuum pump 31, through the exhaust pipe 63 and the exhaust valve 42, is connected to the process chamber (23, 53, 54, 62). It is preferable for the exhaust valve 42 to use the variable conductance valve through which the exhaust conductance can be adjusted. To establish a hermetically sealed space, a top treatment object holder 52 configured to hold the upstream end of the tubular treatment object 21 is connected to the chamber top lid 54, and a bottom treatment object holder 51 configured to hold the downstream end of the treatment object 21 is connected to the chamber bottom lid 53. Depending on materials, geometry and size of the treatment object 21, by applying required changes and modifications appropriately, the structure of the top treatment object holder 52 and the bottom treatment object holder 51 can be designed and manufactured with well-known architecture pertaining to gas joints or vacuum components, easily.

In FIG. 8, the case in which the second main electrode 12 is grounded so as to serve as the cathode, while a high voltage is applied to the first main electrode 11c, which is used as the anode is illustrated, however the polarity of pulse power supply 14 may be reversed so that the first main electrode 11c can serve as the cathode, and the second main electrode 12 can serve as anode. When the first main electrode 11c is assigned as the cathode, which is grounded, a slab-shaped electrode shall implement the first main electrode 11c so that a high voltage can be applied to the second main electrode 12, and the ambient gas adjustment mechanism (62, 27, 66c) embraces the second main electrode 12.

Similar to the first embodiment, a narrow tube having an inside diameter of less than or equal to 7-5 millimeters and a length of more than 4-7 meters may be used as the tubular treatment object 21 in the surface treatment apparatus related to the first modification of the second embodiment. However, even if the length is less than 4 meters, and the inside diameter is more than 7 millimeters inside diameter, the treatment object 21 can be processed. In addition, a cross-section of the treatment object 21 is not limited to a circular geometry, as already explained in the first embodiment.

Although the illustration is omitted, if the treatment object 21 is a flexible long-narrow tube, by providing first and second reels which roll up the treatment object 21, the treatment object 21 may be rewound from the first reel so that the treatment object 21 can be rolled up by the second reel and a plurality of partial surface treatments at the outside of the treatment object 21 can be executed sequentially so as to achieve a full length treatment along the flexible long-narrow tube.

In the surface treatment apparatus related to the first modification of the second embodiment, a high purity nitrogen gas can be supplied as the process gas through the ambient gas adjustment mechanism (62, 27, 66c), however the “process gas” is not limited to nitrogen gas. For example, for pasteurization or sterilization, nitrogen gas being mixed with various kinds of active gas such as halogen based compound gas can be adopted.

High voltage pulses having duty ratio of 10⁻⁷ to 10⁻¹ are applied to between the first main electrode 11c and the second main electrode 12. FIG. 4A shows a pulse having the pulse width around 10-500 nanoseconds, which is preferable for the main pulse. In the surface treatment apparatus related to the first modification of the second embodiment, if the distance of between the first main electrode 11c and the second main electrode 12, the first main electrode 11c and the second main electrode 12 implement a quasi-parallel plate configuration, is set to be 15 millimeters, a high voltage pulse having a repetition frequency of 2 kHz and a voltage value of around 24 kV may be preferably applied.

Because the period of the high voltage pulse is 500 microseconds, as shown in FIGS. 4A and 4B, and the corresponding repetition frequency is determined to be 2 k Hz for the high voltage pulse, the duty ratio becomes 0.3/500=0.006, therefore, non-thermal equilibrium low temperature plasma is generated efficiently and stably, without generating heat plasma ascribable to the high frequency discharge.

To generate discharge in the hermetically sealed space surrounding the outside of the treatment object 21, the feed valve 41 and the exhaust valve 42 are adjusted so that internal gas pressure P2 of the process chamber (23, 53, 54, 62) is equal to the atmospheric pressure P3=101 kPa, or around 80-90 kPa, which is slightly lower than the atmospheric pressure P3. Under the condition such that, in the process chamber (23, 53, 54, 62), through the feed pipe 61 and the feed valve 41, the process gas is supplied from the gas source 33, if high voltage pulses with high repetition rate as shown in FIGS. 4A and 4B are applied across the first main electrode 11b and the second main electrode 12, while the process gas is supplied as a shower by the ambient gas adjustment mechanism (62, 27, 66c), the non-thermal equilibrium low temperature plasma is generated in the inside of the process chamber (23, 53, 54, 62) by the fine-streamer discharge, the surface treatment of the outside of the treatment object 21 is achieved.

### Second Modification of the Second Embodiment

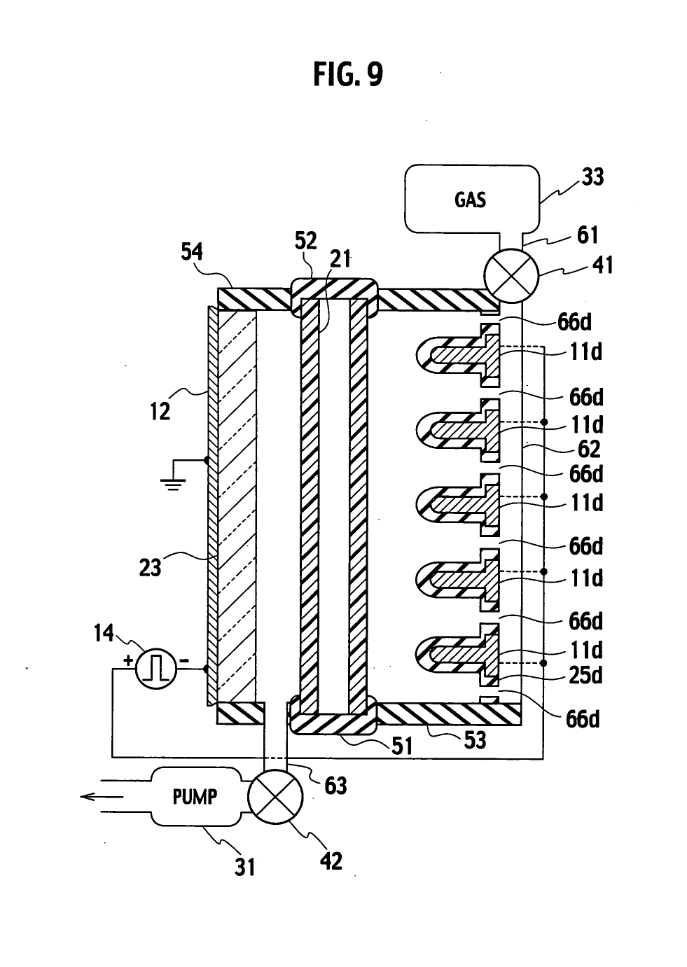

As shown in FIG. 9, a surface treatment apparatus related to a modification of the second embodiment of the present invention encompasses a process chamber (23, 53, 54, 62) establishing a dosed space enclosing the surrounding of the treatment object 21; a first main electrode 11b as an anode; a second main electrode 12 as a cathode; and an ambient gas adjusting means (62, 25d, 66d), incorporating the first main electrode 11c therein, for supplying the process gas in the process chamber (23, 53, 54, 62), from the first main electrode 11c like a shower toward the second main electrode 12, and evacuating the shower of the process gas from a part of the process chamber (23, 53, 54, 62). The main pulse is applied across the first main electrode 11c and second main electrode 12, and the outside of the treatment object 21 is treated in non-thermal equilibrium plasma.

The configuration of the first main electrode 11d such that a plurality of T-shaped protrusions, rather than flat slab configuration, are arranged as shown in FIG. 9 can be regarded as the “quasi-parallel plate configuration”, in view of the situation such that each of discharge points originates at each tips of the T-shaped protrusions of the first main electrode 11d. The second main electrode 12 serves as the cathode, and the surface treatment apparatus related to the second modification of the second embodiment supplies the process gas as a shower from the first main electrode 11d side as the anode. However, the structure of the ambient gas adjustment mechanism (62, 25d, 66d) to exhaust the process gas from the exhaust pipe 63 from the process chamber (23, 53, 54, 62) is different from structure shown in FIG. 6.

In the first modification shown in FIG. 8, contamination by metal was a problem because the first main electrode 11c made of metallic material such as tungsten (W), was exposed in the discharge space, however, in the surface treatment apparatus related to the second modification of the second embodiment of the present invention, because a first electrode protection layer (first main electrode protection layer) 25d made of alumina covers the surface of the first main electrode 11c, the contamination by metal is controlled. The ambient gas adjustment mechanism (62, 25d, 66d) embraces an injection-adjusting chamber 62a, a first electrode protection layer (first main electrode protection layer) 25d, and a plurality of gas supply holes 66d established with the first electrode protection layer, through the gas supply holes 66d the ambient gas is introduced from the injection-adjusting chamber 62a, as shown in FIG. 9. A plurality of gas supply holes 66d are arranged in a configuration similar to the layout shown in FIG. 7, that is, they are arranged in a form of two-dimensional matrix with uniform pitch. On the second electrode (second main electrode) 12, the second electrode-covering insulator (second main electrode-covering insulator) 23 made of high purity quartz is disposed.

Since other functions, configurations, and way of operation are substantially similar to the functions, configurations, and way of operation already explained in the second embodiment with FIG. 6, overlapping or redundant description may be omitted.

### Third Embodiment

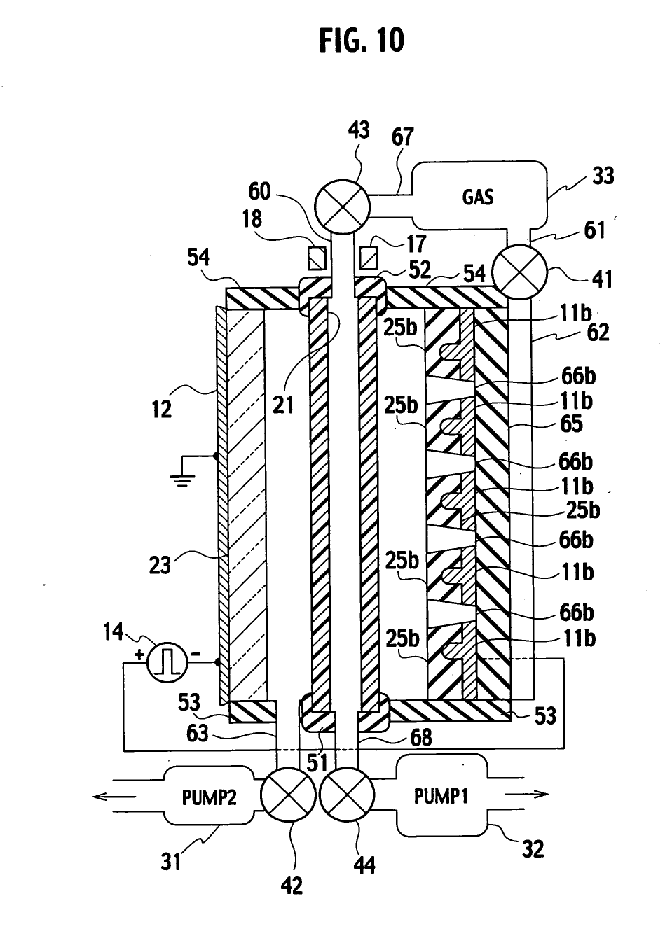

As shown in FIG. 10, a surface treatment apparatus related to a third embodiment of the present invention encompasses a gas introducing system (33, 67, 43, 60) configured to introduce a process gas from upstream end of a tubular dielectric treatment object 21; a first vacuum evacuating system (44, 32) configured to evacuate the process gas from downstream end of the tubular dielectric treatment object 21; an excited particle supplying system (17, 18) disposed at upstream side of the tubular dielectric treatment object 21, configured to supply excited particles for inducing initial discharge in a main body of the tubular dielectric treatment object 21; a first main electrode 11b and a second main electrode 12 disposed oppositely to each other, defining a treating region of the tubular dielectric treatment object 21 as a main plasma generating region disposed therebetween; a process chamber (23, 53, 54, 62) establishing a closed space enclosing the surrounding of the tubular dielectric treatment object 21; an ambient gas adjusting mechanism (62, 65, 66b, 25b), configured to supply the process gas in the process chamber (23, 53, 54, 62), from the first main electrode 11b like a shower toward the second main electrode 12, and evacuating the shower of the process gas from a part of the process chamber (23, 53, 54, 62); and a power supply 14 configured to apply a main pulse across the first main electrode 11b and second main electrode 12 so as to generate a non-thermal equilibrium plasma flow inside the tubular dielectric treatment object 21 and between the first main electrode 11b and second main electrode 12 so that inner and outer surface of the tubular dielectric treatment object 21 can be treated. The process chamber (23, 53, 54,62) establishes a closed space enclosing the surrounding of the tubular dielectric treatment object 21. The first main electrode 11b serves as an anode, and the second main electrode 12 serves as a cathode. The ambient gas adjusting means (62,65, 66b, 25b) incorporates the first main electrode 11b therein, for supplying the process gas in the process chamber (23, 53, 54,62), from the first main electrode 11b like a shower toward the second main electrode 12. The ambient gas adjusting mechanism (62,65, 66b, 25b) has a second vacuum evacuating system (63, 42, 31) configured to evacuate the space enclosing the surrounding of the tubular dielectric treatment object 21. The second vacuum evacuating system (63, 42, 31) evacuates the shower of the process gas from a part of the process chamber (23, 53, 54,62).

In the first main electrode 11b, a plurality of T-shaped protrusions, rather than flat slab configuration, are arranged so as to implement the “quasi-parallel plate configuration” with the second main electrode 12 as shown in FIG. 10. Each of the discharge points originates at each tips of the T-shaped protrusions. In this case, as already explained in the second embodiment, in the light of the configuration of the first main electrode 11b such that the periodical ladder-shaped electrode is implemented by a plurality of bar linear) electrodes, in view of the configuration as a whole, the structure implemented by the first main electrode 11b and the second main electrode 12 can be regarded as approximately “parallel plate configuration”.

The surface treatment apparatus related to the third embodiment encompasses the ambient gas adjustment mechanism (62, 65, 66b, 25b) configured to inject the process gas in a shape of a shower from the first main electrode 11b side, serving as the anode, to the second main electrode 12 side, serving as the cathode, and to exhaust the process gas through the second exhaust pipe 63 from the process chamber (23, 53, 54, 62), which is similar to the surface treatment apparatus related to the second embodiment, but is different from the surface treatment apparatus related to the first embodiment.

The cross-sectional view of the process chamber (23, 53, 54, 62) is illustrated such that, so as to implement four planes assigned to a rectangular parallelepiped, the process chamber (23, 53, 54, 62) embraces a second electrode-covering insulator (second main electrode-covering insulator) 23, a chamber bottom lid 53, a chamber top lid 54 and an injection-adjusting chamber 62. However, two side plates at a rearward portion of the paper and at the near side of the paper of FIG. 10, implementing the remaining two planes assigned to the planes of the rectangular parallelepiped are not illustrated in FIG. 10.

The injection-adjusting chamber 62 has a flat rectangular parallelepiped shape. Among the six planes assigned to each planes of a rectangular parallelepiped, five metallic planes implement the five planes of the rectangular parallelepiped, respectively, and the gas supply layer 65 implements one plane (which corresponds to the left side plane of the gas supply layer 65 in the cross-sectional view shown in FIG. 10). The ambient gas adjustment mechanism (62, 65, 66b, 25b) embraces an injection-adjusting chamber 62, the gas supply layer 65 made of porous ceramics, which facilitate a uniform penetration and/or a uniform distribution of the process gas from the injection-adjusting chamber 62, and a first electrode protection layer (first main electrode protection layer) 25b having a plurality of gas supply holes 66b as shown in FIG. 10. The plurality of taper-shaped gas supply holes 66b penetrate through the first electrode protection layer first main electrode protection layer) 25b, as shown in FIG. 7. The gas supply holes 66b are arranged in a form of two-dimensional matrix with a predetermined pitch. On the other hand, on the second electrode (second main electrode) 12, the second electrode-covering insulator (second main electrode-covering insulator) 23 made of high purity quartz is disposed.

Furthermore, the gas introducing system (33, 67, 43, 60, 61, 41) of the surface treatment apparatus related to the third embodiment embraces a gas source 33 such as a gas cylinder configured to store process gas, a first feed pipe 67 connected to the gas source 33, a second feed pipe 61 connected to the gas source 33, a first feed valve 43 connected to second feed pipe 67, and a second feed valve 41 connected to the second feed pipe 61 as shown in FIG. 10. For the first feed valve 43 and the second feed valve 41, it is preferable to adopt needle valves facilitating the adjustment of the flow rate of the process gas, respectively.

Through the first feed pipe 67 and the first feed valve 43, the process gas is supplied to the upstream side of the tubular dielectric treatment object 21 from the gas source 33, and because the process gas is evacuated by the vacuum pump (second pump) 31 provided at the downstream side of the tubular dielectric treatment object 21, the process gas flows in the tubular dielectric treatment object 21. Inner pressure of the tubular dielectric treatment object 21 is kept at a processing pressure of less than or equal to the atmospheric pressure, for example, around 20-30 kPa. On the other hand, in the process chamber (23, 53, 54, 62), through the second feed pipe 61 and the second feed valve 41, the process gas is supplied from the gas source 33, and the flow of the process gas is shaped into the configuration of uniform shower by the ambient gas adjustment mechanism (62, 65, 66b, 25b).

The process gas supplied by the ambient gas adjustment mechanism (62, 65, 66b, 25b) is exhausted through the second exhaust pipe 63 from the process chamber (23, 53, 54, 62). Then, as shown in FIG. 10, the second vacuum pump (second pump) 31, configured to evacuate the space surrounding the outside of the tubular dielectric treatment object 21 from downstream side of the tubular dielectric treatment object 21, is provided to the surface treatment apparatus related to the third embodiment. The second vacuum pump (second pump) 31 is connected to the second exhaust valve 42, and the second exhaust valve 42 is connected to the second exhaust pipe 63, and the second exhaust pipe 63 is connected to the process chamber (23, 53, 54, 62). On the other hand, the first vacuum pump (first pump) 32 is connected to the first exhaust valve 44, and the first exhaust valve 44 is connected to the first exhaust pipe 68, and the first exhaust pipe 68 is connected to downstream end of the tubular dielectric treatment object 21. It is preferable for the first exhaust valve 44 and the second exhaust valve 42 to use the variable conductance valves through which the exhaust conductance can be adjusted.

To establish the hermetically sealed space, a top treatment object holder 52 configured to hold the upstream end of the tubular dielectric treatment object 21 is connected to the chamber top lid 54, and a bottom treatment object holder 51, configured to hold the downstream end of the tubular dielectric treatment object 21, is connected to the chamber top lid 54. Depending on materials, geometry and size of the tubular dielectric treatment object 21, by applying required changes and modifications appropriately, the structure of the top treatment object holder 52 and the bottom treatment object holder 51 can be designed and manufactured with well-known architecture pertaining to gas joints or vacuum components, easily.

In FIG. 10, because a case that the second main electrode 12 is grounded so as to serve as the cathode, and high voltage is applied to the first main electrode 11b, being used as an anode, is illustrated. However, the polarity of pulse power supply 14 can be reversed such that the first main electrode 11b serves as the cathode, and the second main electrode 12 serves as the anode. When the first main electrode 11b is assigned as the cathode, the first main electrode 11b is made into a slab-shaped electrode; and is grounded, then, the high voltage is applied to the second main electrode 12, which is formed into a ladder type electrode, and the ambient gas adjustment mechanism (62, 65, 66b, 25b) is provided to the second main electrode 12.

Similar to the first embodiment, a narrow tube having an inside diameter of less than or equal to 7-5 millimeters and a length of more than 4-7 meters may be used as the tubular dielectric treatment object 21 in the surface treatment apparatus related to the third embodiment as well, even if the length is equal to or less than 4 meters, and the inside diameter is more than 7 millimeters, the tubular dielectric treatment object 21 can be similarly processed. In addition, a cross-section of the tubular dielectric treatment object 21 is not limited to a circular geometry, as already explained in the first embodiment.

Although the illustration is omitted, if the tubular dielectric treatment object 21 is a flexible long-narrow tube, by providing first and second reels which roll up the tubular dielectric treatment object 21, the tubular dielectric treatment object 21 may be rewound from the first reel so that the tubular dielectric treatment object 21 can be rolled up by the second reel and a plurality of partial internal surface treatment of the tubular dielectric treatment object 21 may be executed sequentially.

In FIG. 10, the excited particle supplying system (17,18) encompasses a first auxiliary electrode 17, a second auxiliary electrode 18, and an auxiliary pulse power supply (although the illustration is omitted) configured to apply a voltage pulse (an auxiliary pulse) across the first auxiliary electrode 17 and the second auxiliary electrode 18 so as to generate initial plasma, the first auxiliary electrode 17 and the second auxiliary electrode 18 sandwich an excitation feed pipe 60 connected to the upstream side of the tubular dielectric treatment object 21 so as to implement a parallel plate configuration, as already explained in the first embodiment. The excitation feed pipe 60 is a pipe made of dielectric material.

In addition, similar to the case of the surface treatment apparatus related to the first embodiment, because it is enough that the initial plasma can be injected in the gas flow in the early stage, the excited particle supplying system may be implemented by any other configuration such as an inductive plasma source which can generate the initial plasma, therefore, the excited particle supplying system is not limited to the parallel plate configuration shown in FIG. 10.

In the surface treatment apparatus related to the third embodiment, a high purity nitrogen gas can be supplied as the process gas in the tubular dielectric treatment object 21 from the upstream side, the “the process gas” is not limited to nitrogen gas. For example, for pasteurization or sterilization against inside and outside of the tubular dielectric treatment object 21, nitrogen gas being mixed with various kinds of active gas such as halogen based compound gas can be adopted.

High voltage pulses having duty ratio of 10⁻⁷ to 10⁻¹ are applied across the first main electrode 11 and the second main electrode 12. FIG. 4A shows pulse width of 10-500 nano seconds, which is preferable for the main pulse. When, in the surface treatment apparatus related to the third embodiment, if a distance between the first main electrode 11b and the second main electrodes, implementing a quasi-parallel plate configuration, is set to be 15 millimeters, the high voltage pulse having a repetition frequency of 2 kHz and a voltage value of around 24 kV is preferred.

Because the period of the high voltage pulse is 500 microseconds, as shown in FIGS. 4A and 4B, and the corresponding repetition frequency is determined to be 2 k Hz for the high voltage pulse, the duty ratio becomes 0.3/500=0.006, therefore, non-thermal equilibrium low temperature plasma is generated efficiently and stably, without generating heat plasma ascribable to the high frequency discharge.

### <Three Operation Modes>

In the surface treatment apparatus related to the third embodiment, there are three operation modes. That is to say, a first mode configured to ignite an discharge only in the inside of the tubular dielectric treatment object 21, a second mode configured to ignite an discharge only at the outside of the tubular dielectric treatment object 21, and a third mode configured to ignite discharges both inside and outside of the tubular dielectric treatment object 21 having tubular geometry.

### (a) First Mode:

As described in the surface treatment apparatus related to the first embodiment, when the tubular dielectric treatment object 21 made of dielectric material is inserted between the first main electrode 11b and the second main electrode 12 implementing a parallel plate configuration, if dielectric constant ε2 of the tubular dielectric treatment object 21 is larger than dielectric constant ε1 of gas, because the electric field distribution can be approximately illustrated as shown in FIG. 5, an dielectric breakdown field becomes large in the tubular dielectric treatment object 21.

Therefore, in order to discharge selectively in the tubular dielectric treatment object 21, it is desirable that the internal gas pressure P1 in the tubular dielectric treatment object 21 is elected to be around 10−40 kPa, which is lower than the gas pressure P2 of the outside of the tubular dielectric treatment object 21.

And it is desirable that the gas pressure P2 of the outside of the tubular dielectric treatment object 21 is elected to be equal to the atmospheric pressure P3=101 kPa, or to be around 80-90 kPa, which is slightly lower than the atmospheric pressure P3. Therefore, the first feed valve 43, the second feed valve 41, the first exhaust valve 44 and the second exhaust valve 42 are adjusted such that the following relation can be satisfied:

P1<P2≦P3 (1).

Alternatively, the gas pressure P1 in the inside of the tubular dielectric treatment object 21 is elected to be around 10−40 kPa, and the gas pressure P2 of the outside of the tubular dielectric treatment object 21 is set to be less than or equal to 10⁻³ Pa to 10⁻⁵ Pa, by adjusting the first feed valve 43, the second feed valve 41, the first exhaust valve 44 and the second exhaust valve 42 may be adjusted so that the following relation can be satisfied:

P2 [symbol] P1<P3 (2).

Because of these requirement for pressure control for example, a pressure gauge is provided to the first exhaust pipe 68 and the second exhaust pipe 63, so that the first feed valve 43, the second feed valve 41, the first exhaust valve 44 and the second exhaust valve 42 can be adjusted by feed-back control. Or, mass-flow controllers configured to control the flow rate may be provided to the first feed pipe 67 and the second feed pipe 61. The first pressure gauge may be provided to each of the downstream side of the first feed valve 43 and the second feed valve 41. After setting the pressure condition as recited by Eq. (1) or (2), the second feed valve 41 and the second exhaust valve 42 are dosed so as to stop the gas-flow at outside of the tubular dielectric treatment object 21 so that the gas-flow is formed only in the inside of the tubular dielectric treatment object 21.

And, after the excited particle supplying system (17,18) is started so that initial plasma is supplied in the gas flow, if high voltage pulses having high repetition rate as shown in FIGS. 4A and 4B are applied across the first main electrode 11 and the second main electrode 12, as the non-thermal equilibrium low temperature plasma is transported in the inside of the tubular dielectric treatment object 21, the surface treatment in the inside of the tubular dielectric treatment object 21 is achieved.

### (b) Second Mode:

In order to generate selectively plasma at the outside of the tubular dielectric treatment object 21, the gas pressure P1 in the inside of the tubular dielectric treatment object 21 is elected to be a relatively higher pressure around 70-90 kPa, which is approximately equal to or a slightly higher than the pressure P2 at the outside of the tubular dielectric treatment object 21. And the gas pressure P2 of the outside of the tubular dielectric treatment object 21 is set to be equal to the atmospheric pressure P3=101 kPa, or around 80-90 kPa, which is slightly lower than the atmospheric pressure P3. Then, the first feed valve 43, the second feed valve 41, the first exhaust valve 44 and the second exhaust valve 42 are adjusted such that:

P1≦P2≦P3 (3).

But, the gas pressure P1 in the inside of the tubular dielectric treatment object 21 is not necessary to be lower than the gas pressure P2 of the outside of the tubular dielectric treatment object 21. That is, the gas pressure P1 in the inside of the tubular dielectric treatment object 21 can be set larger than the atmospheric pressure P3, or approximately equal to the atmospheric pressure P3=101 kPa, while the gas pressure P2 of the outside of the tubular dielectric treatment object 21 is set to be approximately equal to the atmospheric pressure P3, or around 80-90 kPa, which is slightly lower than the atmospheric pressure P3 as:

P2≦P1≈P3 (4)

P2≦P3<P1 (5).

Alternatively, the gas pressure P1 in the inside of the tubular dielectric treatment object 21 can be set to be less than or equal to 10⁻³ Pa to 10⁻⁵ Pa, while the gas pressure P2 of the outside of the tubular dielectric treatment object 21 is set to be equal to the atmospheric pressure P3=101 kPa, or around 80-90 kPa, by adjusting the first feed valve 43, the second feed valve 41, the first exhaust valve 44 and the second exhaust valve 42 so that the flowing condition can be satisfied:

P1 [symbol] P2≦P3 (6).

After controlling these pressures to the corresponding pressure conditions prescribed by Eqs. (3)-(6), the first feed valve 43 and the first exhaust valve 44 are dosed so as to stop the internal gas-flow in the inside of the tubular dielectric treatment object 21. And, in the process chamber (23, 53, 54, 62), via the second feed pipe 61 and the second feed valve 41, process gas is supplied from the gas source 33 in a shape of shower through the ambient gas adjustment mechanism (62, 65, 66b, 25b). Then, the high voltage pulses having high repetition rate as shown in FIGS. 4A and 4B are applied across the first main electrode 11 and the second main electrode 12 so that the non-thermal equilibrium low temperature plasma is generated in the outside of the tubular dielectric treatment object 21 by the fine-streamer discharge, thereby, the surface treatment of the outside of the tubular dielectric treatment object 21 is achieved. In the second mode, generating selectively the discharge cause only at the outside of the tubular dielectric treatment object 21, the excited particle supplying system (17,18) does not operate, of course.

### (c) Third Mode:

In order to generate the discharges in the inside and outside of the tubular dielectric treatment object 21, it is desirable that the gas pressure P1 in the inside of the tubular dielectric treatment object 21 is elected to be around 10−40 kPa, which is lower than the gas pressure P2 of the outside of the tubular dielectric treatment object 21. And the gas pressure P2 of the outside of the tubular dielectric treatment object 21 is set to be approximately equal to the atmospheric pressure P3=101 kPa, or set to be around 80-90 kPa, which is slightly lower than the atmospheric pressure P3 so that the pressure condition as shown by Eq. (1) can be satisfied, by adjusting the first feed valve 43, the second feed valve 41, the first exhaust valve 44 and the second exhaust valve 42.

After controlling the pressure to the corresponding pressure condition as shown by Eq. (1), the excited particle supplying system (17,18) is started so that the initial plasma can be supplied in the gas flow. Simultaneously, in the process chamber (23, 53, 54, 62), the process gas is supplied in the shape of a shower by the ambient gas adjustment mechanism (62, 65, 66b, 25b). If the high voltage pulses having high repetition rate as shown in FIGS. 4A and 4B are applied across the first main electrode Hand the second main electrode 12, the non-thermal equilibrium low temperature plasma is transported in the inside and at the outside of the tubular dielectric treatment object 21 so that the surface treatment in the inside and at the outside of the tubular dielectric treatment object 21 can be achieved, simultaneously.

### Fourth Embodiment

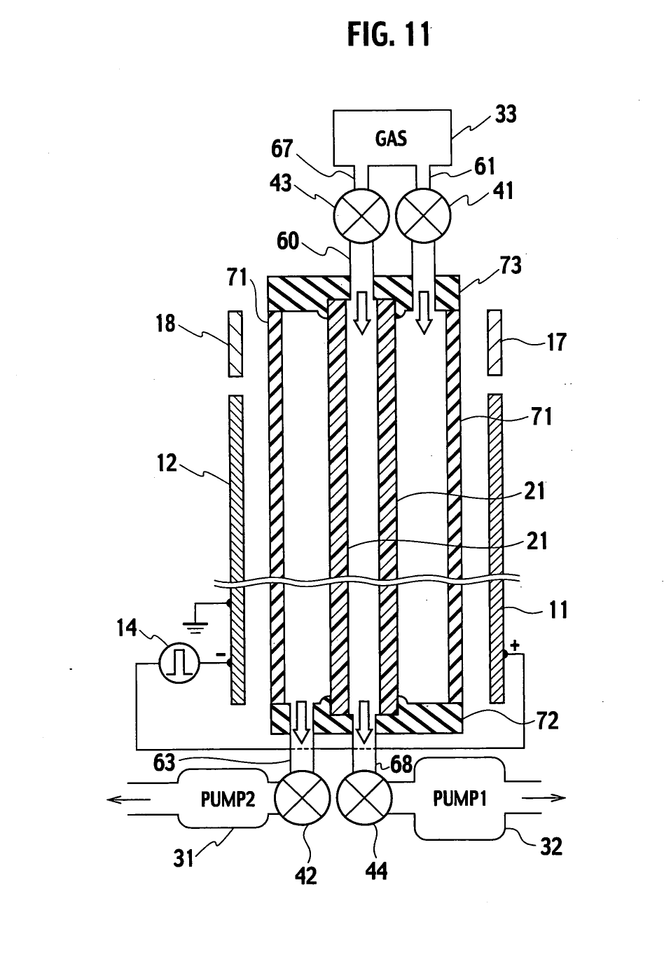

A surface treatment apparatus related to a fourth embodiment of the present invention encompasses an accommodation tube 71 configured to accommodate a dielectric treatment object 21 of tubular geometry, or a long-narrow tube, as shown in FIG. 11, so that the flows of the plasma are supplied in the inside of the tubular dielectric treatment object 21 and at outside of the tubular dielectric treatment object 21, thereby the inside and the outside of the tubular dielectric treatment object 21 care processed simultaneously.

That is to say, the surface treatment apparatus related to the fourth embodiment embraces a gas cylinder configured to store process gas, a first feed valve 43 connected through the first feed pipe to the gas source 33, and a second feed valve 41 connected through the second feed pipe to the gas source 33.

Through the first feed pipe 67 and the first feed valve 43, the process gas is supplied to the upstream side of the tubular dielectric treatment object 21 from the gas source 33, and because the process gas is evacuated by the vacuum pump (first pump) 32 provided at the downstream side of the tubular dielectric treatment object 21, the process gas flows in the tubular dielectric treatment object 21. Inner pressure of the tubular dielectric treatment object 21 is kept at a processing pressure of less than or equal to the atmospheric pressure, for example, around 20-30 kPa.

On the other hand, in the process chamber (71, 72, 73) implemented by the accommodation tube 71, through the second feed pipe 61 and the second feed valve 41, the process gas is supplied from the gas source 33, and because the process gas is evacuated by the vacuum pump (second pump) 31 provided at the downstream side of the accommodation tube 71, the process gas flows in a space between the tubular dielectric treatment object 21 and the accommodation tube 71. Inner pressure of the accommodation tube 71 is kept at a processing pressure of less than and approximately equal to the atmospheric pressure, for example, around 80-90 kPa.

A top accommodating cap 73 and a bottom accommodating cap 72 are connected to the upper end and the bottom end of the accommodation tube 71, respectively, so that the space between the inner wall of the accommodation tube 71 and the outer wall of the tubular treatment object 21 can be vacuum evacuated, thereby a hermetically sealed space with double pipe structure is implemented.

Furthermore, the surface treatment apparatus related to the fourth embodiment embraces a first main electrode 11b, a second main electrode 12 facing to the first main electrode 11b so as to sandwich the treatment object 21, implementing a parallel plate configuration, a first auxiliary electrode 17 and a second auxiliary electrode 18 facing to the first auxiliary electrode 17 so as to sandwich the upstream side of the treatment object 21, implementing a parallel plate configuration.

It is desirable that, in order to generate discharges both in the inside of and at the outside of the tubular dielectric treatment object 21, the gas pressure P1 in the inside of the tubular dielectric treatment object 21 is elected to be around 10-40 kPa, which is slightly lower than the gas pressure P2 between the accommodation tube 71 and the tubular dielectric treatment object 21. And, it is desirable that the gas pressure P2 between the accommodation tube 71 and the tubular dielectric treatment object 21 is set to be equal to the atmospheric pressure P3=101 kPa, or around 80-90 kPa, which is slightly lower than the atmospheric pressure P3, by adjusting the first feed valve 43, the second feed valve 41, the first exhaust valve 44 and the second exhaust valve 42.

After controlling these pressures to the predetermined pressure conditions, the excited particle supplying system (17,18) is started so as to supply provide initial plasmas to the gas flow in the hermetically sealed space between the outside of the tubular dielectric treatment object 21 and accommodation tube 71 and to the gas flow in the inside of the tubular dielectric treatment object 21, thereafter, if high voltage pulses having high repetition rate as shown in FIGS. 4A and 4B are applied across the first main electrode 11 and the second main electrode 12, the non-thermal equilibrium low temperature plasmas are transported in the inside of the tubular dielectric treatment object 21 and the outside of the tubular dielectric treatment object 21 so that the surface treatments in the inside of and at the outside of the tubular dielectric treatment object 21 are achieved simultaneously.

### Fifth Embodiment

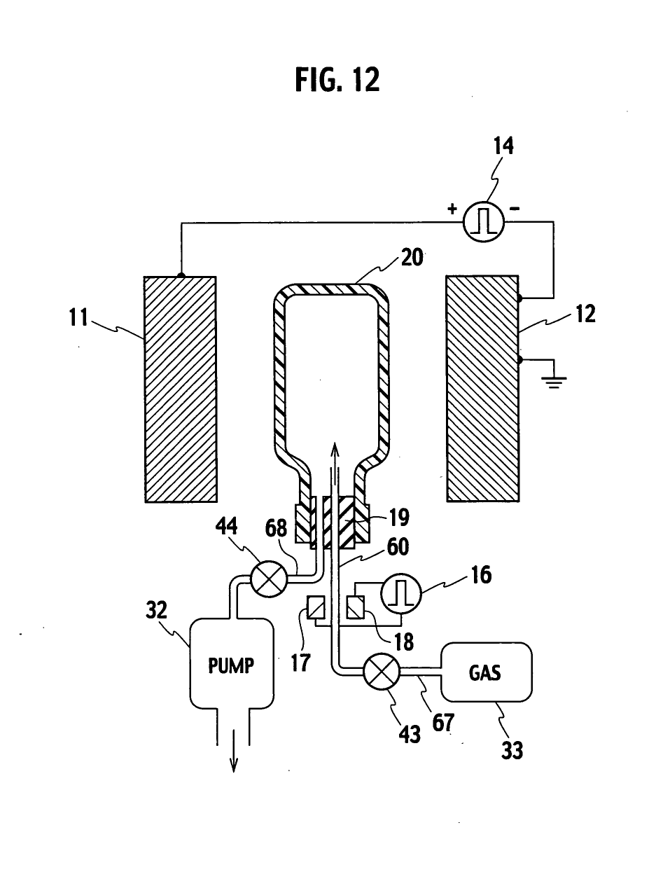

As shown in FIG. 12, a surface treatment apparatus related to a fifth embodiment of the present invention embraces a vacuum evacuating system (32, 44, 68) configured to evacuate a process gas introduced at a specific flow rate from an excitation feed pipe 60 provided at a first end of a tubular treatment object 20 having a blind wall at a second end, from an exhaust pipe 68 provided at the first end, and maintaining the pressure of the process gas inside the treatment object 20 at a process pressure; an excited particle supplying system (16, 17, 18) disposed at upstream side of the treatment object 20, configured to supply excited particles for inducing initial discharge in a main body of the treatment object 20; and a first main electrode 11 and a second main electrode 12 disposed oppositely to each other, defining a treating region of the treatment object 20 as a main plasma generating region disposed therebetween.

A pot or bottle made of dielectric material can serve as the treatment object 20, and a neck adapter 19 is inserted in the neck of the pot-shaped treatment object 20, the neck is allocated at the first end of the pot-shaped treatment object 20. A excitation feed pipe 60 and an exhaust pipe 68 penetrate through the neck adapter 19 in parallel. The excitation feed pipe 60 is a hollow cylinder or a narrow tube made of dielectric material.

The process gas is introduced in the inside of the pot-shaped treatment object 20 by the excitation feed pipe 60 so that the process gas can be exhausted from the exhaust pipe 68. The first main electrode 11 and the second main electrode 12, implement a parallel plate configuration, by facing each other so as to sandwich the pot-shaped treatment object 20.

In one part of the excitation feed pipe 60, an excited particle supplying system (16, 17, 18) configured to supply initial plasma in the gas flow for stating the discharge is provided. The excited particle supplying system (16, 17, 18) is driven at least until generation of main plasma. The excited particle supplying system (16, 17, 18) embraces a first auxiliary electrode 17, a second auxiliary electrode 18, an auxiliary pulse power supply 16 configured to apply an electric pulse (an auxiliary pulse) across the first auxiliary electrode 17 and the second auxiliary electrode 18 so as to generate an initial plasma. The first auxiliary electrode 17 and the second auxiliary electrode 18 implement a parallel plate configuration. On the other hand, the pulse power supply 14 supplies an electric pulse (main pulse) across the first main electrode 11 and the second main electrode 12 to maintain the plasma in the inside of the pot-shaped treatment object 20, which is initiated by the initial plasma.

High voltage pulses having duty ratio of 10⁻⁷ to 10⁻¹ are applied. FIG. 4A shows a case that a pulse width is 300 nano seconds, however, a pulse width of 10-500 nano seconds is preferable for the main pulse. Alternatively, the main pulse of duty ratio of 10⁻⁷ to 10⁻¹ can be applied across the first main electrode 11 and second main electrode 12 so as to generate a non-thermal equilibrium plasma flow inside the treatment object 20.

In FIG. 12, the case that the second main electrode 12 is grounded so as to serve as a cathode so that a high voltage can be applied to the first main electrode 11, which is used as an anode, is illustrated. However, the polarity of pulse power supply 14 can be reversed such that the first main electrode 11 serves as the cathode, while the second main electrode 12 serves as the anode.

Furthermore, in the surface treatment apparatus related to the fifth embodiment, a feed valve 43 is connected to the excitation feed pipe 60, a feed pipe 67 is connected to the feed valve 43, a gas source 33 such as a gas cylinder configured to store process gas is connected to the feed pipe 67. It is preferable to adopt needle valves facilitating the adjustment of the flow rate as the feed valve 43.

On the other hand, the process gas introduced by the excitation feed pipe 60 is exhausted vacuum pump 32. Therefore, an exhaust valve 44 is provided to the exhaust pipe 68, and the vacuum pump 32 is connected to the exhaust valve 44, so that the exhaust valve 44 can control the pressure to an appropriate processing pressure, when the gas flow is introduced in the pot-shaped treatment object 20. It is preferable for the exhaust valve 44 to use the variable conductance valve through which the exhaust conductance can be adjusted.

The process gas is supplied from the gas source 33 in the inside of the pot-shaped treatment object 20 through the excitation feed pipe 60, which is inserted in the neck of the pot-shaped treatment object 20, such that the pressure is controlled at around 20-30 kPa, which is near the atmospheric pressure, but less than the atmospheric pressure, exhausting the process gas from the pot-shaped treatment object 20, by the vacuum pump 32 through the exhaust pipe 68 that is inserted in the neck of the pot-shaped treatment object 20.

When, in the surface treatment apparatus related to the fifth embodiment, if a distance between the first main electrode 11 and the second main electrode 12, implementing a parallel plate configuration, is set to be 15 millimeters, the high voltage pulse having a repetition frequency of 2 kHz and a voltage value of around 24 kV is preferably applied across the first main electrode 11 and the second main electrode 12.

Because the period of the high voltage pulse is 500 microseconds, as shown in FIGS. 4A and 4B, and the corresponding repetition frequency is determined to be 2 k Hz for the high voltage pulse, the duty ratio becomes 0.3/500=0.006, therefore, non-thermal equilibrium low temperature plasma is generated efficiently and stably, without generating heat plasma ascribable to the high frequency discharge.

In the surface treatment apparatus related to the fifth embodiment, a high purity nitrogen gas can be supplied as the process gas in the pot-shaped treatment object 20 from the neck, the “the process gas” is not limited to nitrogen gas. For example, for pasteurize or sterilize inside of the pot-shaped treatment object 20, nitrogen gas being mixed with various kinds of active gas, which may include halogen based compound gas, can be adopted. In addition, as already described in the first embodiment, a cross-section of the pot-shaped treatment object 20 cut along the horizontal plane in FIG. 12 is not limited to a circle, but another geometry such as rectangular cross-sectional shape can be employed, for example.

In addition, as generic concept of “the pot-shaped treatment object” in the fifth embodiment, in addition to the pot or bottle like shape as shown in FIG. 12, a long-narrow tube having a blind wall at the second end of the treatment object 20 is included.

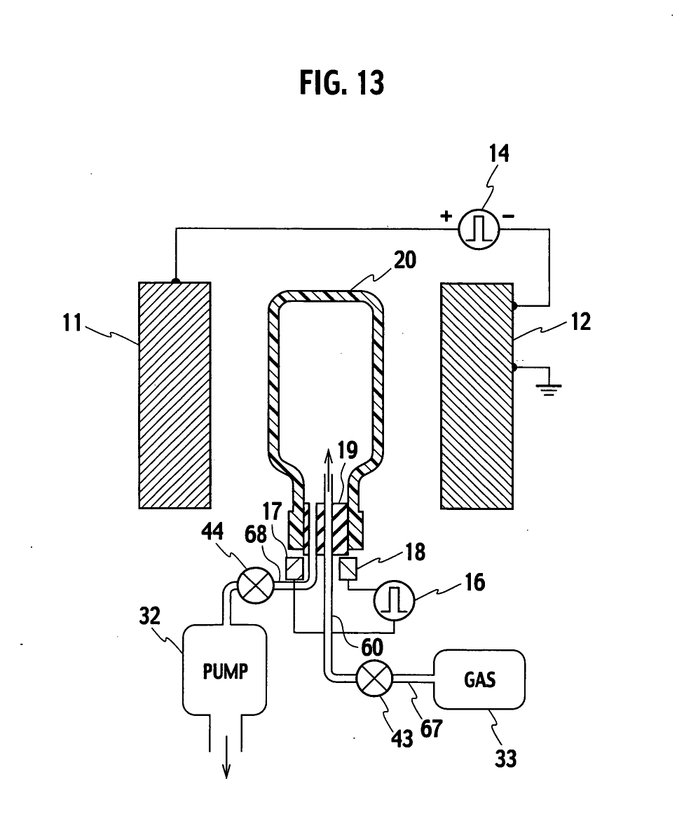

In FIG. 12, an example such that the first auxiliary electrode 17 and the second auxiliary electrode 18 implementing the excited particle supplying system (16, 17, 18) are established at the position where the location of the exhaust pipe 68 is not included is shown, however, the first auxiliary electrode 17 and the second auxiliary electrode 18 may be disposed at a position where both of the exhaust pipe 68 and the excitation feed pipe 60 are aligned so as to sandwich the exhaust pipe 68 and the excitation feed pipe 60 in between the first auxiliary electrode 17 and the second auxiliary electrode 18 as shown in FIG. 13.

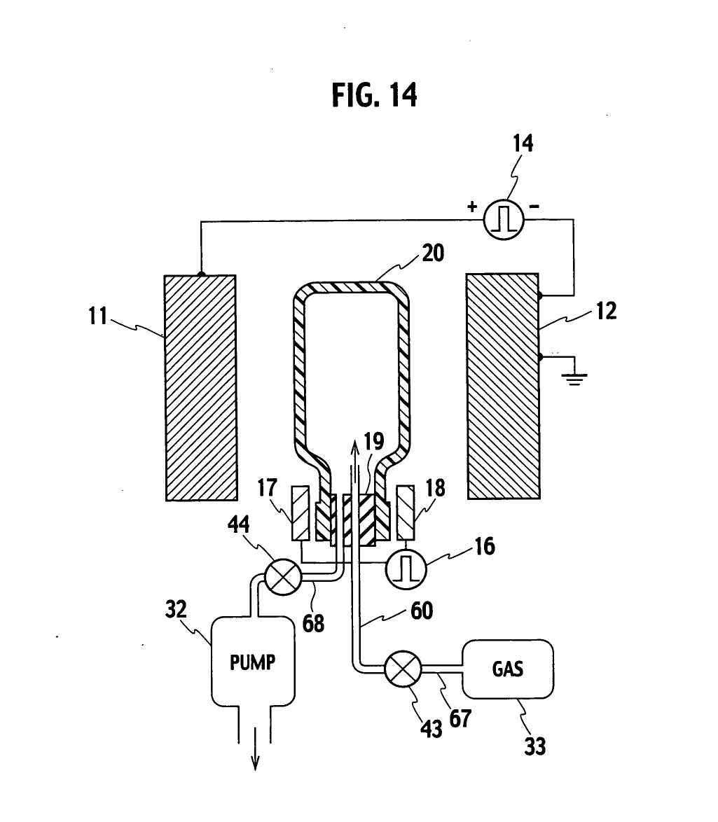

Furthermore, the first auxiliary electrode 17 and the second auxiliary electrode 18 may be disposed at a position where the first auxiliary electrode 17 and the second auxiliary electrode 18 can sandwich the neck adapter 19 as shown in FIG. 14.

In addition, similar to the case of the surface treatment apparatus related to the first and the third embodiments, because it is enough that the initial plasma can be injected in the gas flow in the early stage, the excited particle supplying system (16, 17, 18) may be implemented by any other configuration such as an inductive plasma source which can generate the initial plasma, therefore, the excited particle supplying system (16, 17, 18) is not limited to the parallel plate configuration shown in FIG. 12 to FIG. 14.

### Sixth Embodiment

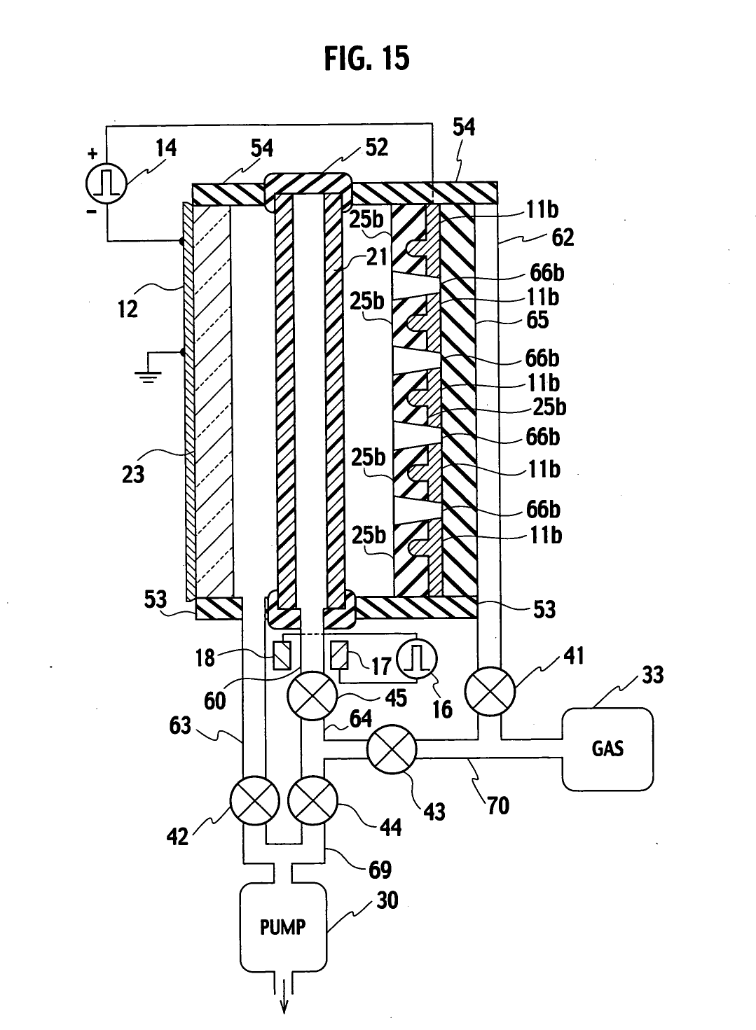

As shown in FIG. 15, a surface treatment apparatus related to a sixth embodiment of the present invention embraces a vacuum manifold unit (43,44,45,60,64,69,70) connected to a first end (a lower side end in FIG. 15) of a tubular treatment object 21 made of dielectric, the tubular treatment object 21 has a blind wall at a second end (an upper side end in FIG. 15) of the tubular treatment object 21, for confining hermetically process gas at specified pressure inside of the treatment object 21 from the first end, an excited particle supplying system (16,17,18) disposed at the first end side, configured to supply excited particles for inducing initial discharge in a main body of the treatment object 21; and a first main electrode 11b and a second main electrode 12 disposed oppositely to each other, defining a treating region of the treatment object as a main plasma generating region disposed therebetween,

The vacuum manifold unit (43,44,45,60,64,69,70) embraces a the excitation feed pipe 60 connected to the first end of the treatment object 21; a manifold valve 45 connected to and the excitation feed pipe 60; a T-shaped pipe 64 connected to the manifold valve 45; a first feed valve 43 and first exhaust valve 44 connected to the T-shaped pipe 64; a feed pipe 70 connected to the first feed valve 43; and an exhaust pipe 69 connected to the first exhaust valve 44. The excitation feed pipe 60 is a hollow cylinder or a narrow tube made of dielectric material. A gas source 33 is connected to feed pipe 70, and a vacuum pump 30 is connected to the exhaust pipe 69. The gas source 33 is a gas cylinder storing process gas. The first feed valve 43 can adopt a needle valve, which facilitate adjustment of the flow rate of the process gas.

The process chamber (23, 53, 54, 62) is connected to a second feed valve 41, and the second feed valve 41 is connected to the feed pipe 70 so that the process gas can be supplied from the gas source 33 to in the inside of the process chamber (23, 53, 54, 62). The process chamber (23, 53, 54, 62) embraces four planes assigned to a rectangular parallelepiped, embraces a second electrode-covering insulator (second main electrode-covering insulator) 23, a process chamber bottom lid 53, a process chamber top lid 54 and an injection-adjusting chamber 62. Similar to the third embodiment, a side plate at a rearward portion of the paper (not illustrated) and another side plate at the near side (not illustrated) of the paper of FIG. 15, implement remaining two planes assigned to the planes of the rectangular parallelepiped. The injection-adjusting chamber 62 has a flat rectangular parallelepiped shape. Among the six planes assigned to each planes of a rectangular parallelepiped, five metallic planes implement the five planes of the rectangular parallelepiped, respectively, and the gas supply layer 65 implements one plane (which corresponds to the left side plane of the gas supply layer 65 in the cross-sectional view shown in FIG. 15). A second exhaust pipe 63 is connected to the process chamber (23, 53, 54, 62), a second exhaust valve 42 is connected to the second exhaust pipe 63, and a vacuum pump 30 is connected to the second exhaust valve 42 through the exhaust pipe 69. It is preferable, as the first exhaust valve 44 and the second exhaust valve 42, to use the variable conductance valves through which the exhaust conductance can be adjusted.

At first, in the state that the first feed valve 43 is closed, the manifold valve 45 and the first exhaust valve 44 are opened so that inside of the treatment object 21 can be vacuum evacuated to an ultimate pressure (or background pressure) of about 10⁻¹ Pa to 10⁻⁶ Pa by the vacuum pump 30.

Then, the first exhaust valve 44 is dosed, after the internal pressure of the tubular treatment object 21 has arrived to the ultimate pressure, and the first feed valve 43 is opened so that, through the T-shaped pipe 64, the manifold valve 45 and the excitation feed pipe 60, the process gas can be supplied to the inside of the tubular treatment object 21 from the gas source 33 via the first end of the tubular treatment object 21. When the internal pressure of the treatment object 21 is set around 20-30 kPa, which is near to the atmospheric pressure but less than the atmospheric pressure, the manifold valve 45 is dosed so that the internal pressure in the inside of the treatment object 21 can be maintained at a hermetically confined state with the processing pressure.

On the other hand, through the feed pipe 70 and the second feed valve 41, the process gas is supplied to the process chamber (23, 53, 54, 62), the process gas is supplied at a constant flow rate through the ambient gas adjustment mechanism (62, 65, 66b, 25b) from the gas source 33.

Similar to the third embodiment, the ambient gas adjustment mechanism (62, 65, 66b, 25b) embraces an injection-adjusting chamber 62, a gas supply layer 65 made of porous ceramics facilitating a uniform distribution of the process gas from the injection-adjusting chamber 62, a gas supply layer 65 as shown in FIG. 15, and a first electrode protection layer (first main electrode protection layer) 25b having a plurality of gas supply holes 66b.

The ambient gas adjustment mechanism (62, 65, 66b, 25b) is implemented by a plurality of taper-shaped gas supply holes 66b penetrating through the first electrode protection layer (first main electrode protection layer) 25b, similar to the topology shown in FIG. 7, the gas supply holes 66b are arranged in a form of two-dimensional matrix with a predetermined pitch. On the other hand, on the second electrode (second main electrode) 12, the second electrode-covering insulator (second main electrode-covering insulator) 23 made of high purity quartz is disposed.

Therefore, the process gas is formed into a configuration of uniform shower through the ambient gas adjustment mechanism (62, 65, 66b, 25b), and the process gas is supplied so as to surround the outside of the treatment object 21 in the process chamber (23, 53, 54, 62). The process gas supplied through the ambient gas adjustment mechanism (62, 65, 66b, 25b) is exhausted through the second exhaust pipe 63 from the process chamber (23, 53, 54, 62).

Furthermore, the surface treatment apparatus related to the sixth embodiment embraces the excited particle supplying system (16,17,18) disposed at the first end side, configured to supply excited particles for inducing initial discharge in a main body of the treatment object 21 in the early stage of discharge, in main body of the treatment object 21 the process gas is confined hermetically; and the first main electrode 11b and the second main electrode 12 disposed oppositely to each other so as to sandwich the treatment object 21, implementing a parallel plate configuration, in the configuration as a whole; and a pulse power supply 14 configured to apply electric pulses (main pulses) across the first main electrode 11b and the second main electrode 12 so as to maintain plasma state generated by the injection of the excited particles, and to cause a plasma state in the inside of the treatment object 21.

Because a periodic array of T-shaped protrusions, rather than flat slab configuration, is employed for the first main electrode 11b, the configuration as a whole is called as “quasi-parallel plate configuration” in view of the situation such that each of discharge points originates at each tips of the T-shaped protrusions, and all of the tips of the T-shaped protrusion are arranged on a single plane as if they implement a virtual flat slab. In this case the first main electrode 11b is equivalent to an array of bar-shaped linear) electrodes arranged in parallel so as to implement a ladder, and the ladder can implement an approximately “parallel plate configuration” with the second main electrode 12.

To the chamber top lid 54, a top treatment object holder 52 configured to hold the second end (the upper end in FIG. 15,) side of the tubular treatment object 21 is attached, and a bottom treatment object holder 51 configured to hold the first end (the bottom end in FIG. 15) of the treatment object 21 is connected to the chamber bottom lid 53 so as to establish a hermetically sealed state. Depending on materials, geometry and size of the treatment object 21, by adding an appropriate change, the structure of the bottom treatment object holder 51 can be designed and manufactured with well-known architecture pertaining to gas joints or vacuum components is designed, it is preferable.

In FIG. 15, a case that the second main electrode 12 is grounded so as to serve as the cathode, and high voltage is applied to the first main electrode 11b, being used as an anode, is illustrated. However, the polarity of pulse power supply 14 can be reversed so that the first main electrode 11b can serve as the cathode, and the second main electrode 12 can serve as the anode to which the high voltage is applied. When the first main electrode 11b is assigned as the cathode, the first main electrode 11b is made into a slab-shaped electrode, and is grounded so that the high voltage can be applied to the second main electrode 12, which is formed into a ladder type electrode, and the ambient gas adjustment mechanism (62, 65, 66b, 25b) is provided to the second main electrode 12. In addition, as already described in the first and third embodiments, a cross-section of the treatment object 21 cut along the horizontal plane in FIG. 15 is not limited to a circle, but another geometry such as rectangular cross-sectional shape can be employed, for example.

In FIG. 15, the excited particle supplying system (16, 17,18) encompasses the first auxiliary electrode 17, the second auxiliary electrode 18, and an auxiliary pulse power supply (although the illustration is omitted) configured to apply a voltage pulse (an auxiliary pulse) across the first auxiliary electrode 17 and the second auxiliary electrode 18 so as to generate initial plasma, the first auxiliary electrode 17 and the second auxiliary electrode 18 sandwich the excitation feed pipe 60 connected to the first end of the treatment object 21 so as to implement a parallel plate configuration. Similar to the case of the surface treatment apparatus related to the first and the third embodiments, because it is enough that the initial plasma can be injected in the gas flow in the early stage, the excited particle supplying system (16, 17, 18) may be implemented by any other configuration such as an inductive plasma source which can generate the initial plasma, therefore, the excited particle supplying system (16, 17, 18) is not limited to the parallel plate configuration shown in FIG. 15.

After excitation of initial plasma by injection of excited particles, in the surface treatment apparatus shown in FIG. 15, the inside and the outside of the treatment object 21 having a tubular geometry with sealed second are processed by radicals included in the plasma. In the surface treatment apparatus related to the sixth embodiment, a high purity nitrogen gas can be supplied as the process gas, however the “the process gas” is not limited to nitrogen gas. For example, for pasteurization or sterilization of the inside and the outside of the treatment object 21, nitrogen gas being mixed with various kinds of active gas such as halogen based compound gas can be adopted.

Main pulse (high voltage pulse) of duty ratio of 10⁻⁷ to 10⁻¹ is applied across the first main electrode 11b and second main electrode 12, to generate a non-thermal equilibrium plasma flow inside the treatment object 21, and thereby an inner surface of the treatment object 21 is treated. Preferably, a high voltage pulse having the high repetition rate, which have been explained in the first embodiment, is applied across the first main electrode 11 and the second main electrode 12 (See FIGS. 4A and 4B.). FIG. 4A shows a pulse width of 50-300 nano seconds preferable for the main pulse. When, in the surface treatment apparatus related to the sixth embodiment, if a distance between the first main electrode 11b and the second main electrodes, implementing a quasi-parallel plate configuration, is set to be 15 millimeters, the high voltage pulse having a repetition frequency of 2 kHz and a voltage value of around 24 kV is preferred. Because the period of the high voltage pulse is 500 microseconds, as shown in FIGS. 4A and 4B, and the corresponding repetition frequency is determined to be 2 k Hz for the high voltage pulse, the duty ratio becomes 0.3/500=0.006, therefore, non-thermal equilibrium low temperature plasma is generated efficiently and stably, without generating heat plasma ascribable to the high frequency discharge.

In the surface treatment apparatus related to the sixth embodiment, there are three operation modes explained in the third embodiment. That is to say, a first mode configured to ignite selectively an discharge only in the inside of the treatment object 21, a second mode configured to ignite an discharge only at the outside of the treatment object 21, a third mode configured to ignite both in the inside of and at the outside of the treatment object 21, although the treatment object 21 has the tubular geometry and the sealed second end. Similar to the third embodiment, those modes can be controlled with the pressure conditions prescribed by Eqs. (1)-(6). Since ways of operations of the three operation modes are substantially similar to those already explained in the third embodiment, overlapping or redundant description might be omitted.

### Seventh Embodiment

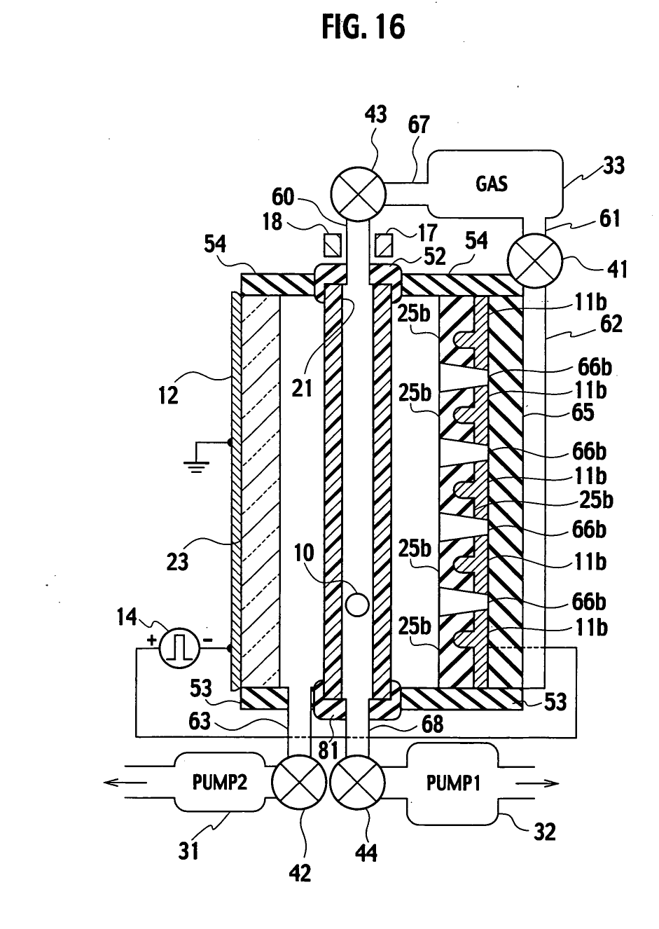

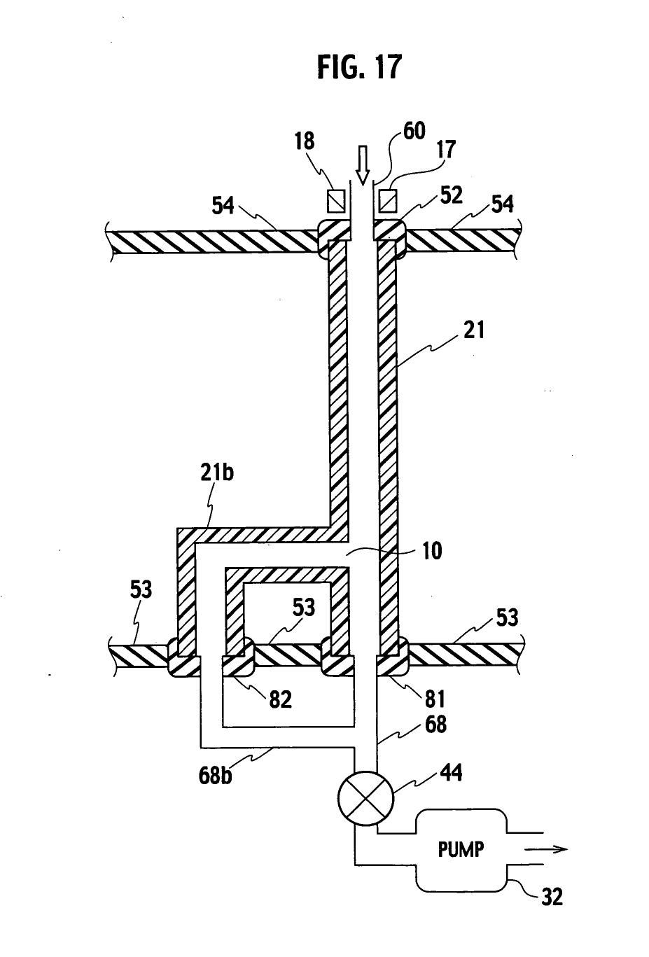

FIG. 16 and FIG. 17 are cross-sectional views looked from directions perpendicular to each other. As shown in FIGS. 16 and 17, a surface treatment apparatus related to a seventh embodiment of the present invention embraces a vacuum evacuating system (68, 68b, 44, 32) configured to evacuate process gas introduced from an upstream end of a tubular trunk pipe 21 of a treatment object (21, 21b) so as to generate a gas flow, the treatment object (21, 21b) having the tubular trunk pipe 21 and a branch pipe 21b branched off from the trunk pipe 21, from a downstream end of the trunk pipe 21 and an end portion of the branch pipe 21b of the treatment object (21, 21b); an excited particle supplying system (17, 18) disposed at the upstream side of the treatment object (21, 21b), configured to supply excited particles for inducing initial discharge in a main body of the treatment object (21, 21b); and a first main electrode 11b and a second main electrode 12 disposed oppositely to each other, defining a treating region of the treatment object (21, 21b) as a main plasma generating region disposed therebetween.

An endoscope may correspond to an example of the treatment object (21, 21b) having the tubular trunk pipe 21 and the branch pipe 21b branched off from the trunk pipe 21 (hereinafter called as “the T-branched treatment object (21, 21b)”). A plurality of T-shaped protrusions, rather than flat slab electrode, implements the “quasi-parallel plate configuration” with the second main electrode 12. Similar to the second, the third, the sixth embodiment, because each of discharges originates from each tips of the T-shaped protrusions arranged periodically in a plane, in view of the configuration as a whole, the structure can be approximated as “parallel plate configuration”.

The surface treatment apparatus related to the sixth embodiment further embraces a process chamber (23, 53, 54, 62) surrounding the outside of the tubular treatment object having the branch. In the process chamber (23, 53, 54, 62), to the surface of the second main electrode 12 serving as the cathode, the process gas is injected in a shower from the first main electrode 11b serving as the anode. Similar to the third embodiment, so as to supply process gas in the shape of a shower in the process chamber (23, 53, 54, 62), the surface treatment apparatus related to the sixth embodiment further embraces a ambient gas adjustment mechanism (62, 65, 66b, 25b) in the process chamber (23, 53, 54, 62), and the process gas is exhausted through a second exhaust pipe 63 from the process chamber (23, 53, 54, 62).

The process chamber (23, 53, 54, 62) embraces six planes assigned to each planes of a rectangular parallelepiped, such as a second electrode-covering insulator (second main electrode-covering insulator) 23, a chamber bottom lid 53, a chamber top lid 54 and an injection-adjusting chamber 62, and two side plates at a rearward portion of the paper (not illustrated) and at the near side (not illustrated) of the paper of FIG. 16.

The injection-adjusting chamber 62 has a flat rectangular parallelepiped shape. Among the six planes assigned to each planes of a rectangular parallelepiped, five metallic planes implement the five planes of the rectangular parallelepiped, respectively, and the gas supply layer 65 implements one plane (which corresponds to the left side plane of the gas supply layer 65 in the cross-sectional view shown in FIG. 16).

To establish a hermetically sealed space with the process chamber (23, 53, 54, 62), a top treatment object holder 52 configured to hold the upstream end of the trunk pipe 21 (21, 21b) is provided to the chamber top lid 54, and to the chamber bottom lid 53, a branch holder 82 configured to hold an end of the branch pipe 21b, which is branched off at the branching site 10 from the tubular trunk pipe 21, and a bottom treatment object holder 81 configured to hold the downstream end of the tubular trunk pipe 21 are provided as shown in FIG. 17. Depending on materials, geometry and size of the T-branched treatment object (21, 21b), by applying required changes and modifications appropriately, the structure of the top treatment object holder 52, the bottom treatment object holder 81 and the branch holder 82 can be designed and manufactured with well-known architecture pertaining to gas joints or vacuum components.

The vacuum evacuating system (68, 68b, 44, 32) encompasses a first exhaust pipe 68 connected to the bottom treatment object holder 81, a branched portion exhaust pipe 68b, which is branched off from the first exhaust pipe 68, connected to the branch holder 82, a first vacuum pump (first pump) 32 connected to the downstream side of the first exhaust pipe 68, and a first exhaust valve 44 connected between the first exhaust pipe 68 and first vacuum pump (first pump) 32. By such a constitution, the first vacuum pump (first pump) 32 can vacuum evacuate, through the exhaust pipe 68, the branched portion exhaust pipe 68b and the first exhaust valve 44, the inside of the T-branched treatment object (21, 21b).

As shown in FIG. 16, the ambient gas adjustment mechanism (62, 65, 66b, 25b) embraces an injection-adjusting chamber 62, a gas supply layer 65 made of porous ceramics facilitating a uniform distribution of the process gas from the injection-adjusting chamber 62, a gas supply layer 65, a first electrode protection layer (first main electrode protection layer) 25b having a plurality of gas supply holes 66b. The ambient gas adjustment mechanism (62, 65, 66b, 25b) is implemented by a plurality of taper-shaped gas supply holes 66b penetrating through electrode (first main electrode) protection layer 25b, and similar to the second embodiment, the gas supply holes 66b are arranged in a form of two-dimensional matrix with a predetermined pitch. (See FIG. 7.)

On the other hand, on the second electrode (second main electrode) 12, the second electrode-covering insulator (second main electrode-covering insulator) 23 made of high purity quartz is disposed. Furthermore, the surface treatment apparatus related to the seventh embodiment embraces a second feed valve 41 connected to the injection-adjusting chamber 62, a second feed pipe 61 connected to the second feed valve 41, an excitation feed pipe 60 connected to the top treatment object holder 52, a first feed valve 43 connected to the excitation feed pipe 60, a first feed pipe 67 connected between the first feed valve 43 and a gas source 33 such as a gas cylinder configured to store the process gas, and a second feed pipe 61 connected between the second feed valve 41 and the gas source 33 as shown in FIG. 16. It is preferable to adopt needle valves facilitating the adjustment of the flow rate for the first feed valve 43, the second feed valve 41.

Through the first feed pipe 67 and the first feed valve 43, the process gas is supplied from the gas source 33 in the inside of the T-branched treatment object (21, 21b). When the process gas is supplied to the upstream side of the T-branched treatment object (21, 21b), by the vacuum pump (second pump) 31 provided at the downstream side, the process gas flows in the inside of the T-branched treatment object (21, 21b), and the internal pressure of the T-branched treatment object (21, 21b) is kept at a processing pressure of around 20-30 kPa, which is near to and less than the atmospheric pressure.

On the other hand, in the process chamber (23, 53, 54, 62), through the second feed pipe 61 and the second feed valve 41, the process gas is supplied from the gas source 33, and the flow of the process gas is shaped into the configuration of uniform shower through the ambient gas adjustment mechanism (62, 65, 66b, 25b). The process gas supplied through the ambient gas adjustment mechanism (62, 65, 66b, 25b) is exhausted through the second exhaust pipe 63 from the process chamber (23, 53, 54, 62). And, as shown in FIG. 16 and FIG. 17, the second vacuum pump (second pump) 31, configured to evacuate the space surrounding the outside of the T-branched treatment object (21, 21b), is connected to the second exhaust pipe 63 via the second exhaust valve 42 in the surface treatment apparatus related to the seventh embodiment. That is, the second vacuum pump (second pump) 31 is connected to the second exhaust valve 42, and the second exhaust valve 42 is connected to the second exhaust pipe 63, and the second exhaust pipe 63 is connected to the process chamber (23, 53, 54, 62). It is preferable for the first exhaust valve 44 and the second exhaust valve 42 to use the variable conductance valves, through which the exhaust conductance can be adjusted.

In FIG. 16, a case that the second main electrode 12 is grounded so as to serve as the cathode, and high voltage is applied to the first main electrode 11b, being used as an anode is illustrated. However, the polarity of pulse power supply 14 can be reversed so that the first main electrode 11b can serve as the cathode, and the second main electrode 12 can serve as the anode, and high voltage is applied to the second main electrode 12. When the first main electrode 11b is assigned as the cathode, the first main electrode 11b is made into a slab-shaped electrode, and is grounded so that the high voltage can be applied to the second main electrode 12, which is formed into a ladder type electrode, and the ambient gas adjustment mechanism (62, 65, 66b, 25b) is provided to the second main electrode 12.

Similar to the first embodiment, a narrow tube (trunk pipe 21) having an inside diameter of less than or equal to 7-5 millimeters and a length is more than 4-7 meters, aside from the branch pipe 21b, may be used as the T-branched treatment object (21, 21b) in the surface treatment apparatus related to the seventh embodiment. However, even if the length of the trunk pipe 21 is less than 4 meters, and the inside diameter is more than 7 millimeters, the T-branched treatment object (21, 21b) can be processed. In addition, as already described in the first embodiment, for both the branch pipe and the trunk pipe, cross-sections of the T-branched treatment object (21, 21b) cut along the horizontal plane in FIGS. 16 and 17 are not limited to circles, but another geometries such as rectangular cross-sectional shapes can be employed, for example.

In FIGS. 16 and 17, the excited particle supplying system (17,18) encompasses the first auxiliary electrode 17, the second auxiliary electrode 18, and an auxiliary pulse power supply (although the illustration is omitted) configured to apply a voltage pulse (an auxiliary pulse) across the first auxiliary electrode 17 and the second auxiliary electrode 18 so as to generate initial plasma, the first auxiliary electrode 17 and the second auxiliary electrode 18 sandwich the excitation feed pipe 60 connected to the upstream end of the T-branched treatment object (21, 21b) so as to implement a parallel plate configuration. Similar to the case of the surface treatment apparatus related to the first embodiment, because it is enough that the initial plasma can be injected in the gas flow in the early stage, the excited particle supplying system (17, 18) may be implemented by any other configuration such as an inductive plasma source which can generate the initial plasma, therefore, the excited particle supplying system (17, 18) is not limited to the parallel plate configuration shown in FIGS. 16 and 17.

After excitation of initial plasma, the surface-treatment apparatus shown in FIG. 16 and FIG. 17, both the inside and the outside of the T-branched treatment object (21, 21b) are processed by radicals included in the plasma. In the surface treatment apparatus related to the seventh embodiment, a high purity nitrogen gas can be supplied as the process gas in the T-branched treatment object (21, 21b) from the upstream side, the “the process gas” is not limited to nitrogen gas. For example, for pasteurization or sterilization of the inside and the outside of the T-branched treatment object (21, 21b), nitrogen gas being mixed with various kinds of active gas such as halogen based compound gas can be adopted.

A high voltage pulse having the high repetition rate or duty ratio of 10⁻⁷ to 10⁻¹, which have been explained in the first embodiment, is applied across the first main electrode 11 and the second main electrode 12 (See FIGS. 4A and 4B). When, in the surface treatment apparatus related to the seventh embodiment, if a distance between the first main electrode 11b and the second main electrodes, implementing a quasi-parallel plate configuration, is elected to be 15 millimeters, the high voltage pulse having a repetition frequency of 2 kHz and a voltage value of around 24 kV is preferably applied across the first main electrode 11 and the second main electrode 12. In the case that the period of the high voltage pulse is 500 microseconds, the repetition frequency is determined to be 2 kHz, the duty ratio becomes 0.3/500=0.006 repeatedly.

Therefore, a stable non-thermal equilibrium low temperature plasma is generated the efficiently, without generating heat plasma ascribable to the high frequency discharge. In the surface treatment apparatus related to the seventh embodiment, there are three operation modes explained in the third embodiment. That is to say, a first mode configured to ignite selectively an discharge in the inside of the T-branched treatment object (21, 21b), a second mode configured to ignite selectively an discharge only at the outside of the T-branched treatment object (21, 21b), a third mode configured to ignite discharges both inside and outside of the T-branched treatment object (21, 21b). Therefore, similar to the third embodiment, those three modes can be controlled with appropriate pressure conditions prescribed by Eqs. (1)-(6).

Since ways of operations of the three operation modes are substantially similar to those already explained in the third embodiment, overlapping or redundant description might be omitted.

### Eighth Embodiment

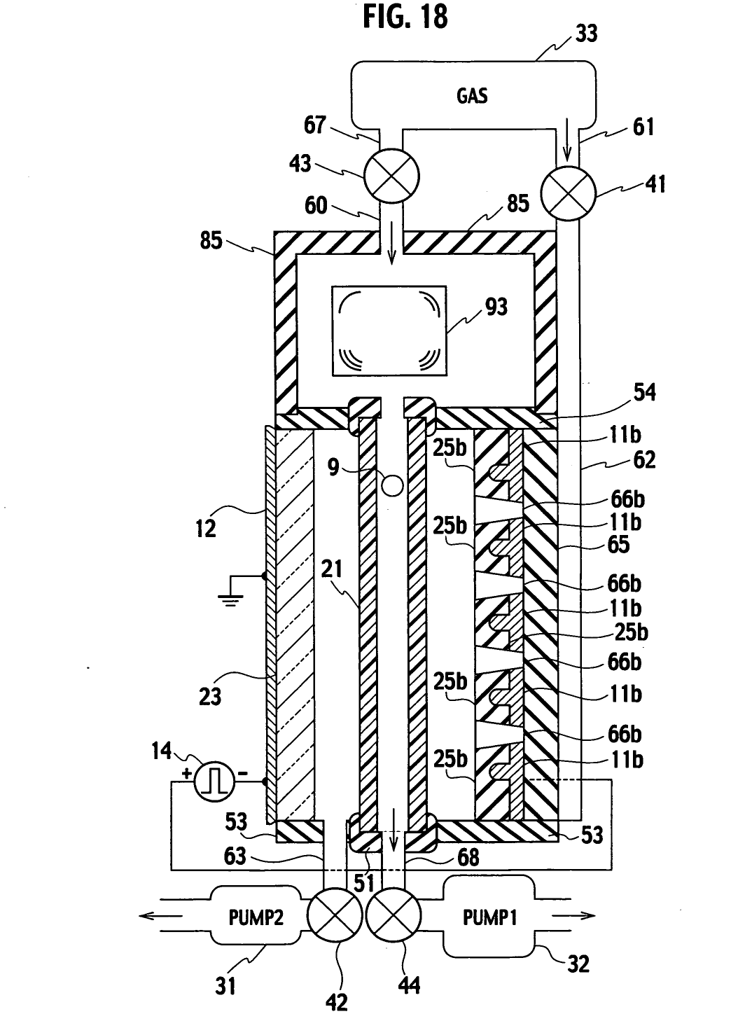

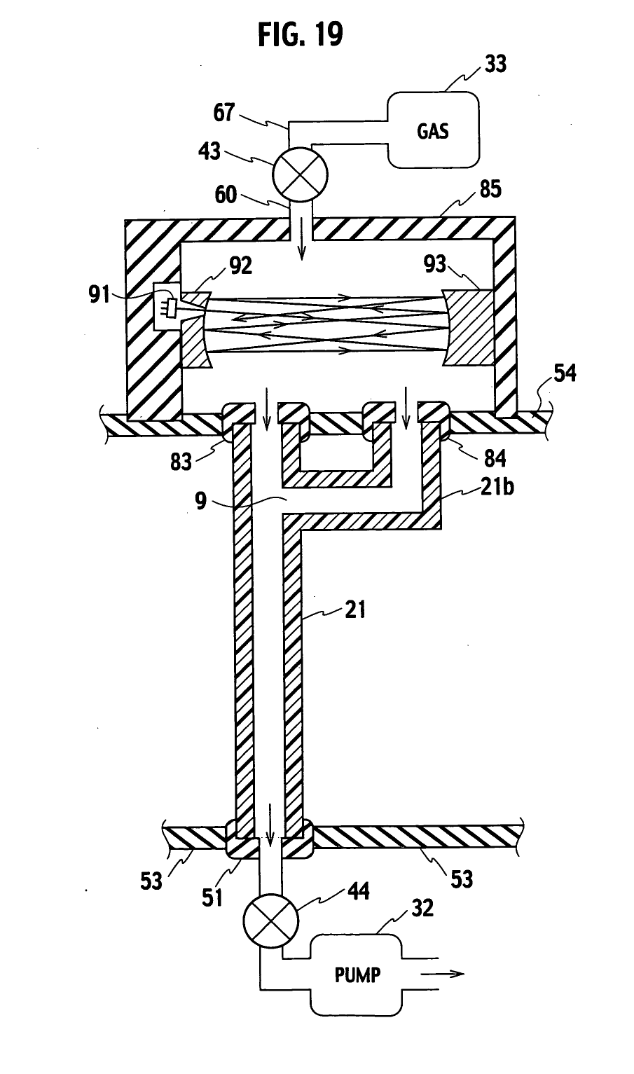

FIG. 18 and FIG. 19 are cross-sectional views looked from directions perpendicular to each other. As shown in FIGS. 18 and 19, a surface treatment apparatus related to a eighth embodiment of the present invention embraces a vacuum evacuating system (68, 44, 32) configured evacuate process gas introduced from an upstream end of a tubular trunk pipe 21 of a treatment object (21, 21b) and an end portion of a branch pipe 21b of the treatment object (21, 21b), the treatment object (21, 21b) having the tubular trunk pipe 21 and the branch pipe 21b branched off from the trunk pipe 21, from a downstream end of the trunk pipe 21; an excited particle supplying system (85, 91, 92, 93) disposed at the upstream side of the treatment object (21, 21b), configured to supply excited particles for inducing initial discharge in a main body of the treatment object (21, 21b); and a first main electrode 11b and a second main electrode 12 disposed oppositely to each other, defining a treating region of the treatment object (21, 21b) as a main plasma generating region disposed therebetween.

As described in the seventh embodiment, an endoscope may correspond to an example of the treatment object (21, 21b) having the tubular trunk pipe 21 and the branch pipe 21b branched off from the trunk pipe 21 (hereinafter called as “the T-branched treatment object (21, 21b)”), but the topology is reversed such that the upstream side and the downstream side of the T-branched treatment object (21, 21b) of the seventh embodiment is just reversed.

As to the first main electrode 11b, a plurality of T-shaped protrusions rather than flat slab electrode are arranged periodically in a plane so as to implement the “quasi-parallel plate electrode”. Similar to the second, third, sixth, and seventh embodiments, because, in the first main electrode 11b, a plurality of T-shaped protrusions are arranged periodically, each of the discharges originates from each tips of the T-shaped protrusions, in view of the configuration as a whole, the structure can be approximated as “parallel plate configuration” with the second main electrode 12.

As shown in FIG. 18 and FIG. 19, the excited particle supplying system (85, 91, 92, 93) embraces an excited particle generation chamber 85, a first reflecting mirror 92 installed in the excited particle generation chamber 85, a second reflecting mirror 93 installed in the excited particle generation chamber 85 and facing to first reflecting mirror 92 and an ultraviolet rays irradiation mechanism 91, for example. The first reflecting mirror 92 is a concave mirror having a narrow through-hole in a part, such that the ultraviolet rays emitted from the ultraviolet rays irradiation mechanism 91 can pass through the through-hole so as to illuminate the surface of the second reflecting mirror 93. And the second reflecting mirror 93 is a concave mirror, which can reflect the ultraviolet rays toward the surface of the first reflecting mirror 92, which can reflect the ultraviolet rays toward the surface of the first reflecting mirror 92 the first introduced from a through-hole of the second reflecting mirror 93 so as to cause a multi-reflection of the ultraviolet rays between the first reflecting mirror 92 and the second reflecting mirror 93. While the multi-reflection of the ultraviolet rays are repeated, process gas is supplied in the excited particle generation chamber 85, and the process gas is activated to generate the excited particles in the excited particle generation chamber 85.

As ultraviolet rays irradiation mechanism 91, semiconductor light emitting devices such as semiconductor lasers or light emitting diodes made of wideband gap semiconductors, which may include, for example, GaN based compound semiconductors, ZnSe based compound semiconductors, ZnO based compound semiconductors, SiC based compound semiconductors, are desirable for miniaturization of excited particle supplying system (85, 91, 92, 93).

However, even another lasers such as solid-state lasers or gas lasers, which can emit ultraviolet rays are available. As gas lasers, which can emit ultraviolet rays, excimer laser is preferable. When a large-scale ultraviolet rays irradiation mechanism 91, such as gas lasers including excimer laser, is used, such large-scale ultraviolet rays irradiation mechanism 91 shall be disposed outside of the excited particle generation room 85, and to activate process gas by the ultraviolet rays emitted from the ultraviolet rays irradiation mechanism 91, window materials such as sapphire, which can transmit the ultraviolet rays, shall be provided to a wall of the excited particle generation chamber 85. In this way, the ultraviolet rays emitted from the external ultraviolet rays irradiation mechanism 91, disposed outside of excited particle generation chamber 85, can be introduced between the first reflecting mirror 92 and the second reflecting mirror 93 via the through-hole of the first reflecting mirror 92, so as to cause multi-reflection between the first reflecting mirror 92 and the second reflecting mirror 93, and the process gas can be activated.

In the surface treatment apparatus related to the eighth embodiment, to the surface of the second main electrode 12 serving as the cathode, the process gas is injected in a shower from the first main electrode 11b serving as the anode. Similar to the third, the sixth, the seventh embodiments, so as to supply process gas in the shape of a shower, the surface treatment apparatus related to the eighth embodiment further-embraces a ambient gas adjustment mechanism (62, 65, 66b, 25b), and the process gas is exhausted through the second exhaust pipe 63 from the process chamber (23, 53, 54, 62). The process chamber (23, 53, 54, 62) embraces six planes assigned to each planes of a rectangular parallelepiped, such as a second electrode-covering insulator (second main electrode-covering insulator) 23, a chamber bottom lid 53, the chamber top lid 54 and an injection-adjusting chamber 62, two side plates at a rearward portion of the paper (not illustrated) and at the near side (not illustrated) of the paper of FIG. 18, implement remaining two planes assigned to the planes of the rectangular parallelepiped.

The injection-adjusting chamber 62 has a flat rectangular parallelepiped shape. Among the six planes assigned to each planes of a rectangular parallelepiped, five metallic planes implement the five planes of the rectangular parallelepiped, respectively, and the gas supply layer 65 implements one plane (which corresponds to the left side plane of the gas supply layer 65 in the cross-sectional view shown in FIG. 18).

To establish a hermetically sealed state, as shown in FIG. 19, a ring-shaped branch holder 84 configured to hold an end of the branch pipe 21b, which is branched off from the trunk pipe 21 of the T-branched treatment object (21, 21b), and a ring-shaped top treatment object holder 83 configured to hold the upstream end of the trunk pipe 21 are connected to the chamber top lid 54. Via the top treatment object holder 83 and the branch holder 84, apertures are established in the bottom of the excited particle generation chamber 85 so as to implement the excited particle supplying system (85, 91, 92, 93). In other word, the top treatment object holder 83 and the branch holder 84 are connected to the bottom of the excited particle generation chamber 85 of the excited particle supplying system (85, 91, 92, 93). On the other hand, to the chamber bottom lid 53, a bottom treatment object holder 51 configured to hold the downstream end of the tubular trunk pipe 21 in a hermetically sealed state as shown in FIG. 19 is arranged. Depending on materials, geometry and size of the T-branched treatment object (21, 21b), by applying required changes and modifications appropriately, the structures of the top treatment object holder 83, the branch holder 84 and the bottom treatment object holder 51 can be designed and manufactured with well-known architecture pertaining to gas joints or vacuum components, easily.

The first exhaust pipe 68 is connected to the bottom treatment object holder 51. And the first vacuum pump (first pump) 32 is connected to the downstream side of the first exhaust pipe 68 through the first exhaust valve 44. By such a constitution, the first vacuum pump (first pump) 32 can vacuum evacuate the inside of the T-branched treatment object (21, 21b) through the exhaust pipe 68 and the first exhaust valve 44.

As shown in FIG. 18, the ambient gas adjustment mechanism (62, 65, 66b, 25b) embraces an injection-adjusting chamber 62, a gas supply layer 65 made of porous ceramics facilitating a uniform distribution of the process gas from the injection-adjusting chamber 62, a gas supply layer 65 and a first electrode protection layer (first main electrode protection layer) 25b having a plurality of gas supply holes 66b. The ambient gas adjustment mechanism (62, 65, 66b, 25b) is implemented by a plurality of taper-shaped gas supply holes 66b penetrating through the first electrode protection layer first main electrode protection layer) 25b, and similar to the second embodiment, the gas supply holes 66b are arranged in a form of two-dimensional matrix with a predetermined pitch. (See FIG. 7.). On the other hand, on the second electrode (second main electrode) 12, the second electrode-covering insulator (second main electrode-covering insulator) 23 made of high purity quartz is disposed.

Furthermore, the surface treatment apparatus related to the eighth embodiment embraces an excitation feed pipe 60 connected to a ceiling wall of the excited particle generation chamber 85, a first feed valve 43 connected to the excitation feed pipe 60, a second feed valve 41 connected to the injection-adjusting chamber 62, a first feed pipe 67 connected between the first feed valve 43 and a gas source 33 such as a gas cylinder configured to store the process gas, and a second feed pipe 61 connected between the second feed valve 41 and the gas source 33, as shown in FIG. 18. It is preferable to adopt needle valves facilitating the adjustment of the flow rate for the first feed valve 43, the second feed valve 41. In the surface treatment apparatus related to the eighth embodiment, the excitation feed pipe 60 does not have to be always pipe made of dielectric material.

In the inside of excited particle generation chamber 85, through the first feed pipe 67, the first feed valve 43 and the excitation feed pipe 60, the process gas is supplied from the gas source 33, and the process gas is supplied to the upstream side of the T-branched treatment object (21, 21b).

The process gas being supplied in the inside of excited particle generation chamber 85 further flows into the apertures of the top treatment object holder 83 and the branch holder 84, which are provided at the bottom of the excited particle generation chamber 85, and the process gas is further transported to the trunk pipe 21 and the branch pipe 21b of the T-branched treatment object (21, 21b).

Then, in the inside of excited particle generation chamber 85, excited particles are generated, and the excited particles are transported through the top treatment object holder 83 and the branch holder 84 provided at the bottom of the excited particle generation chamber 85, and the excited particles are injected into the trunk pipe 21 and the branch pipe 21b of the T-branched treatment object (21, 21b), while initial plasmas are generated in the inside of the trunk pipe 21 of the T-branched treatment object (21, 21b) and inside of the branch pipe 21b.

The process gas supplied in the trunk pipe 21 of the T-branched treatment object (21, 21b) and the branch pipe 21b are mixed at the branching site 9, and are further exhausted by the vacuum pump (second pump) 31 provided at the downstream side of the T-branched treatment object (21, 21b), and the internal pressure of the T-branched treatment object (21, 21b) is kept at a processing pressure of around 20-30 kPa, which is near to and less than the atmospheric pressure.

On the other hand, as shown in FIG. 18, in the process chamber (23, 53, 54, 62), through the second feed pipe 61 and the second feed valve 41, the process gas is supplied from the gas source 33, and the flow of the process gas is shaped into the configuration of uniform shower through the ambient gas adjustment mechanism (62, 65, 66b, 25b). The process gas supplied through the ambient gas adjustment mechanism (62, 65, 66b, 25b) is exhausted through the second exhaust pipe 63 from the process chamber (23, 53, 54, 62). Addressing to the exhaustion of the process gas, as shown in FIG. 18 and FIG. 19, the second vacuum pump (second pump) 31, configured to evacuate the space surrounding the outside of the T-branched treatment object (21, 21b), is connected to the second exhaust valve 42, the second exhaust valve 42 is connected to the second exhaust pipe 63, and the second exhaust pipe 63 is connected to the process chamber (23, 53, 54, 62). It is preferable for the first exhaust valve 44 and the second exhaust valve 42 to use the variable conductance valves, through which the exhaust conductance can be adjusted.

In FIG. 18, a case that the second main electrode 12 is grounded so as to serve as the cathode, and high voltage is applied to the first main electrode 11b, being used as the anode, is illustrated. However, the polarity of pulse power supply 14 can be reversed so that the first main electrode 11b can serve as the cathode, and the second main electrode 12 can serve as the anode to which the high voltage is applied. When the first main electrode 11b is assigned as the cathode, the first main electrode 11b is made into a slab-shaped electrode, and is grounded so that the high voltage can be applied to the second main electrode 12, which is formed into a ladder type electrode, and the ambient gas adjustment mechanism (62, 65, 66b, 25b) is provided to the second main electrode 12.

Similar to the first embodiment, a narrow tube (trunk pipe 21) having an inside diameter of less than or equal to 7-5 millimeters and a length is more than 4-7 meters, aside from the branch pipe 21b, may be used as the T-branched treatment object (21, 21b) in the surface treatment apparatus related to the eighth embodiment. However, even if the length of the trunk pipe 21 is less than 4 meters, and the inside diameter is more than 7 millimeters, the T-branched treatment object (21, 21b) can be processed. In addition, as already described in the first embodiment, for both the branch pipe and the trunk pipe, cross-sections of the T-branched treatment object (21, 21b) cut along the horizontal plane in FIGS. 18 and 19 are not limited to circles, but another geometries such as rectangular cross-sectional shapes can be employed, for example.

After excitation of initial plasma, as shown in FIG. 18 and FIG. 19, the inside of the T-branched treatment object (21, 21b) is processed by radicals included in plasma transported to the inside of the T-branched treatment object (21, 21b) at a constant flow rate. In addition, the outside of the T-branched treatment object (21, 21b) is processed by radicals included in plasma generated at the outside of the T-branched treatment object (21, 21b). In the surface treatment apparatus related to the eighth embodiment, a high purity nitrogen gas can be supplied as the process gas in the inside and at the outside of the T-branched treatment object (21, 21b), the “the process gas” is not limited to nitrogen gas. For example, for pasteurization or sterilization of the inside and the outside of the T-branched treatment object (21, 21b), nitrogen gas being mixed with various kinds of active gas such as halogen based compound gas can be adopted.

A high voltage pulse having duty ratio of 10⁻⁷ to 10⁻¹, which have been explained in the first embodiment is applied across the first main electrode 11 and the second main electrode 12 (See FIGS. 4A and 4B.). In the surface treatment apparatus related to the eighth embodiment, if a distance between the first main electrode 11b and the second main electrodes, implementing a quasi-parallel plate configuration, is elected to be 15 millimeters, the high voltage pulse having a repetition frequency of 2 kHz and a voltage value of around 24 kV is preferably applied across the first main electrode 11 and the second main electrode 12. When the period of the high voltage pulse is elected to be 500 microseconds, because the repetition frequency is determined to be 2 kHz, the duty ratio becomes 0.3/500=0.006. Therefore, stable non-thermal equilibrium low temperature plasma is generated efficiently, without generating heat plasma ascribable to the high frequency discharge.

In the surface treatment apparatus related to the eighth embodiment, there are three operation modes explained in the third embodiment. That is to say, a first mode configured to ignite selectively an discharge only in the inside of the T-branched treatment object (21, 21b), a second mode configured to ignite selectively an discharge only at the outside of the T-branched treatment object (21, 21b), a third mode configured to ignite both inside and outside of the T-branched treatment object (21, 21b) having tubular geometry with a branch. Similar to the third embodiment, those three modes can be controlled with pressure conditions prescribed by Eqs. (1)-(6). Since ways of operations of the three operation modes are substantially similar to those already explained in the third embodiment, overlapping or redundant description might be omitted.

### Ninth Embodiment

In the third, sixth to eighth embodiments, examples to control three operation modes with pressure conditions prescribed by Eqs. (1)-(6) are explained. A first mode configured to ignite selectively an discharge only in the inside of the treatment object 21, a second mode configured to ignite selectively an discharge only at the outside of the treatment object 21, a third mode configured to ignite both inside and outside of the treatment object 21 are controlled by choosing a pressure conditions prescribed by Eqs. (1)-(6). That is to say, the control of three operation modes can be executed with another parameters aside from the pressure of the process gas. Temperature of the process gas is one example of other parameters for controlling the three operation modes, therefore, in a surface treatment apparatus related to the ninth embodiment of the present invention, such control of the temperature of the process gas will be explained.

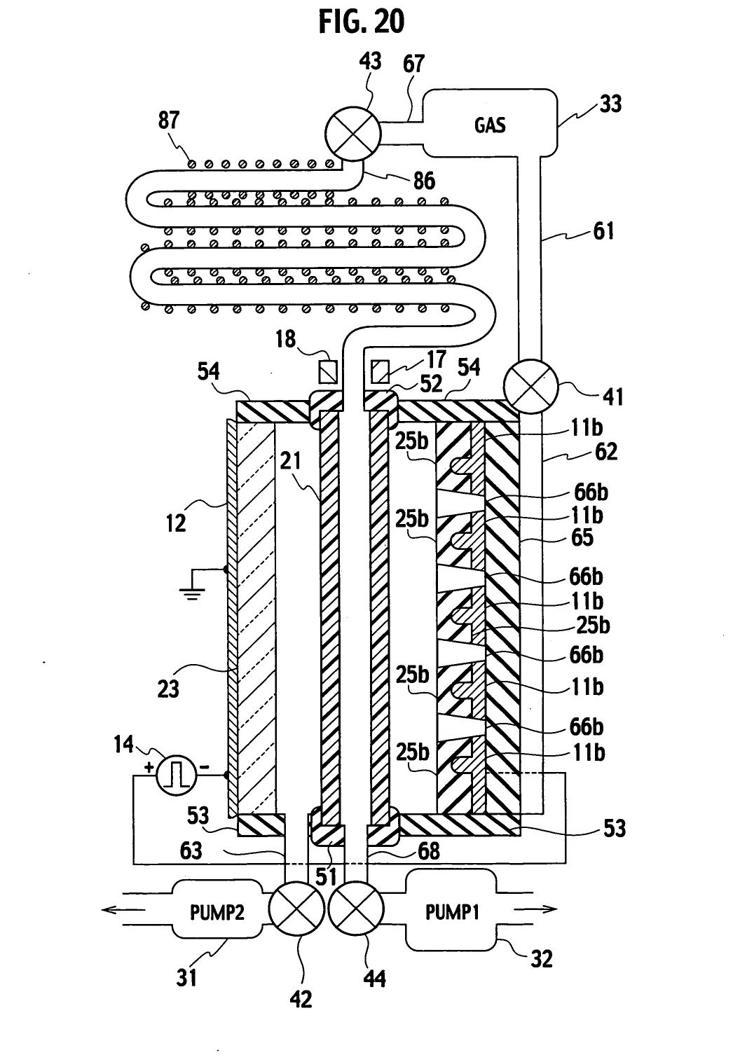

As illustrated in FIG. 20, the features such that the surface treatment apparatus related to the ninth embodiment embraces a first vacuum pump (first pump) 32 connected to downstream end of the tubular dielectric treatment object 21, configured to evacuate the process gas from downstream end of the tubular dielectric treatment object 21; a second vacuum pump (second pump) 31, configured to evacuate the space surrounding the outside of the tubular dielectric treatment object 21 from downstream side of the tubular dielectric treatment object 21; an excited particle supplying system (17,18) disposed at the upstream end side, configured to supply excited particles for inducing initial discharge in a main body of the tubular dielectric treatment object 21 in the early stage of discharge; a first main electrode 11b and a second main electrode 12 disposed oppositely to each other so as to sandwich the tubular dielectric treatment object 21, implementing a parallel plate configuration, in the configuration as a whole; and a pulse power supply 14 configured to apply electric pulses (main pulses) across the first main electrode 11b and the second main electrode 12 so as to maintain plasma state generated by the injection of the excited particles, and to cause a plasma state in the inside and at the outside of the tubular dielectric treatment object 21 are similar to the surface treatment apparatus related to the third embodiment. In addition, the features such the surface treatment apparatus related to the ninth embodiment embraces a gas source 33 such as a gas cylinder configured to store process gas, a first feed pipe 67 connected to the gas source 33, a second feed pipe 61 connected to the gas source 33, a first feed valve 43 connected to second feed pipe 67, and a second feed valve 41 connected to the second feed pipe 61 are similar to the surface treatment apparatus related to the third embodiment.

However, the surface treatment apparatus related to the ninth embodiment of the present invention is different from the surface treatment apparatus related to the third embodiment in that a heating feed pipe 86 is connected to the feed valve 43 and a pre-heater 87 is provided around the heating feed pipe 86 so as to pre-heat the process gas, as shown in FIG. 20. It is desirable to increase the effective heating distance by employing a topology such that the heating feed pipe 86 follows a winding/turning course in a shape of meandering line, as shown in FIG. 20, so as to improve the heating efficiency of the process gas. Although all of the heating feed pipe 86 is not required to consist of dielectric material, but a localized portion, around where the excited particle supplying system (17,18) works, should be made dielectric materials.

Through the first feed pipe 67 and the first feed valve 43, the process gas is supplied from the gas source 33 in the inside of the tubular treatment object 21, such that the process gas is fly supplied to the upstream side, by the vacuum pump (second pump) 31 provided at the downstream side, the process gas flows in the inside of the treatment object 21, while the inner pressure of the treatment object 21 is kept at a predetermined pressure. Among the three operation modes, when a first mode configured to ignite selectively an discharge only in the inside of the treatment object 21 is desired, by selectively energize the process gas flowing in the inside of the treatment object 21 through the pre-heater 87 so as to increase the temperature of the process gas flowing in the inside of the treatment object 21, such that the temperature of the process gas flowing in the inside of the treatment object 21 is approximately 30-50 degrees Celsius higher than the temperature of the process gas applied to the outside of the treatment object 21, which is fed through the ambient gas adjustment mechanism (62, 65, 66b, 25b), a selective discharge is easily established only in the inside of the treatment object 21. Of course, in order to generate discharge selectively, is desirable to decrease the gas pressure P1 in the inside of the treatment object 21 lower than the gas pressure P2 at the outside of the treatment object 21, such that the gas pressure P1 in the inside of the treatment object 21 is set to be around 10-40 kPa. In addition, it is desirable to decrease the gas pressure P2 at the outside of the treatment object 21 such that the gas pressure P2 at the outside of the treatment object 21 is approximately equal to the atmospheric pressure P3=101 kPa, or is around 80-90 kPa, which is slightly lower than the atmospheric pressure P3, as prescribed by Eq. (1). However, the first mode configured to ignite selectively an discharge only in the inside of the treatment object 21 is more stably and surely achieved when the temperature of the process gas flowing in the inside of the treatment object 21 is increased such that the temperature of the process gas flowing in the inside of the treatment object 21 is approximately 30-50 degrees Celsius higher than the temperature of the process gas applied to the outside of the treatment object 21.

In addition, when the gas pressure P2 at the outside of the treatment object 21 is near to gas pressure P1 in the inside of the treatment object 21, the first mode configured to ignite selectively an discharge only in the inside of the treatment object 21 can be established easily.

Since the structure and configuration of the process chamber (23, 53, 54, 62) and the ambient gas adjustment mechanism (62, 65, 66b, 25b) are substantially similar to those already explained in the third embodiment, overlapping or redundant description might be omitted.

In addition, although the illustration is omitted, if a buried heater is established in the inside of the ambient gas adjustment mechanism (62, 65, 66b, 25b) so that the temperature of the process gas flowing outside of the treatment object 21 can be increase than the temperature of the process gas flowing in the inside of the treatment object 21, the second mode configured to ignite selectively an discharge only at the outside of the treatment object 21 can be easily established.

In addition, if a Peltier cooling unit is provided in the inside of the ambient gas adjustment mechanism (62, 65, 66b, 25b) so that, by electronic cooling (Peltier effect), the temperature of the process gas applied to the outside of the treatment object 21 is decreased lower than the temperature of the process gas flowing in the inside of the treatment object 21, the first mode configured to ignite selectively an discharge only in the inside of the treatment object 21 can be established easily. Instead of the Peltier cooling unit, piping of refrigerant gas may be provided in the inside of the ambient gas adjustment mechanism (62, 65, 66b, 25b), so that the temperature of the process gas applied to the outside of the treatment object 21 is decreased lower than the temperature of the process gas flowing in the inside of the treatment object 21, the first mode configured to ignite selectively an discharge only in the inside of the treatment object 21 can be established easily.

Others are substantially similar to those already explained in the third embodiment, overlapping or redundant description might be omitted.

### Tenth Embodiment

As explained in the ninth embodiment, the control of three operation modes can be achieved by control mechanism of a parameter aside from pressure of the process gas. Although one example of other parameters is the temperature of the process gas, which has been explained in the surface treatment apparatus related to the ninth embodiment of the present invention, another methodology to use trigger gas will be explained in a surface treatment apparatus related to the tenth embodiment of the present invention, in which, in the early stage of discharge, by introducing the trigger gas selectively where the selective discharge is desired, the selective discharge can be easily established so as to control three operation modes.

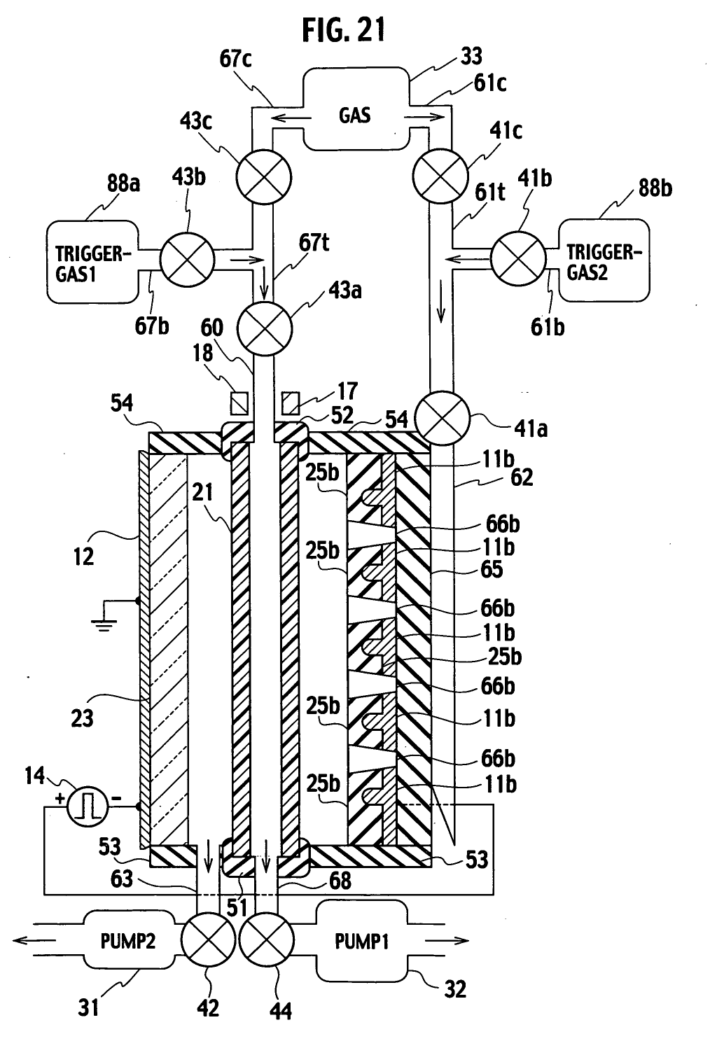

As illustrated in FIG. 21, the features such that the surface treatment apparatus related to the tenth embodiment embraces a first vacuum pump (first pump) 32 connected to downstream end of the tubular dielectric treatment object 21, configured to evacuate the process gas from downstream end of the tubular dielectric treatment object 21; a second vacuum pump (second pump) 31, configured to evacuate the space surrounding the outside of the tubular dielectric treatment object 21 from downstream side of the tubular dielectric treatment object 21; an excited particle supplying system (17,18) disposed at the upstream end side, configured to supply excited particles for inducing initial discharge in a main body of the tubular dielectric treatment object 21 in the early stage of discharge; a first main electrode 11b and a second main electrode 12 disposed oppositely to each other so as to sandwich the tubular dielectric treatment object 21, implementing a parallel plate configuration, in the configuration as a whole; and a pulse power supply 14 configured to apply electric pulses (main pulses) across the first main electrode 11b and the second main electrode 12 so as to maintain plasma state generated by the injection of the excited particles, and to cause a plasma state in the inside and at the outside of the tubular dielectric treatment object 21 are similar to the surface treatment apparatus related to the third embodiment. In addition, the features such the surface treatment apparatus related to the tenth embodiment embraces a gas source 33 such as a gas cylinder configured to store process gas, a first feed pipe 67c connected to the gas source 33, a second feed pipe 61c connected to the gas source 33, a first feed valve 43c connected to second feed pipe 67c, and a second feed valve 41c connected to the second feed pipe 61c are similar to the surface treatment apparatus related to the third embodiment.

However, the surface treatment apparatus related to the tenth embodiment of the present invention is different from the surface treatment apparatus related to the third embodiment in that the surface treatment apparatus related to the tenth embodiment encompasses a first T-shaped pipe 67t, configured to introduce a first trigger gas, is connected to first feed valve 43c and a second T-shaped pipe 61t, configured to introduce a second trigger gas, is connected to the second feed valve 41c. Furthermore, to the first branch of the first T-shaped pipe 67, through a trigger gas introduction valve 43b and a first trigger gas introduction pipe 67b, a first trigger gas source 88a is connected, and to the second branch of the second T-shaped pipe 61t, through a trigger gas introduction valve 41b and a second trigger gas introduction pipe 61b, a second trigger gas source 88b is connected.

In FIG. 21, although the first trigger gas source 88a and the second trigger gas source 88b are illustrated as discrete gas sources, a common gas source can be employed. The first trigger gas source 88a and the second trigger gas source 88b are gas cylinders, in which gases that facilitate discharge, such as helium (He), or Argon (Ar) are filled As for the first trigger gas introduction valve 43b and the second trigger gas introduction valve 41b, the valves having higher response time, such as an electromagnetic valve or an air pressure valve are preferable.

Furthermore, to the downstream side of the first T-shaped pipe 67t, an excitation feed pipe 60 is connected through a first manifold valve 43a. The excitation feed pipe 60 is a pipe made of dielectric material. On the other hand, to the second downstream side of the second T-shaped pipe 61t, an ambient gas adjustment mechanism (62, 65, 66b, 25b) is connected through a second manifold valve 41a.

Through the first feed pipe 67c, the first feed valve 43c, the first T-shaped pipe 67t, the first manifold valve 43a and the excitation feed pipe 60, the process gas is supplied from the gas source 33 to the inside of the tubular treatment object 21, and the process gas supplied to the upstream side of the tubular treatment object 21, by the vacuum pump first pump) 32 provided at the downstream side of the tubular treatment object 21, the process gas is forced to flow in the inside of the treatment object 21, while the inner pressure of the treatment object 21 is kept at a predetermined pressure.

Then, at the beginning of the discharge, and in a short time, the first trigger gas introduction valve 43b is opened, when the first mode configured to generate selectively the discharge only in the inside of the treatment object 21 is desired among three operation modes, and the first trigger gas flows from the first trigger gas source 88a, through the first trigger gas introduction valve 43b, the T-shaped pipe 67t, the first manifold valve 43a and the excitation feed pipe 60, to the inside of the treatment object 21 so that a selective discharge is easy established only in the inside of the treatment object 21.

Of course, the gas pressure P1 in the inside of the treatment object 21 is preferably decreased to be around 10-40 kPa in the inside of the treatment object 21 in order to generate discharge selectively, and it is desirable to decrease the gas pressure P1 lower than the gas pressure P2 at the outside of the treatment object 21. In addition, the gas pressure P2 at the outside of the treatment object 21 is elected to be equal to the atmospheric pressure P3=101 kPa, around 80-90 kPa which is slightly lower than the atmospheric pressure P3 as taught by Eq. (1). However, if the first trigger gas is selectively injected in the inside of the treatment object 21, like a pulse in a shot time, the first mode configured to selectively generate the discharge only in the inside of the treatment object 21 is stably and surely established. In addition, even in a case when the gas pressure P2 at the outside of the treatment object 21 is near to gas pressure P1 in the inside of the treatment object 21, the first mode configured to ignite selectively discharge only in the inside of the treatment object 21 is easily achieved by the introducing of the first trigger gas.

On the other hand, through the second feed pipe 61 c, the second feed valve 41c, the second T-shaped pipe 61t, the second manifold valve 41a, the process gas is supplied from the gas source 33 to the ambient gas adjustment mechanism (62, 65, 66b, 25b), and the process gas supplied to the upstream side, by the vacuum pump (second pump) 31 provided at the downstream side of the process chamber (23, 53, 54, 62), the process gas is forced to flow in the process chamber (23, 53, 54, 62), while the process chamber (23, 53, 54, 62) is kept at a predetermined pressure.

Then, at the beginning of the discharge, and in a short time, the second trigger gas introduction valve 41b is opened, when the second mode configured to selectively generate discharge only at the outside of the treatment object 21 is desired, among three operation modes, the second trigger gas flows from the second trigger gas source 88b, through the second trigger gas introduction valve 41b, the T-shaped pipe 61t and the second manifold valve 41a, to the inside of the process chamber (23, 53, 54, 62) so that a selective discharge is easy established only at the outside of the treatment object 21.

Of course, in order to generate the discharge only at the outside of the treatment object 21, it is preferable to consider the pressure conditions prescribed by Eqs. (3), (4), (5) or (6), however by injecting pulse-like the second trigger gas, selective ignition of the discharge can be established more surely and more stably only at the outside of the treatment object 21. In addition, even in a case when the gas pressure P2 at the outside of the treatment object 21 is near to the gas pressure P1 in the inside of the treatment object 21, the second mode configured to ignite selectively discharge only at the outside of the treatment object 21 can be achieved surely and stably.

As to the third mode configured to generate discharges both in the inside and at the outside of the treatment object 21, both of the first and second trigger gases can be injected; only the first trigger gas is injected in the pressure condition such that only the discharge in the inside of the treatment object 21 is not easy; alternatively, only the second trigger gas is injected in the pressure condition such that only the discharge at the outside of the treatment object 21 is not easy; while the third mode can be established without employing the first and second trigger gases.

Since other structures or configurations, such as the configuration of the process chamber (23, 53, 54, 62) and the ambient gas adjustment mechanism (62, 65, 66b, 25b) are substantially similar to those already explained in the third embodiment, overlapping or redundant description might be omitted.

### Eleventh Embodiment

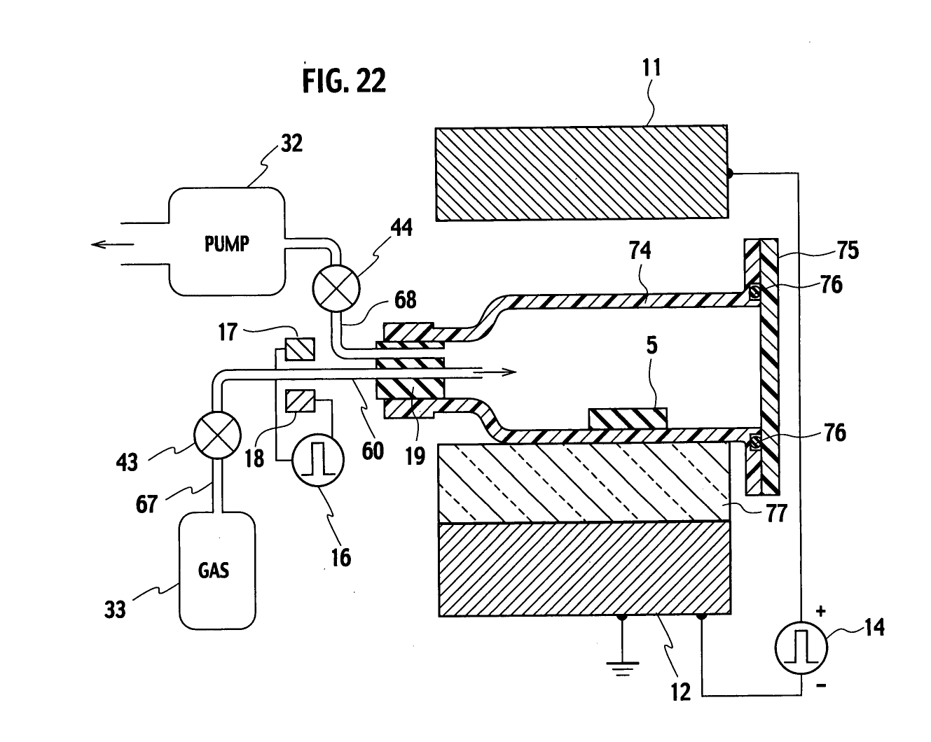

As shown in FIG. 22, a surface treatment apparatus related to a eleventh embodiment of the present invention apparatus encompasses a dielectric housing (74, 75 and 76) configured to accommodate an treatment object 5; a vacuum evacuating system (32,44 and 68) configured to evacuate a the process gas introduced at a specific flow rate from a feed pipe provided at first end of the dielectric housing (74, 75 and 76) having second end closed, from an exhaust pipe provided at the first end, and maintaining the pressure of the process gas inside the dielectric housing (74, 75 and 76) at a process pressure; an excited particle supplying system (16,17 and 18) disposed at first end of the dielectric housing (74, 75 and 76), configured to supply excited particles for inducing initial discharge in a main body of the dielectric housing (74, 75 and 76); and a first main electrode 11 and a second main electrode 12 disposed oppositely to each other, defining a treating region of the treatment object as a main plasma generating region disposed therebetween, wherein the excited particle supplying system (16,17 and 18) is driven at least until generation of main plasma, and main pulse of duty ratio of 10⁻⁷ to 10⁻¹ is applied across the first main electrode 11 and second main electrode 12, to generate a non-thermal equilibrium plasma flow inside the dielectric housing (74, 75 and 76), and thereby a surface of the treatment object 5 is treated.

The dielectric housing (74, 75 and 76) is implemented by a dielectric tube 74 and a dielectric flange plate 75. The dielectric tube 74 and the dielectric flange plate 75 is sealed by o-ring 76 so as to establish a vacuum tight structure. On the second main electrode 12, a second main electrode covering insulating film 77 is disposed so as to cover the surface of the second main electrode 12, and the dielectric housing (74, 75 and 76) is mounted and fixed on the second main electrode covering insulating film 77.

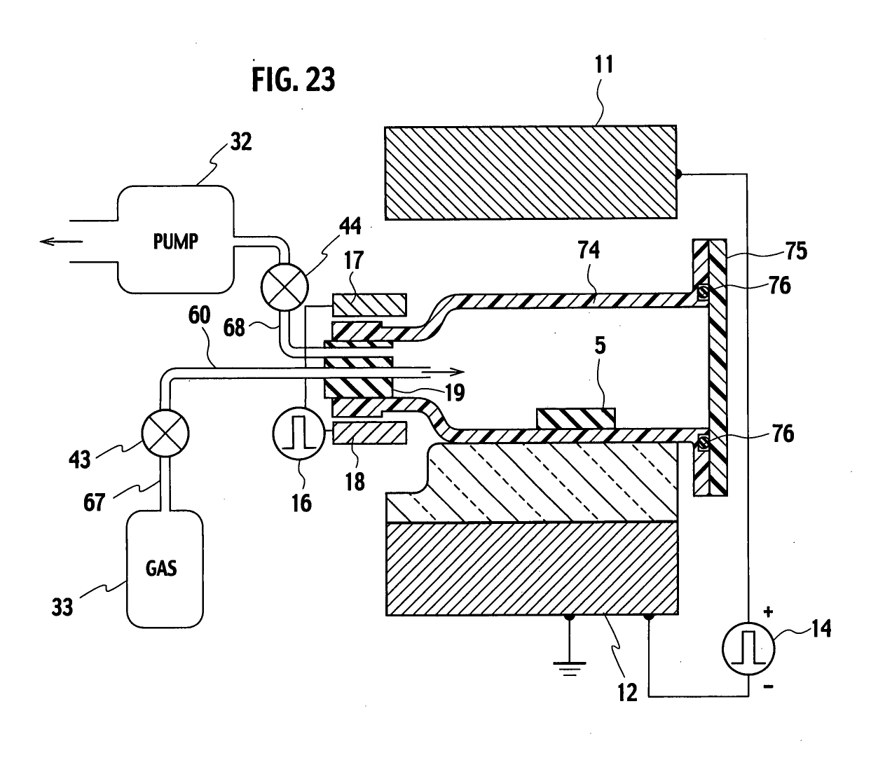

In FIG. 22, the first auxiliary electrode 17 and the second auxiliary electrode 18, implementing the excited particle supplying system (16, 17 and 18), are arranged at a position where the excitation feed pipe 60 does not overlap with position of the exhaust pipe 68 were shown. However, the first auxiliary electrode 17 and the second auxiliary electrode 18 may be disposed at a position to sandwich both the exhaust pipe 68 and the excitation feed pipe 60 as shown in FIG. 23. FIG. 23 is a cross-sectional view schematically explaining essential structure of the surface treatment apparatus in accordance with a first modification of the eleventh embodiment of the present invention.

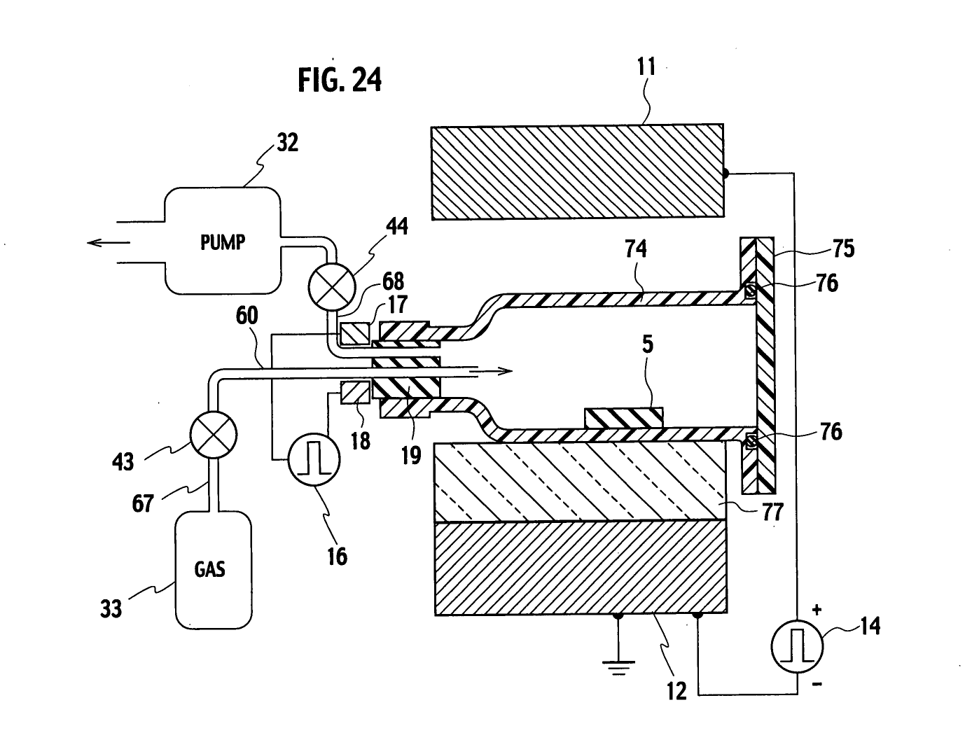

Furthermore, the first auxiliary electrode 17 and the second auxiliary electrode 18 may be disposed at a position sandwiching the neck adapter 19 as shown in FIG. 24. FIG. 24 is a cross-sectional view schematically explaining essential structure of the surface treatment apparatus in accordance with a second modification of the eleventh embodiment of the present invention.

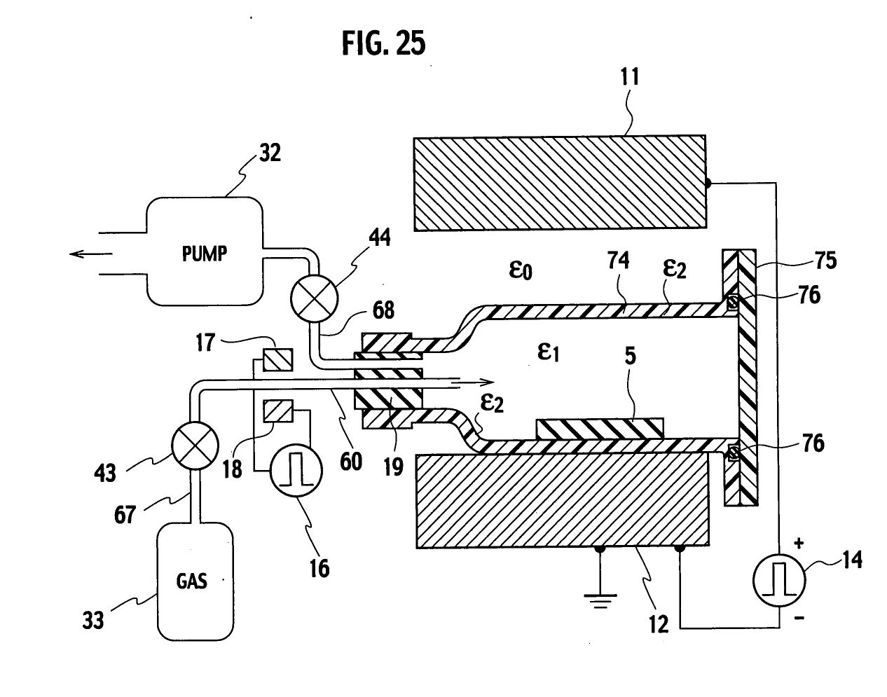

Although, in FIGS. 22-24, the dielectric housings (74, 75 and 76) are mounted on the second main electrode 12 via the second main electrode covering insulating film 77, respectively, the dielectric housing (74, 75 and 76) can be fixed directly on the second main electrode 12 as shown in FIG. 25. FIG. 25 is a cross-sectional view schematically explaining essential structure of the surface treatment apparatus in accordance with a third modification of eleventh embodiment of the present invention.

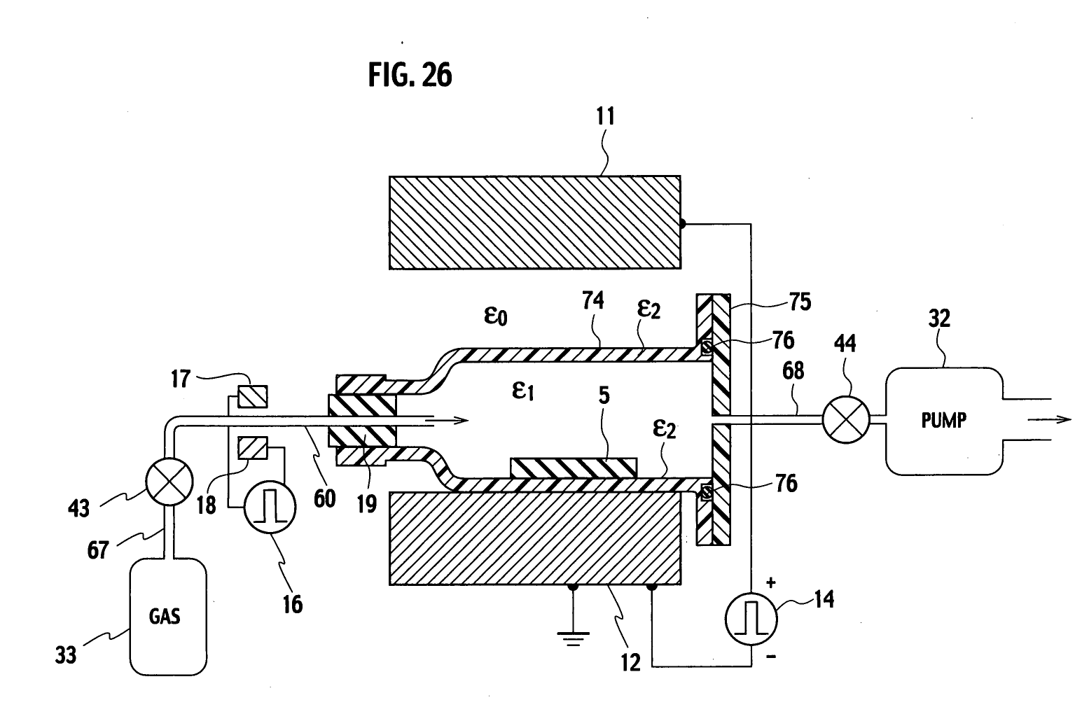

As shown in FIG. 26, a surface treatment apparatus related to a fourth modification of the eleventh embodiment of the present invention apparatus encompasses a dielectric housing (74, 75 and 76) configured to accommodate an treatment object 5; a gas introducing system (33, 67, 43, 60) (33, 67, 43, 60) configured to introduce process gas from upstream end of the dielectric housing (74, 75 and 76); a vacuum evacuating system (32,44 and 68) configured to evacuate the process gas from downstream end of the dielectric housing (74, 75 and 76); an excited particle supplying system (16,17 and 18) disposed at upstream side of the dielectric housing (74, 75 and 76), configured to supply excited particles for inducing initial discharge in a main body of the dielectric housing (74, 75 and 76); and a first main electrode 11 and a second main electrode 12 disposed oppositely to each other, defining a treating region of the treatment object as a main plasma generating region disposed therebetween, wherein the excited particle supplying system (16,17 and 18) is driven at least until generation of main plasma, and main pulse of duty ratio of 10⁻⁷ to 10⁻¹ is applied across the first main electrode 11 and second main electrode 12, to generate a non-thermal equilibrium plasma flow inside the dielectric housing (74, 75 and 76), and thereby a surface of the treatment object 5 is treated.

Although, in FIG. 26, the dielectric housing (74, 75 and 76) is fixed directly on the second main electrode 12, the dielectric housings (74, 75 and 76) may be mounted on the second main electrode 12 via a second main electrode covering insulating film as shown in FIGS. 22-24.

### Twelfth Embodiment

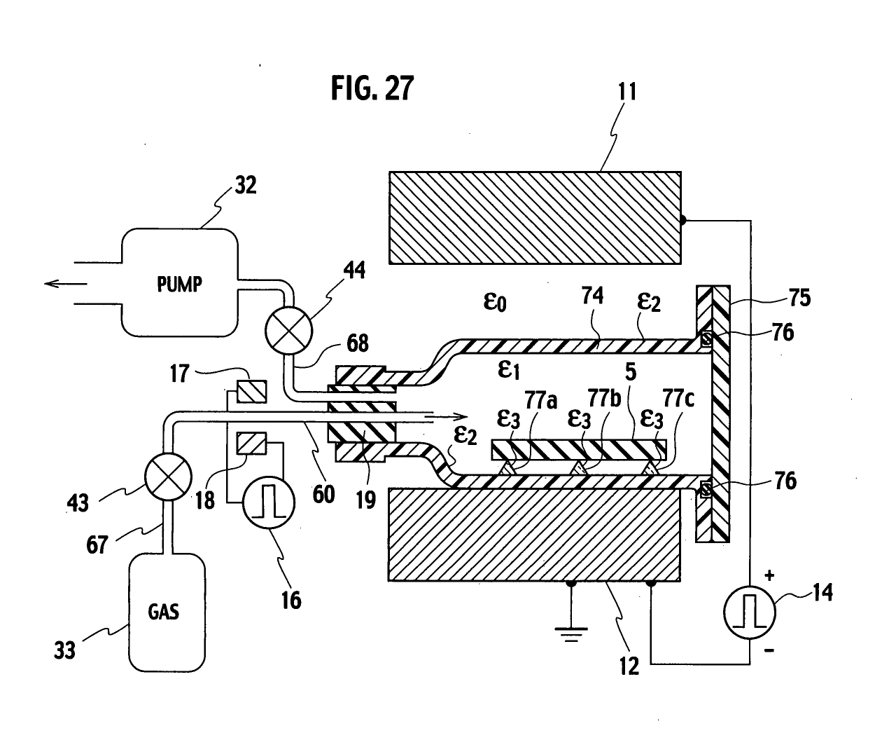

As shown in FIG. 27, a surface treatment apparatus related to a twelfth embodiment of the present invention apparatus encompasses a dielectric housing (74, 75 and 76) configured to accommodate an treatment object 5 via a plurality of protrusions 77a, 77b, 77c; a vacuum evacuating system (32,44 and 68) configured to evacuate process gas introduced at a specific flow rate from a feed pipe provided at first end of the dielectric housing (74, 75 and 76) having second end closed, from an exhaust pipe provided at the first end, and maintaining the pressure of the process gas inside the dielectric housing (74, 75 and 76) at a process pressure; an excited particle supplying system (16,17 and 18) disposed at first end side of the dielectric housing (74, 75 and 76), configured to supply excited particles for inducing initial discharge in a main body of the dielectric housing (74, 75 and 76); and a first main electrode 11 and a second main electrode 12 disposed oppositely to each other, defining a treating region of the treatment object as a main plasma generating region disposed therebetween, wherein the excited particle supplying system (16,17 and 18) is driven at least until generation of main plasma, and main pulse of duty ratio of 10⁻⁷ to 10⁻¹ is applied across the first main electrode 11 and second main electrode 12, to generate a non-thermal equilibrium plasma flow inside the dielectric housing (74, 75 and 76), and thereby a surface of the treatment object 5 is treated.

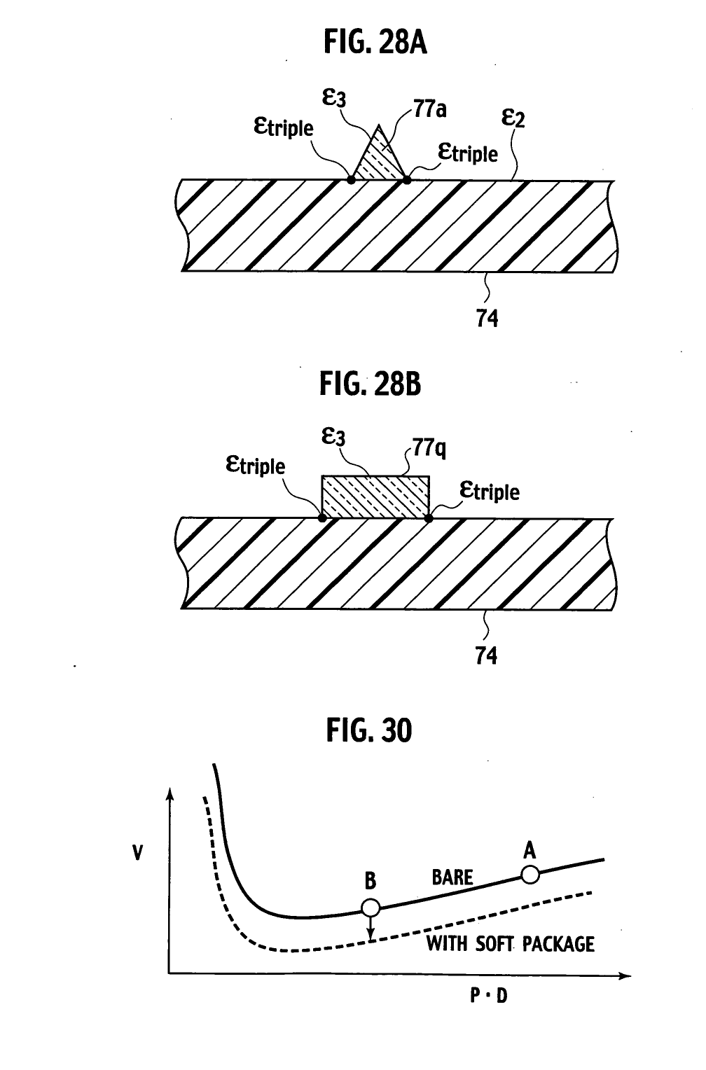

As shown in FIG. 27, the dielectric housing (74, 75 and 76) is implemented by a dielectric tube 74 and a dielectric flange plate 75, and a plurality of protrusions 77a, 77b, 77c are provided on the inner surface of the dielectric tube 74, and the treatment object 5 is mounted on the inner surface of dielectric tube 74 via protrusions 77a, 77b, 77c. If a plurality of protrusions 77a, 77b, 77c are provided on the inner surface of the dielectric tube 74, the initial voltage required for plasma discharge can be reduced, owing to the effect of dielectric triple point εₜᵣᵢₚₗₑ as shown in FIGS. 28A and 28B. If dielectric triple point εₜᵣᵢₚₗₑ is present in a plasma space, the plasma discharge will start from the dielectric triple point εₜᵣᵢₚₗₑ, and the initial voltage required for plasma discharge can be reduced.

### Thirteen Embodiment

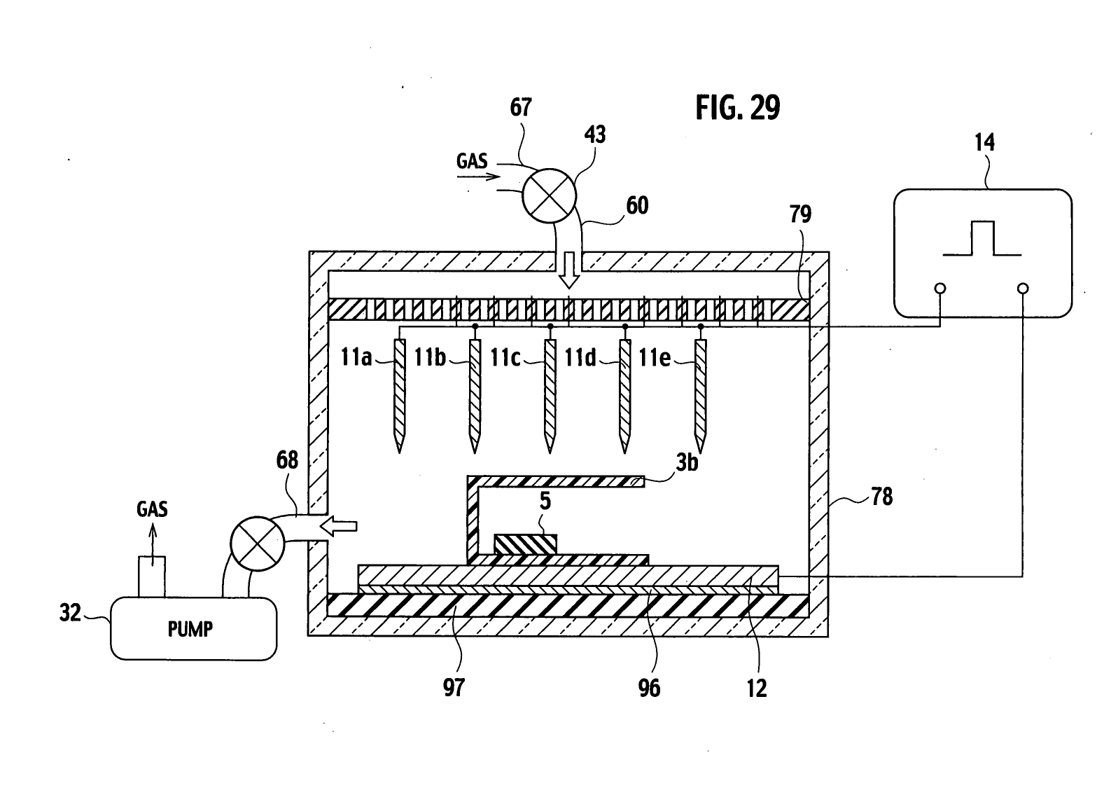

As shown in FIG. 29, a surface treatment apparatus related to a thirteenth embodiment of the present invention encompasses a process chamber 78 establishing a dosed space enclosing the surrounding of the treatment object 5, which is installed in a flexible container 3b; a gas introducing system (67, 43, 60) for introducing process gas from upstream side of the process chamber 78; a vacuum evacuating system (68, 32) for evacuating the process gas from downstream side of the process chamber 78; an array of first main electrodes 11a, 11b, 11c, 11d and 11e, disposed in the process chamber 78 so as to serve as an anode; a second main electrode 12 disposed in the process chamber 78 so as to serve as a cathode; and an ambient gas adjusting mechanism 79 disposed in the process chamber 78, for supplying the process gas from a side where the array of first main electrodes 11a, 11b, 11c, 11d and 11e are arranged, like a shower toward the surface of the second main electrode 12.

The flexible container 3b is a housing made of thin dielectric thin film. One plane of the flexible container 3b is made open such that ambient gas and plasma species can communicate between inside and outside of the flexible container 3b.

A pulse power supply 14 applies electric pulses (main pulses) across the array of first main electrodes 11a, 11b, 11c, 11d and 11e and the second main electrode 12, which implement a quasi-parallel plate configuration, so that the electric pulse can cause the fine-streamer discharge in the hermetically sealed space, which surrounds the outside of the flexible container 3b. In the ambient gas adjustment mechanism 79 a plurality of gas supply holes are provided in a form of two-dimensional matrix with a predetermined pitch. The main pulse of duty ratio of 10⁻⁷ to 10⁻¹ is applied between the array of first main electrodes 11a, 11b, 11c, 11d and 11e and second main electrode 12, and the surface of the treatment object 5 is treated in non-thermal equilibrium plasma in the flexible container 3b.

If we assume the distance between the tip of the array of first main electrodes 11a, 11b, 11c, 11d and 11e and the top of the flexible container 3b is d, the film thickness of the flexible container 3b is t, and the inner height of the flexible container 3b is g, with ε₁ for the dielectric constant of the process gas, and ε₂ for the dielectric constant of flexible container 3b, the total capacitance Cₜₒₜₐₗ of the parallel plate capacitance with area S, which is defined against the plasma space is given by:

Cₜₒₜₐₗ=S/(d/ε₀ε₁+2t/ε₀ε₂+g/ε₀ε₁) (7).

From Eq. (7), we understand that we can make electric field in the inside of the flexible container 3b larger than at the outside of the flexible container 3b, so that we can generate plasma only in the inside of the flexible container 3b. Namely, as shown in FIG. 30, the Paschen's curve illustrated by dotted line for the case that the flexible container 3b is employed win move to lower voltage side, compared to the curve illustrated by solid line for the case that the flexible container 3b is not employed.

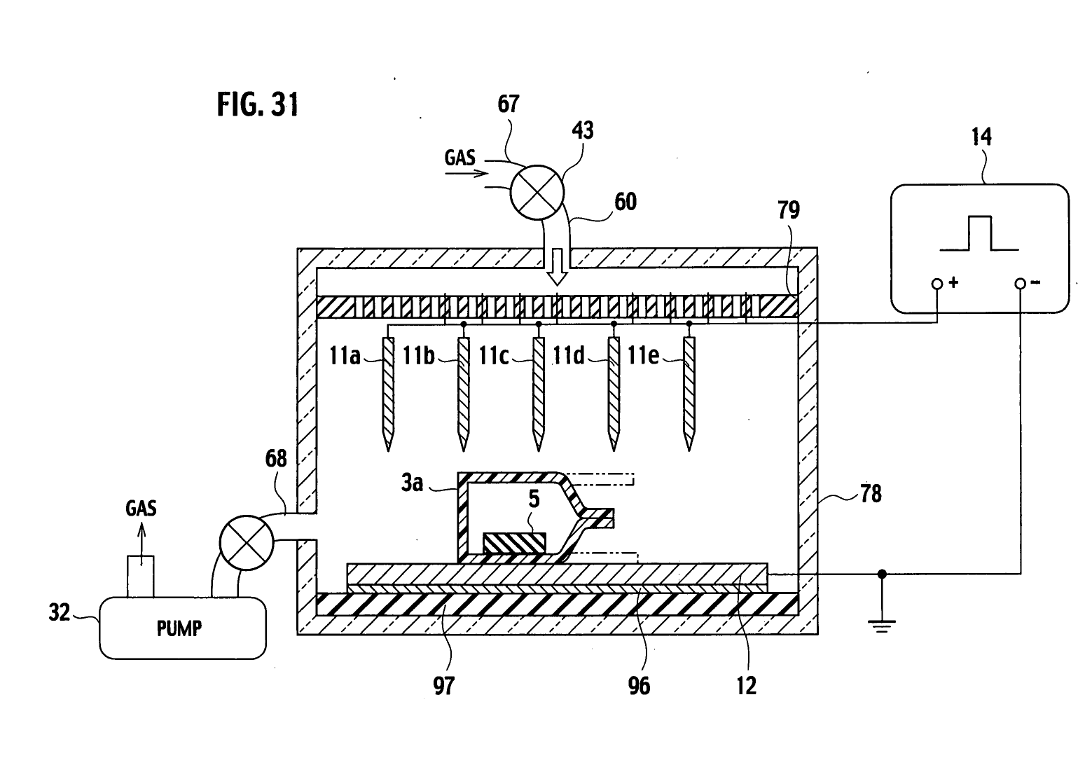

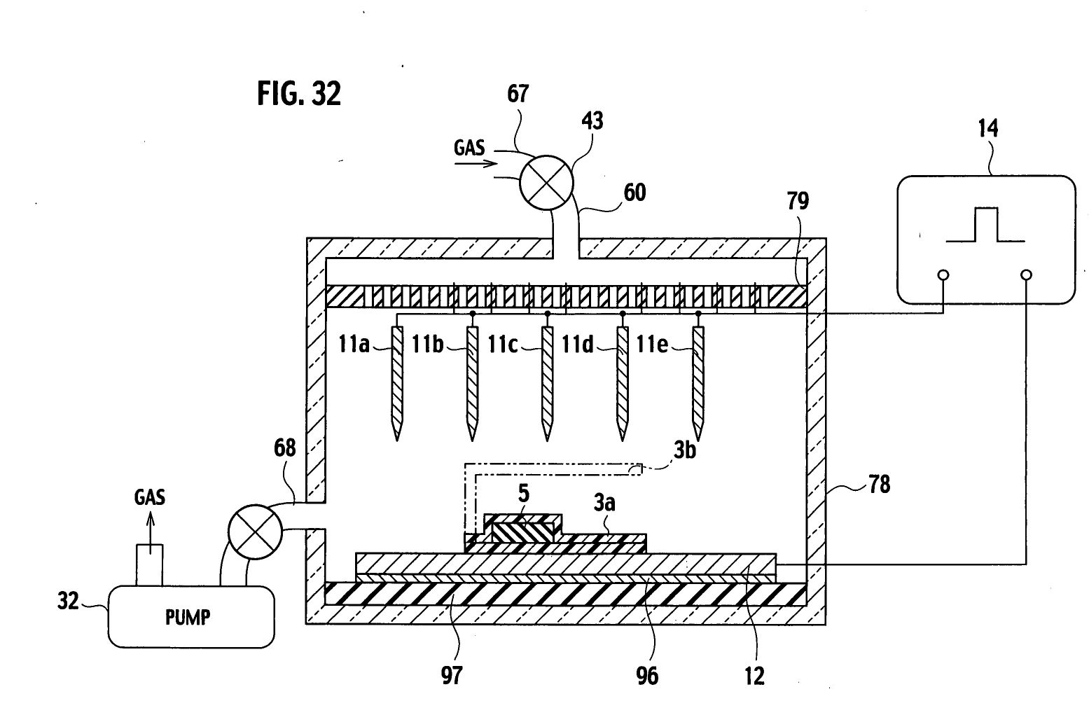

As shown in FIG. 31, when the treatment against the treatment object 5 is completed, the treatment object 5 may be hermetically sealed by the flexible container 3a with inert gas such as nitrogen gas, because the flexible container 3a is so thin to establish a flexible behavior. Alternatively, as shown in FIG. 32, when the treatment against the treatment object 5 is completed, the treatment object 5 may be hermetically sealed by the flexible container 3a with reduced pressure.

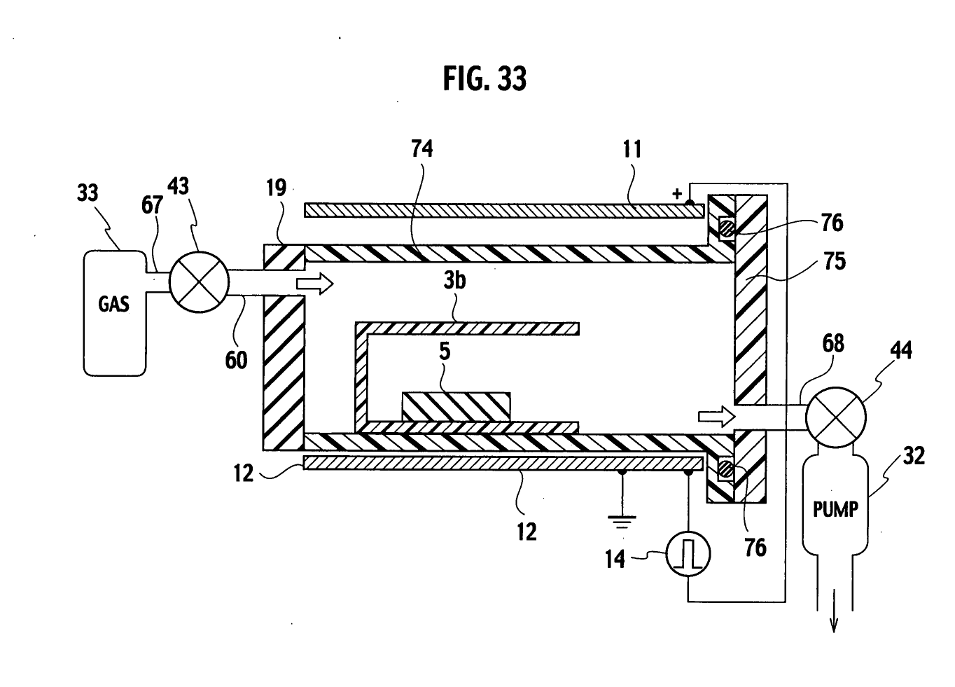

As shown in FIG. 33, a surface treatment apparatus related to a modification of the thirteenth embodiment of the present invention encompasses a process chamber (74, 75 and 76) establishing a closed space enclosing the surrounding of the treatment object 5, which is installed in a flexible container 3b; a gas introducing system (33, 67, 43, 60) for introducing a the process gas from upstream side of the process chamber (74, 75 and 76); a vacuum evacuating system (68, 44 and 32) for evacuating the process gas from downstream side of the process chamber (74, 75 and 76); a first main electrodes 11, disposed over the process chamber (74, 75 and 76) so as to serve as an anode; a second main electrode 12 disposed below the process chamber (74, 75 and 76) so as to serve as a cathode. The main pulse of duty ratio of 10⁻⁷ to 10⁻¹ is applied across the first main electrodes 11 and second main electrode 12, and an outer surface of the treatment object 5 is treated in non-thermal equilibrium plasma. A pulse power supply 14 applies electric pulses (main pulses) across the first main electrodes 11 and the second main electrode 12, which implement a parallel plate configuration, so that the electric pulse can cause the fine-streamer discharge in the hermetically sealed space, which surrounds the outside of the treatment object 5.

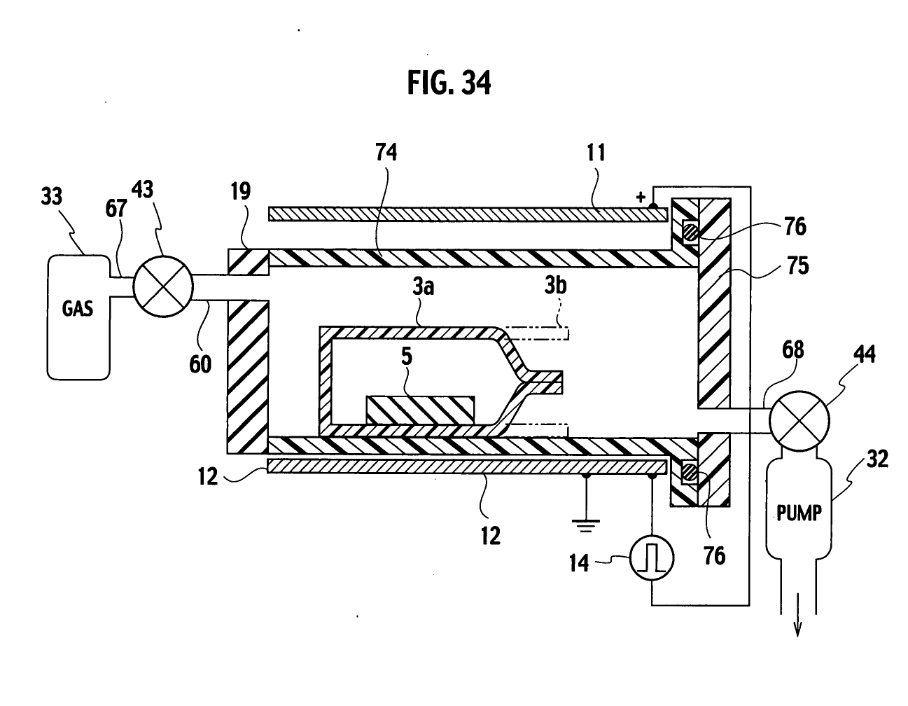

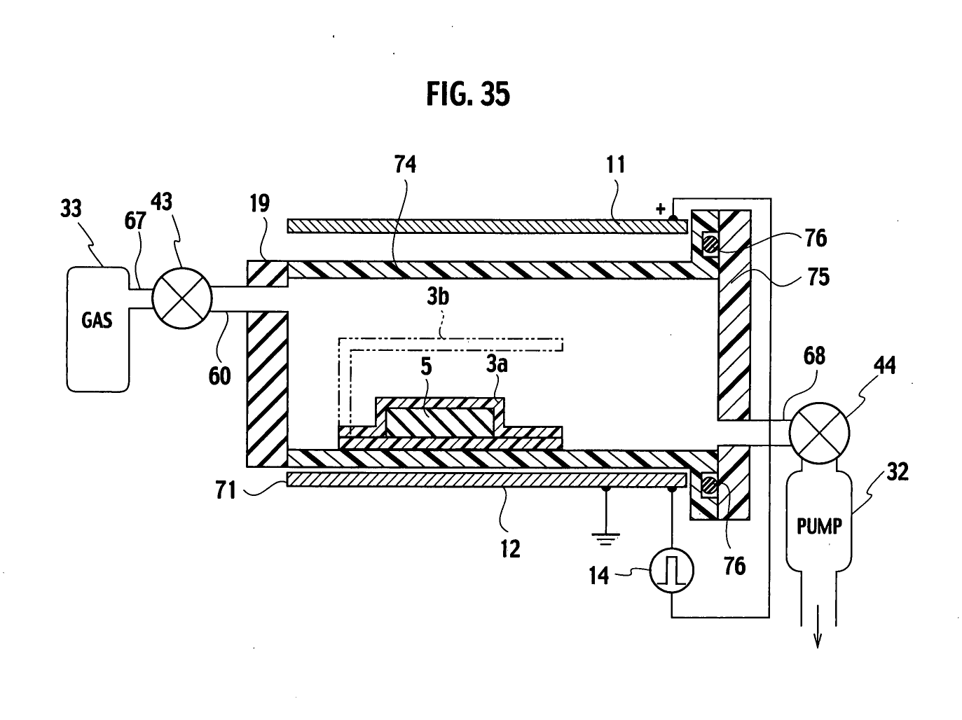

Although FIG. 33 shows the state that the treatment object 5 is under treatment by the surface treatment apparatus in accordance with the modification of the thirteenth embodiment of the present invention, as shown in FIG. 34, when the treatment against the treatment object 5 is completed, the treatment object 5 may be hermetically sealed by the flexible container 3a with inert gas such as nitrogen gas, because the flexible container 3a is capable of being bent or flexed. Alternatively, as shown in FIG. 35, when the treatment against the treatment object 5 is completed, the treatment object 5 may be hermetically sealed by the flexible container 3a with reduced pressure.

### OTHER EMBODIMENTS

Various modifications will become possible for those skilled in the art after receiving the teaching of the present disclosure without departing from the scope thereof.

For example, each technical idea explained in first to thirteenth embodiments can be combined. For example, structure of the first main electrode 11c and the structure of the ambient gas adjustment mechanism (62, 27, 66c), with which the first modification of the second embodiment is explained, may be applied to the third, sixth to tenth embodiments. And, the structure of the first main electrode 11d and the third structure of the ambient gas adjustment mechanism (62, 25d, 66d), with which the second modification of the second embodiment is explained, may be applied to the third, sixth to tenth embodiments.

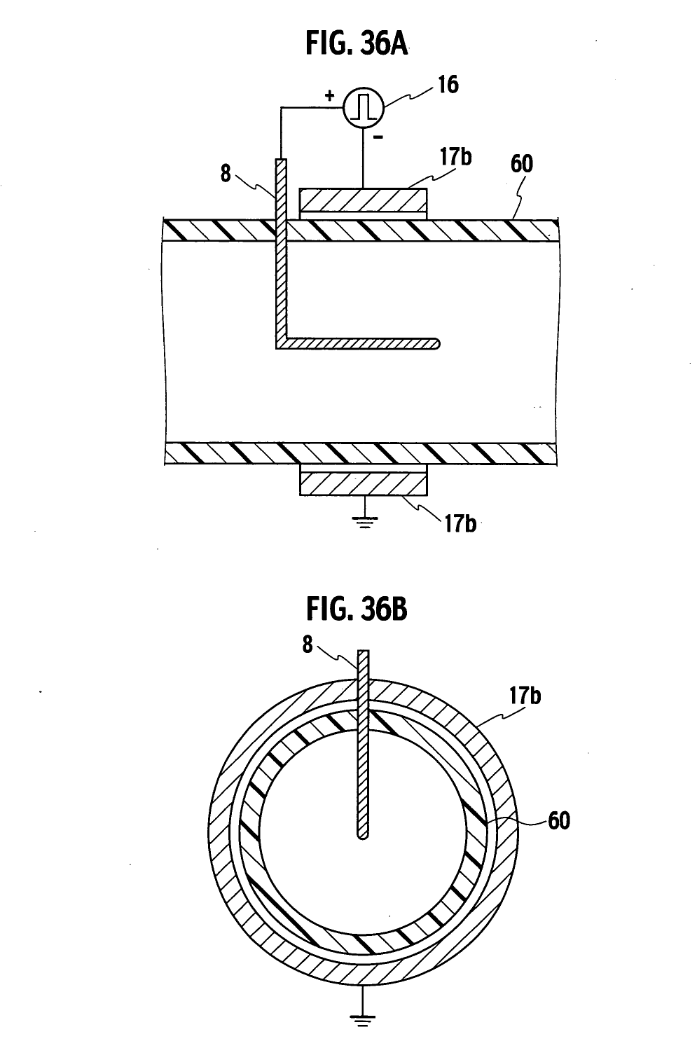

In addition, as the excited particle supplying system, the excitations by plasma discharges through parallel plate configurations are disclosed in the first to seventh and the ninth to thirteenth embodiments, and the excitation by ultraviolet rays is disclosed in the eighth embodiment, they are mere illustrations, and there are many other excitation mechanisms of various kinds for generating initial plasma. For example, as shown in FIGS. 36A and 36B, a belt-shaped (flat ring) shell electrode (the first auxiliary electrode) 17b may surround the outside of the excitation feed pipe 60, while an L-shaped electrode (the second auxiliary electrode) 8 is inserted in the central part of the excitation feed pipe 60 so that a discharge can be generated between the first auxiliary electrode 17b and the second auxiliary electrode 8.

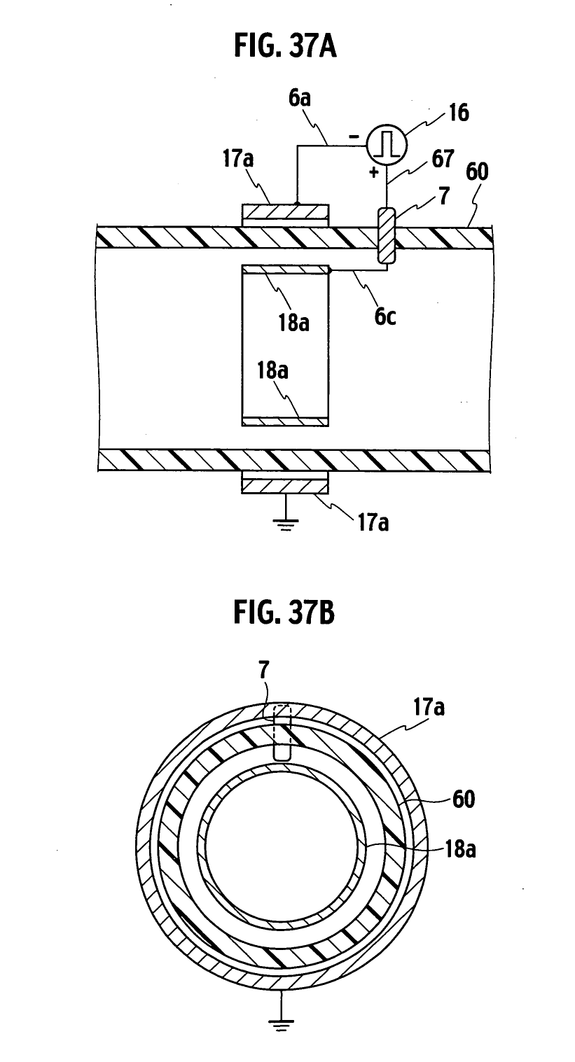

Alternatively, as shown in FIGS. 37A and 37B, a cylindrical outer shell (the first auxiliary electrode) 17a may surround the outside of the excitation feed pipe 60, while a cylindrical inner shell (the second auxiliary electrode) 18a may be included in the inside of the excitation feed pipe 60 so as to implement concentric cylinders, in which a discharge is established between the first auxiliary electrode 17a and the second auxiliary electrode 18a.

In FIGS. 37A and 37B, though a case that an auxiliary pulse power supply 16 provides a voltage to the inner cylindrical shell (the second auxiliary electrode) 18a through an electric current introduction terminal feedthrough) 7, the methodology for supplying the voltage is not limited to the configuration illustrated in FIGS. 37A and 37B.

Through a first outer wiring 67, the electric current introduction terminal (feedthrough) 7 is connected to the auxiliary pulse power supply 16, and the electric current introduction terminal (feedthrough) 7 is connected to the inner cylindrical shell (the second auxiliary electrode) 18a through an inner wiring 6c. In addition, the auxiliary pulse power supply 16 is connected to the outer cylindrical shell (the first auxiliary electrode) 17a through a second outer wiring 6a.

In addition, although the excitation of the process gas by ultraviolet rays using multi-reflection was explained in the eighth embodiment, it is not necessary to use the multi-reflection, and other methodologies such as the collinear introduction of the ultraviolet ray beam along the introduction direction of the process gas can generate the excited particles. In addition, the excited particles can be generated by irradiation of radioactive rays, aside from ultraviolet rays, such as synchrotron radiation, for example.

Furthermore, although the cases that a single treatment object is processed are illustrated in the first to thirteenth embodiments, a plurality of treatment objects can be processed simultaneously, if the first main electrode 11b and the second main electrode 12 are disposed so as to sandwich the plurality of treatment objects. If each of the inside of the plurality of treatment object is processed, a plurality of feed pipes and a plurality of exhaust pipe and accompanying valves shall be required for each treatment objects, respectively, of course.

Thus, the present invention of course includes various embodiments and modifications and the like, which are not detailed above. Therefore, the scope of the present invention will be defined in the following claims.

What is claimed is:

1. A surface treatment apparatus comprising:
a gas introducing system configured to introduce a process gas from an upstream end of a tubular treatment object;
a vacuum evacuating system configured to evacuate the process gas from a downstream end of the treatment object;
an excited particle supplying system disposed at upstream side of the treatment object, configured to supply excited particles for inducing initial discharge in a main body of the treatment object; and
a first main electrode and a second main electrode disposed oppositely to each other, defining a treating region of the treatment object as a main plasma generating region disposed therebetween,
wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow in the inside of the treatment object, and thereby an inner surface of the treatment object is treated.

2. The surface treatment apparatus according to claim 1, further comprising:
a process chamber establishing a dosed space enclosing the surrounding of the treatment object; and
an ambient gas adjusting mechanism incorporating the first main electrode therein, configured to supply the process gas in the process chamber, from the first main electrode like a shower toward the second main electrode, and evacuating the shower of the process gas from a part of the process chamber,
wherein the main pulse is applied across the first main electrode and second main electrode, and an outer surface of the treatment object is further treated in non-thermal equilibrium plasma.

3. The surface treatment apparatus according to claim 1, wherein a half width of pulse width of the main pulse is 10 to 500 ns,
the pulse width is set according to an interval of the anode and cathode, and such that the pulse voltage application is completed before an arc discharge current begins to flow in the plasma generation between the anode and cathode, the plasma generation lapses from a glow discharge, through a streamer discharge to the arc discharge.

4. The surface treatment apparatus according to claim 2, wherein the ambient gas adjusting mechanism has a second vacuum evacuating system configured to evacuate the space enclosing the surrounding of the treatment object.

5. The surface treatment apparatus according to claim 1, wherein the excited particle supplying system is any one of an ultraviolet ray irradiator, a laser beam irradiator, an electron beam irradiator, a radiation irradiator, and a high temperature heater.

6. The surface treatment apparatus according to claim 1, wherein discharge of the non-thermal equilibrium plasma is fine streamer discharge.

7. The surface treatment apparatus according to claim 1, wherein discharge of the non-thermal equilibrium plasma has a maximum rise rate dV/dt of voltage of the main pulse, which is applied across the first main electrode and the second main electrode, in a range of 10 kV/μs to 1000 kV/μs.

8. A surface treatment apparatus comprising:
a vacuum evacuating system configured to evacuate a process gas introduced at a specific flow rate from a feed pipe provided at an upstream end of a tubular treatment object having a blind wall at a second end, from an exhaust pipe provided at the upstream end, and maintaining the pressure of the process gas inside the treatment object at a process pressure;
an excited particle supplying system disposed at upstream side of the treatment object, configured to supply excited particles for inducing initial discharge in a main body of the treatment object; and
a first main electrode and a second main electrode disposed oppositely to each other, defining a treating region of the treatment object as a main plasma generating region disposed therebetween,
wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow in the inside of the treatment object, and thereby an inner surface of the treatment object is treated.

9. The surface treatment apparatus according to claim 8, wherein a half width of pulse width of the main pulse is 10 to 500 ns,
the pulse width is set according to an interval of the anode and cathode, and such that the pulse voltage application is completed before an arc discharge current begins to flow in the plasma generation between the anode and cathode, the plasma generation lapses from a glow discharge, through a streamer discharge to the arc discharge.

10. A surface treatment apparatus comprising:
a vacuum manifold unit connected to a first end of a tubular treatment object having a blind wall at a second end, configured to confine hermetically process gas at specified pressure inside of the treatment object from the first end;
an excited particle supplying system disposed at the first end side, configured to supply excited particles for inducing initial discharge in a main body of the treatment object; and
a first main electrode and a second main electrode disposed oppositely to each other, defining a treating region of the treatment object as a main plasma generating region disposed therebetween,
wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma in the inside of the treatment object, and thereby an inner surface of the treatment object is treated.

11. The surface treatment apparatus according to claim 10, wherein a half width of pulse width of the main pulse is 10 to 500 ns,
the pulse width is set according to an interval of the anode and cathode, and such that the pulse voltage application is completed before an arc discharge current begins to flow in the plasma generation between the anode and cathode, the plasma generation lapses from a glow discharge, through a streamer discharge to the arc discharge.

12. A surface treatment apparatus comprising:
a vacuum evacuating system configured to evacuate process gas introduced from an upstream end of a tubular trunk pipe of a treatment object to generate a gas flow, the treatment object having the tubular trunk pipe and a branch pipe branched off from the trunk pipe, from an downstream end of the trunk pipe and an end portion of the branch pipe;
an excited particle supplying system disposed at the upstream side of the treatment object, configured to supply excited particles for inducing initial discharge in a main body of the treatment object; and
a first main electrode and a second main electrode disposed oppositely to each other, defining a treating region of the treatment object as a main plasma generating region disposed therebetween,
wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow in the inside of the treatment object, and thereby an inner surface of the treatment object is treated.

13. The surface treatment apparatus according to claim 12, wherein a half width of pulse width of the main pulse is 10 to 500 ns,
the pulse width is set according to an interval of the anode and cathode, and such that the pulse voltage application is completed before an arc discharge current begins to flow in the plasma generation between the anode and cathode, the plasma generation lapses from a glow discharge, through a streamer discharge to the arc discharge.

14. A surface treatment apparatus comprising:
a vacuum evacuating system configured to evacuate process gas introduced from an upstream end of a tubular trunk pipe of a treatment object and an end portion of a branch pipe of the treatment object to generate a gas flow, the treatment object having the tubular trunk pipe and the branch pipe branched off from the trunk pipe, from a downstream end of the trunk pipe;
an excited particle supplying system disposed at the upstream side of the treatment object, configured to supply excited particles for inducing initial discharge in a main body of the treatment object; and
a first main electrode and a second main electrode disposed oppositely to each other, defining a treating region of the treatment object as a main plasma generating region disposed therebetween,
wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow in the inside of the treatment object, and thereby an inner surface of the treatment object is treated.

15. The surface treatment apparatus according to claim 14, wherein a half width of pulse width of the main pulse is 10 to 500 ns,
the pulse width is set according to an interval of the anode and cathode, and such that the pulse voltage application is completed before an arc discharge current begins to flow in the plasma generation between the anode and cathode, the plasma generation lapses from a glow discharge, through a streamer discharge to the arc discharge.

16. A surface treatment apparatus comprising:
an excited particle supplying system disposed at upstream side of a tubular treatment object made of dielectric material, the treatment object having a length greater than the diameter, configured to supply excited particles for inducing initial discharge in a main body of the treatment object; and
a first main electrode and a second main electrode disposed oppositely to each other, defining a treating region of the treatment object as a main plasma generating region disposed therebetween,
wherein a process gas is introduced from one end of the treatment object to form a gas flow inside of the treatment object, and the pressure of the gas flow is adjusted to a process pressure in a range of 20 kPa to 100 kPa, the excited particle supplying system is driven at least until generation of main plasma, and main pulse of duty ratio of 10⁻⁷ to 10⁻¹ is applied across the first main electrode and second main electrode to generate a non-thermal equilibrium plasma flow in the inside of the treatment object, and thereby an inner surface of the treatment object is treated.

17. The surface treatment apparatus according to claim 16, wherein a half width of pulse width of the main pulse is 10 to 500 ns,
the pulse width is set according to an interval of the anode and cathode, and such that the pulse voltage application is completed before an arc discharge current begins to flow in the plasma generation between the anode and cathode, the plasma generation lapses from a glow discharge, through a streamer discharge to the arc discharge.

18. A surface treatment apparatus comprising:
a dielectric housing configured to accommodate an treatment object;
a gas introducing system configured to introduce a process gas from upstream end of the dielectric housing;
a vacuum evacuating system configured to evacuate the process gas from downstream end of the dielectric housing;
an excited particle supplying system disposed at upstream side of the dielectric housing, configured to supply excited particles for inducing initial discharge in a main body of the dielectric housing; and
a first main electrode and a second main electrode disposed oppositely to each other, defining a treating region of the treatment object as a main plasma generating region disposed therebetween,
wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow inside the dielectric housing, and thereby a surface of the treatment object is treated.

19. The surface treatment apparatus according to claim 18, wherein a half width of pulse width of the main pulse is 10 to 500 ns,
the pulse width is set according to an interval of the anode and cathode, and such that the pulse voltage application is completed before an arc discharge current begins to flow in the plasma generation between the anode and cathode, the plasma generation lapses from a glow discharge, through a streamer discharge to the arc discharge.

20. A surface treatment apparatus comprising:
a dielectric housing configured to accommodate an treatment object;
a vacuum evacuating system configured to evacuate a process gas introduced at a specific flow rate from a feed pipe provided at a first end of the dielectric housing having a blind wall at a second end, from an exhaust pipe provided at the first end, and maintaining the pressure of the process gas inside the dielectric housing at a process pressure;
an excited particle supplying system disposed at upstream side of the dielectric housing, configured to supply excited particles for inducing initial discharge in a main body of the dielectric housing; and
a first main electrode and a second main electrode disposed oppositely to each other, defining a treating region of the treatment object as a main plasma generating region disposed therebetween,
wherein the excited particle supplying system is driven at least until generation of main plasma, and main pulse of duty ratio of 10⁻⁷ to 10⁻¹ is applied across the first main electrode and second main electrode, to generate a non-thermal equilibrium plasma flow inside the dielectric housing, and thereby a surface of the treatment object is treated.

21. The surface treatment apparatus according to claim 20, wherein a half width of pulse width of the main pulse is 10 to 500 ns,
the pulse width is set according to an interval of the anode and cathode, and such that the pulse voltage application is completed before an arc discharge current begins to flow in the plasma generation between the anode and cathode, the plasma generation lapses from a glow discharge, through a streamer discharge to the arc discharge.
